(19) United States
(12) Patent Application Publication
(10) Pub. No.: US 2011/0311913 A1
(43) Pub. Date: Dec. 22, 2011

(54) POSITIVE RESIST COMPOSITION AND METHOD OF FORMING RESIST PATTERN

(75) Inventors: Kenta SUZUKI, Kawasaki-shi (JP); Daiju SHIONO, Kawasaki-shi (JP)

(73) Assignee: TOKYO OHKA KOGYO CO., LTD., Kawasaki-shi (JP)

(21) Appl. No.: 13/156,180

(22) Filed: Jun. 8, 2011

(30) Foreign Application Priority Data
Jun. 15, 2010 (JP) P2010-136216
Jul. 16, 2010 (JP) P2010-161958

(51) Int. Cl. G03F 7/20; G03F 7/039

(52) U.S. Cl. 430/270.1; 430/326

(57) ABSTRACT

A positive resist composition including: a base component (A′) that exhibits increased solubility in an alkali developing solution under action of acid, without including an acid generator component other than the base component (A′), wherein the base component (A′) includes a resin component (A1) having a structural unit (a0-1) represented by general formula (a0-1) shown below and a structural unit (a1) containing an acid dissociable, dissolution inhibiting group:

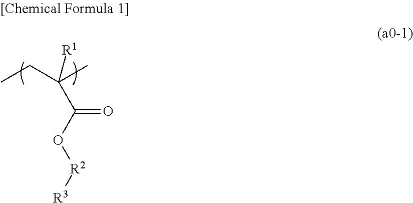

wherein R¹ represents a hydrogen atom, an alkyl group of 1 to 5 carbon atoms or a halogenated alkyl group of 1 to 5 carbon atoms; R² represents a single bond or a divalent linking group; and R³ represents a cyclic group that contains —SO₂— within the ring skeleton thereof.

### BACKGROUND OF THE INVENTION

1. Field of the Invention

The present invention relates to a positive resist composition exhibiting excellent lithography properties, and a method of forming a resist pattern using the resist composition.

Priority is claimed on Japanese Patent Application No. 2010-136216, filed Jun. 15, 2010, and Japanese Patent Application No. 2010-161958, filed Jul. 16, 2010, the contents of which are incorporated herein by reference.

2. Description of Related Art

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have led to rapid progress in the field of pattern miniaturization.

Typically, these miniaturization techniques involve shortening the wavelength of the exposure light source. Conventionally, ultraviolet radiation typified by g-line and i-line radiation has been used, but nowadays KrF excimer lasers and ArF excimer lasers are now starting to be introduced in mass production. Furthermore, research is also being conducted into lithography techniques that use exposure light source having a wavelength shorter than these excimer lasers, such as F₂ excimer lasers, electron beam (EB), extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material which satisfies these conditions, a chemically amplified resist composition is used, which includes a base component that exhibits a changed solubility in an alkali developing solution under action of acid and an acid generator that generates acid upon exposure.

For example, a chemically amplified positive resist typically contains a resin component (base resin) that exhibits increased solubility in an alkali developing solution under the action of acid, and an acid generator component. If the resist film formed using this resist composition is selectively exposed during formation of a resist pattern, then acid is generated from the acid generator within the exposed portions, and the action of this acid causes an increase in the solubility of the resin component in an alkali developing solution, making the exposed portions soluble in the alkali developing solution.

Currently, resins that contain structural units derived from (meth)acrylate esters within the main chain (acrylic resins) are widely used as base resins for resists that use ArF excimer laser lithography and the like, as they exhibit excellent transparency in the vicinity of 193 nm (for example, see Patent Document 1). Here, the term “(meth)acrylic acid” is a generic term that includes either or both of acrylic acid having a hydrogen atom bonded to the α-position and methacrylic acid having a methyl group bonded to the α-position. The term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

Further, in order to improve various lithography properties, a resin having a plurality of structural units is currently used for a chemically amplified resist. For example, in the case of a positive resist, a resin containing a structural unit having an acid dissociable, dissolution inhibiting group that is dissociated by the action of acid generated from the acid generator, a structural unit having a polar group such as a hydroxyl group, and a structural unit having a lactone structure and the like is typically used. Among these structural units, a structural unit having a lactone structure is generally considered as being effective in improving the adhesion between the resist film and the substrate, and increasing the compatibility with an alkali developing solution, thereby contributing to improvement in various lithography properties.

In recent years, low energy EB exposure apparatuses accelerated with low voltage have been developed. Devices that can be achieved by the low energy EB exposure apparatuses are attracting attention in view of their high throughput, small size, and low cost.

### PRIOR ART DOCUMENTS

### Patent Documents

[Patent Document 1] Japanese Unexamined Patent Application, First Publication No. 2003-241385

### SUMMARY OF THE INVENTION

In the future, as further progress is made in lithography techniques and the potential application fields for lithography techniques continue to expand, demands will grow for novel materials capable of being used in these lithography applications. For example, further progress in pattern miniaturization will result in ever greater demands for improvements in resist materials, both in terms of various lithography properties such as exposure latitude (EL) margin, line width roughness (LWR) and the like, as well as resolution, and in terms of the shape of the obtained pattern.

However, in the conventional resist materials as those described in the above Patent Document 1 that contain a resin component and an acid generator component separately, the acid generator component aggregates and does not distribute uniformly within the formed resist film, thereby reducing the lithography properties. Further, this problem is particularly prominent in recent years in the thin film resist materials when subjected to exposure using KrF and ArF excimer lasers, EB and EUV as exposure light sources, and thus the solution for the problem has been demanded.

Furthermore, in those cases where a resist composition which has been used for the conventional lithography process employing an ArF excimer laser or the like as an exposure light source is used for the lithography process employing a low energy EB as an exposure light source as described above, the sensitivity is too high, which makes it unsuitable for practical use. For this reason, development of a general-purpose resist composition that can be used not only with the current exposure light sources such as ArF excimer lasers and KrF excimer lasers but also with low energy EB has been expected.

The present invention takes the above circumstances into consideration, with an object of providing a positive resist composition exhibiting excellent lithography properties and pattern shape, and a method of forming a resist pattern that uses the resist composition.

In order to achieve the above object, the present invention adopts the aspects described below.

That is, a first aspect of the present invention is a positive resist composition including a base component (A′) that exhibits increased solubility in an alkali developing solution under action of acid, without including an acid generator component other than the aforementioned base component (A′), wherein the aforementioned base component (A′) includes a resin component (A1) having a structural unit (a0-1) represented by general formula (a0-1) shown below and a structural unit (a1) containing an acid dissociable, dissolution inhibiting group.

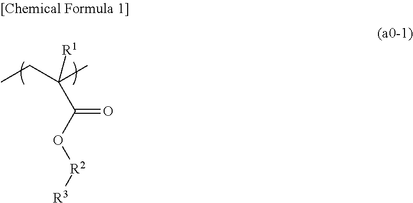

In the formula, R¹ represents a hydrogen atom, an alkyl group of 1 to 5 carbon atoms or a halogenated alkyl group of 1 to 5 carbon atoms; R² represents a single bond or a divalent linking group; and R³ represents a cyclic group that contains —SO₂— within the ring skeleton thereof.

In the present description and claims, the term “aliphatic” is a relative concept used in relation to the term “aromatic”, and defines a group or compound or the like that has no aromaticity.

An “alkyl group”, unless otherwise specified, includes linear, branched and cyclic, monovalent saturated hydrocarbon groups.

The term “alkylene group” includes linear, branched or cyclic divalent saturated hydrocarbon groups, unless otherwise specified.

The same definition for the “alkyl group” described above applies for the “alkyl group within an alkoxy group”.

A “halogenated alkyl group” is a group in which some or all of the hydrogen atoms of an alkyl group have been substituted with halogen atoms, wherein examples of the halogen atoms include fluorine atoms, chlorine atoms, bromine atoms and iodine atoms.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (a resin, polymer or copolymer).

A “structural unit derived from an acrylate ester” describes a structural unit formed by cleavage of the ethylenic double bond of an acrylate ester.

The term “acrylate ester” is a generic term that includes the acrylate ester having a hydrogen atom bonded to the carbon atom on the α-position, and acrylate esters having a substituent (an atom other than a hydrogen atom or a group) bonded to the carbon atom on the α-position. Examples of the substituent bonded to the carbon atom on the α-position include an alkyl group of 1 to 5 carbon atoms, a halogenated alkyl group of 1 to 5 carbon atoms and a hydroxyalkyl group of 1 to 5 carbon atoms.

A “carbon atom on the α-position of an acrylate ester” refers to the carbon atom bonded to the carbonyl group, unless specified otherwise.

With respect to the acrylate ester, specific examples of the alkyl group of 1 to 5 carbon atoms for the substituent at the α-position include linear or branched alkyl groups of 1 to 5 carbon atoms such as a methyl group, ethyl group, propyl group, isopropyl group, n-butyl group, isobutyl group, tert-butyl group, pentyl group, isopentyl group and neopentyl group.

Specific examples of the halogenated alkyl group of 1 to 5 carbon atoms include groups in which some or all of the hydrogen atoms of the aforementioned “alkyl group of 1 to 5 carbon atoms for the substituent at the α-position” are substituted with halogen atoms. Examples of the halogen atom include a fluorine atom, a chlorine atom, a bromine atom and an iodine atom, and a fluorine atom is particularly desirable.

In the present invention, it is preferable that a hydrogen atom, an alkyl group of 1 to 5 carbon atoms or a halogenated alkyl group of 1 to 5 carbon atoms is bonded to the α-position of the acrylate ester, and more preferably a hydrogen atom, an alkyl group of 1 to 5 carbon atoms or a fluorinated alkyl group of 1 to 5 carbon atoms. In terms of industrial availability, a hydrogen atom or a methyl group is the most desirable.

The term “exposure” is used as a general concept that includes irradiation with any form of radiation, including an ArF excimer laser, KrF excimer laser, F₂ excimer laser, extreme ultraviolet rays (EUV), vacuum ultraviolet rays (VUV), electron beam (EB), X-rays or soft X-rays.

The expression “decomposable in an alkali developing solution” means that the group is decomposable by the action of an alkali developing solution (preferably decomposable by action of a 2.38% by weight aqueous solution of tetramethylammonium hydroxide (TMAH) at 23° C.), and exhibits increased alkali solubility in the alkali developing solution.

According to the present invention, there are provided a positive resist composition exhibiting excellent lithography properties and pattern shape, and a method of forming a resist pattern.

### BRIEF DESCRIPTION OF THE DRAWINGS

FIG. 1 is a graph showing the film thickness in Examples 16 to 18 and Comparative Example 5 when the exposure dose has been changed.

### DETAILED DESCRIPTION OF THE INVENTION

### <<Positive Resist Composition>>

The positive resist composition of the present invention includes a base component (A′) that exhibits increased solubility in an alkali developing solution under action of acid, and includes no acid generator component other than the aforementioned base component (A′).

In the positive resist composition, when radial rays are irradiated (when exposure is conducted), a partial structure within a structural unit (a0-1) described later in the component (A′) becomes mobile and acts as an acid, thereby increasing the solubility of the component (A′) in an alkali developing solution by the action of this acid. Therefore, in the formation of a resist pattern, by conducting selective exposure of a resist film formed by using the positive resist composition, the solubility of the exposed portions in an alkali developing solution is increased, whereas the solubility of the unexposed portions of this resist film in an alkali developing solution is unchanged, and hence, a resist pattern can be formed by alkali developing.

Here, the term “base component” refers to an organic compound capable of forming a film.

As the base component, an organic compound having a molecular weight of 500 or more is typically used. When the organic compound has a molecular weight of 500 or more, the organic compound exhibits a satisfactory film-forming ability, and a resist pattern of nano level can be easily formed.

The “organic compound having a molecular weight of 500 or more” can be broadly classified into non-polymers and polymers.

In general, as a non-polymer, any of those compounds having a molecular weight of at least 500 but less than 4,000 may be used. Hereafter, a “low molecular weight compound” refers to a non-polymer having a molecular weight in the range of 500 to less than 4,000.

As a polymer, any of those compounds which have a molecular weight of 1,000 or more is generally used. In the present description and claims, the term “polymeric compound” refers to a polymer having a molecular weight of 1,000 or more. With respect to a polymeric compound, the “molecular weight” is the weight average molecular weight in terms of the polystyrene equivalent value determined by gel permeation chromatography (GPC).

### <Component (A′)>

### [Resin Component (A1)]

The resin component (A1) (hereafter, sometimes referred to as a “component (A1)”) includes a structural unit (a0-1) represented by the aforementioned general formula (a0-1) and a structural unit (a1) containing an acid dissociable, dissolution inhibiting group.

The component (A1) may have a structural unit (a2) derived from an acrylate ester containing a lactone-containing cyclic group, as well as the structural unit (a0-1) and the structural unit (a1).

The component (A1) may also have a structural unit (a3) derived from an acrylate ester containing a polar group-containing aliphatic hydrocarbon group, as well as the structural unit (a0-1) and the structural unit (a1) or the structural unit (a0-1), the structural unit (a1) and the structural unit (a2).

(Structural Unit (a0-1))

The structural unit (a0-1) is a structural unit represented by the above general formula (a0-1).

In formula (a0-1), R¹ represents a hydrogen atom, an alkyl group of 1 to 5 carbon atoms or a halogenated alkyl group of 1 to 5 carbon atoms.

The alkyl group for R¹ is preferably a linear or branched alkyl group of 1 to 5 carbon atoms. Specific examples include a methyl group, ethyl group, propyl group, isopropyl group, n-butyl group, isobutyl group, tert-butyl group, pentyl group, isopentyl group and neopentyl group.

The halogenated alkyl group of 1 to 5 carbon atoms for R¹ is a group in which some or all of the hydrogen atoms of the alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

R¹ is preferably a hydrogen atom, an alkyl group of 1 to 5 carbon atoms or a fluorinated alkyl group of 1 to 5 carbon atoms. In terms of industrial availability, a hydrogen atom or a methyl group is the most desirable.

In formula (a0-1), R² represents a single bond or a divalent linking group.

Preferred examples of the divalent linking group for R² include divalent hydrocarbon groups which may have a substituent, and divalent linking groups containing a hetero atom.

The description that the hydrocarbon group “may have a substituent” means that some or all of the hydrogen atoms within the hydrocarbon group may be substituted with an atom other than a hydrogen atom or with a group.

The hydrocarbon group is preferably an aliphatic hydrocarbon group, but may be an aromatic hydrocarbon group. An “aliphatic hydrocarbon group” refers to a hydrocarbon group that has no aromaticity.

The aliphatic hydrocarbon group may be saturated or unsaturated, but is preferably saturated.

Specific examples of the aliphatic hydrocarbon group include linear and branched aliphatic hydrocarbon groups, and aliphatic hydrocarbon groups containing a ring in the structure thereof.

The linear or branched aliphatic hydrocarbon group is preferably a group of 1 to 10 carbon atoms, more preferably 1 to 8 carbon atoms, still more preferably 1 to 5 carbon atoms, and most preferably 1 or 2 carbon atoms.

The linear aliphatic hydrocarbon group is preferably a linear alkylene group, and specific examples include a methylene group [—CH₂—], ethylene group [—(CH₂)₂—], trimethylene group [—(CH₂)₃—], tetramethylene group [—(CH₂)₄—], or pentamethylene group [—(CH₂)₅—].

As the branched aliphatic hydrocarbon group, a branched alkylene group is preferable, and specific examples include alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, alkylethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—, alkyltrimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The chain-like aliphatic hydrocarbon group may or may not have a substituent. Examples of the substituent include a fluorine atom, a fluorinated alkyl group of 1 to 5 carbon atoms, and an oxygen atom (═O).

Examples of the aliphatic hydrocarbon group containing a ring in the structure thereof include cyclic aliphatic hydrocarbon groups (groups in which two hydrogen atoms have been removed from an aliphatic hydrocarbon ring), and groups in which this type of cyclic aliphatic hydrocarbon group is either bonded to the terminal of an aforementioned chain-like aliphatic hydrocarbon group, or interposed within the chain of an aforementioned chain-like aliphatic hydrocarbon group.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Specific examples of the monocycloalkane include cyclopentane and cyclohexane.

As the polycyclic group, a group in which two hydrogen atoms have been removed from a polycycloalkane of 7 to 12 carbon atoms is preferable. Specific examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

Examples of the aromatic hydrocarbon group include divalent aromatic hydrocarbon groups in which an additional hydrogen atom has been removed from the nucleus of a monovalent aromatic hydrocarbon group such as a phenyl group, biphenyl group, fluorenyl group, naphthyl group, anthryl group or phenanthryl group;

aromatic hydrocarbon groups in which a portion of the carbon atoms that constitute the ring of an aforementioned divalent aromatic hydrocarbon group have been substituted with a hetero atom such as an oxygen atom, sulfur atom or nitrogen atom; and

aromatic hydrocarbon groups in which an additional hydrogen atom has been removed from the nucleus of an arylalkyl group such as a benzyl group, phenethyl group, 1-naphthylmethyl group, 2-naphthylmethyl group, 1-naphthylethyl group or 2-naphthylethyl group.

The aromatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

With respect to a divalent linking group containing a hetero atom, a hetero atom is an atom other than carbon and hydrogen, and examples thereof include an oxygen atom, a nitrogen atom, a sulfur atom and a halogen atom.

Specific examples of the divalent linking group containing a hetero atom include —O—, —C(═O)—, —C(═O)—O—, a carbonate bond (—O—C(═O)—O—), —NH—, —NR⁰⁴— (R⁰⁴ represents an alkyl group), —NH—C(═O)—, and ═N—. Further, a combination of any one of these “divalent linking groups containing a hetero atom” with a divalent hydrocarbon group can also be used. As examples of the divalent hydrocarbon group, the same groups as those described above for the hydrocarbon group which may have a substituent can be given, and a linear or branched aliphatic hydrocarbon group is preferable.

R² may or may not have an acid dissociable portion in the structure thereof. An “acid dissociable portion” refers to a portion within the organic group which is dissociated from the organic group by action of acid generated upon exposure. When R² group has an acid dissociable portion, it preferably has an acid dissociable portion having a tertiary carbon atom.

In the present invention, as the aforementioned R², a single bond, an alkylene group, a divalent aliphatic cyclic group or a divalent linking group containing a hetero atom is preferable, and a single bond, an alkylene group or a divalent linking group containing a hetero atom is more preferable.

When R² represents an alkylene group, the alkylene group preferably has 1 to 10 carbon atoms, more preferably 1 to 6 carbon atoms, still more preferably 1 to 4 carbon atoms, and most preferably 1 to 3 carbon atoms. Specific examples of alkylene groups include the same linear alkylene groups and branched alkylene groups as those listed above.

When R² represents a divalent aliphatic cyclic group, as the aliphatic cyclic group, the same aliphatic cyclic groups as those described above for the “aliphatic hydrocarbon group containing a ring in the structure thereof” can be used.

As the aliphatic cyclic group, a group in which two hydrogen atoms have been removed from cyclopentane, cyclohexane, norbornane, isobornane, adamantane, tricyclodecane or tetracyclododecane is particularly desirable.

When R² represents a divalent linking group containing a hetero atom, preferable examples of linking groups include —O—, —C(═O)—O—, —C(═O)—, —O—C(═O)—O—, —C(═O)—NH—, —NH— (H may be replaced with a substituent such as an alkyl group, an acyl group or the like), —S—, —S(═O)₂—, —S(═O)₂—O—, a group represented by the formula -A-O—B—, and a group represented by the formula -[A-C(═O)—O]ₘ—B—. Herein, each of A and B independently represents a divalent hydrocarbon group which may have a substituent, and m represents an integer of 0 to 3.

When R² represents —NH—, H may be replaced with a substituent such as an alkyl group, an acyl group or the like. The substituent (an alkyl group, an acyl group or the like) preferably has 1 to 10 carbon atoms, more preferably 1 to 8 carbon atoms, and most preferably 1 to 5 carbon atoms.

In the group represented by the formula -A-O—B— or -[A-C(═O)—O]ₘ—B—, A represents a divalent hydrocarbon group which may have a substituent, and B represents a single bond or a divalent hydrocarbon group which may have a substituent. Each of A and B independently represents a divalent hydrocarbon group which may have a substituent.

Examples of divalent hydrocarbon groups for A and B which may have a substituent include the same groups as those described above for the “divalent hydrocarbon group which may have a substituent” usable as R².

As A, a linear aliphatic hydrocarbon group is preferable, more preferably a linear alkylene group, still more preferably a linear alkylene group of 1 to 5 carbon atoms, and a methylene group or an ethylene group is particularly desirable.

As B, a single bond or a linear or branched aliphatic hydrocarbon group is preferable, and a single bond, a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

Further, in the group represented by the formula -[A-C(═O)—O]ₘ—B—, m represents an integer of 0 to 3, preferably an integer of 0 to 2, and more preferably 1 or 2.

As the structural unit (a0-1) in the present invention, structural units represented by general formulas (a0-11) and (a0-12) shown below are particularly desirable.

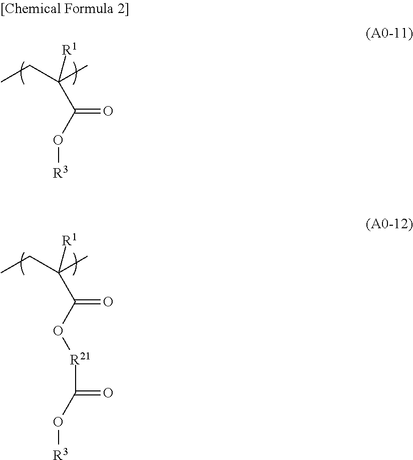

In the formulas, R¹ represents a hydrogen atom, an alkyl group of 1 to 5 carbon atoms or a halogenated alkyl group of 1 to 5 carbon atoms; R²¹ represents a divalent linking group; and R³ represents a cyclic group that contains —SO₂— within the ring skeleton thereof.

In formulas (a0-11) and (a0-12), R¹ is the same as R¹ defined above in general formula (a0-1).

In formulas (a0-11) and (a0-12), R²¹ represents a divalent linking group, and examples of the divalent linking groups include the same divalent linking groups as those described above for R² in general formula (a0-1). The divalent linking group for R²¹ is preferably an alkylene group or a divalent linking group containing a hetero atom, and a methylene group, an ethylene group or a group represented by the formula -[A-C(═O)—O]ₘ—B— is particularly desirable.

Here, examples of the alkylene group and divalent linking group containing a hetero atom include the same groups as those described above for the “alkylene group” and “divalent linking group containing a hetero atom” usable as R². Each of A and B independently represents a divalent hydrocarbon group which may have a substituent, and m represents an integer of 0 to 3.

Examples of divalent hydrocarbon groups for A and B which may have a substituent include the same groups as those described above for the “divalent hydrocarbon group which may have a substituent” usable as R².

As A, a linear aliphatic hydrocarbon group is preferable, more preferably a linear alkylene group, still more preferably a linear alkylene group of 1 to 5 carbon atoms, and a methylene group or an ethylene group is particularly desirable.

As B, a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

Further, in the group represented by the formula -[A-C(═O)—O]ₘ—B—, m represents an integer of 0 to 3, preferably an integer of 0 to 2, more preferably 0 or 1, and most preferably 1.

In formulas (a0-11) and (a0-12), R³ is the same as R³ in general formula (a0-1) to be described later.

In general formula (a0-1), R³ represents a cyclic group containing —SO₂— within the ring skeleton thereof. More specifically, R³ is a cyclic group in which the sulfur atom (S) within the —SO₂— group forms part of the ring skeleton thereof.

The cyclic group for R³ refers to a cyclic group including a ring that contains —SO₂— within the ring skeleton thereof, and this ring is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The cyclic group for R³ may be either a monocyclic group or a polycyclic group.

As R³, a cyclic group containing —O—SO₂— within the ring skeleton thereof, i.e., a sultone ring in which —O—S— within the —O—SO₂— group forms part of the ring skeleton thereof is particularly desirable.

The cyclic group for R³ preferably has 3 to 30 carbon atoms, more preferably 4 to 20 carbon atoms, still more preferably 4 to 15 carbon atoms, and most preferably 4 to 12 carbon atoms.

Herein, the number of carbon atoms refers to the number of carbon atoms constituting the ring skeleton, excluding the number of carbon atoms within a substituent.

The cyclic group for R³ may be either an aliphatic cyclic group or an aromatic cyclic group, and is preferably an aliphatic cyclic group.

Examples of aliphatic cyclic groups for R³ include the aforementioned cyclic aliphatic hydrocarbon groups for R² in which part of the carbon atoms constituting the ring skeleton thereof has been substituted with —SO₂— or —O—SO₂—.

More specifically, examples of monocyclic groups include a monocycloalkane in which one hydrogen atom have been removed therefrom and a —CH₂— group constituting the ring skeleton thereof has been substituted with —SO₂—; and a monocycloalkane in which one hydrogen atom have been removed therefrom and a —CH₂—CH₂— group constituting the ring skeleton thereof has been substituted with —O—SO₂—. Further, examples of polycyclic groups include a polycycloalkane (a bicycloalkane, a tricycloalkane, a tetracycloalkane or the like) in which one hydrogen atom have been removed therefrom and a —CH₂— group constituting the ring skeleton thereof has been substituted with —SO₂—; and a polycycloalkane in which one hydrogen atom have been removed therefrom and a —CH₂—CH₂— group constituting the ring skeleton thereof has been substituted with —O—SO₂—.

The cyclic group for R³ may have a substituent. Examples of the substituent include an alkyl group, an alkoxy group, a halogen atom, a halogenated alkyl group, a hydroxyl group, an oxygen atom (═O), —COOR″, —OC(═O)R″, a hydroxyalkyl group and a cyano group.

The alkyl group for the substituent is preferably an alkyl group of 1 to 6 carbon atoms. The alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or an ethyl group is preferable, and a methyl group is particularly desirable.

As the alkoxy group for the substituent, an alkoxy group of 1 to 6 carbon atoms is preferable. The alkoxy group is preferably a linear alkoxy group or a branched alkoxy group. Specific examples of the alkoxy group include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups for the substituent has been substituted with the aforementioned halogen atoms. As the halogenated alkyl group, a fluorinated alkyl group is preferable, and a perfluoroalkyl group is particularly desirable.

In the —COOR″ group and the —OC(═O)R″ group, R″ preferably represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

In those cases where R″ represents a cyclic alkyl group, the cyclic alkyl group preferably has 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxyl group.

More specific examples of R³ include groups represented by general formulas (3-1) to (3-4) shown below.

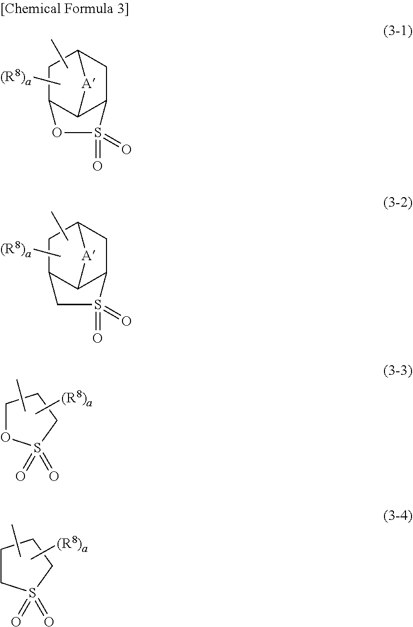

In the formulas, A′ represents an oxygen atom, a sulfur atom, or an alkylene group of 1 to 5 carbon atoms which may contain an oxygen atom or a sulfur atom; a represents an integer of 0 to 2; and R⁸ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—), or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or interposed within the alkylene group. Specific examples of such alkylene groups include —O—CH₂—, —CH₂—O—CH₂—, —S—CH₂—, and —CH₂—S—CH₂—.

A′ is preferably an alkylene group of 1 to 5 carbon atoms or —O—, is more preferably an alkylene group of 1 to 5 carbon atoms, and is most preferably a methylene group.

a represents an integer of 0 to 2, and is most preferably 0.

When a is 2, the plurality of R⁸ may be the same or different from each other.

As the alkyl group, alkoxy group, halogenated alkyl group, —COOR″, —OC(═O)R″ and hydroxyalkyl group for R⁸, the same alkyl groups, alkoxy groups, halogenated alkyl groups, —COOR″, —OC(═O)R″ and hydroxyalkyl groups as those described above as the substituent which the cyclic group for R³ may have can be used.

Specific examples of the cyclic groups represented by the aforementioned general formulas (3-1) to (3-4) are shown below. In the formulas, “Ac” represents an acetyl group.

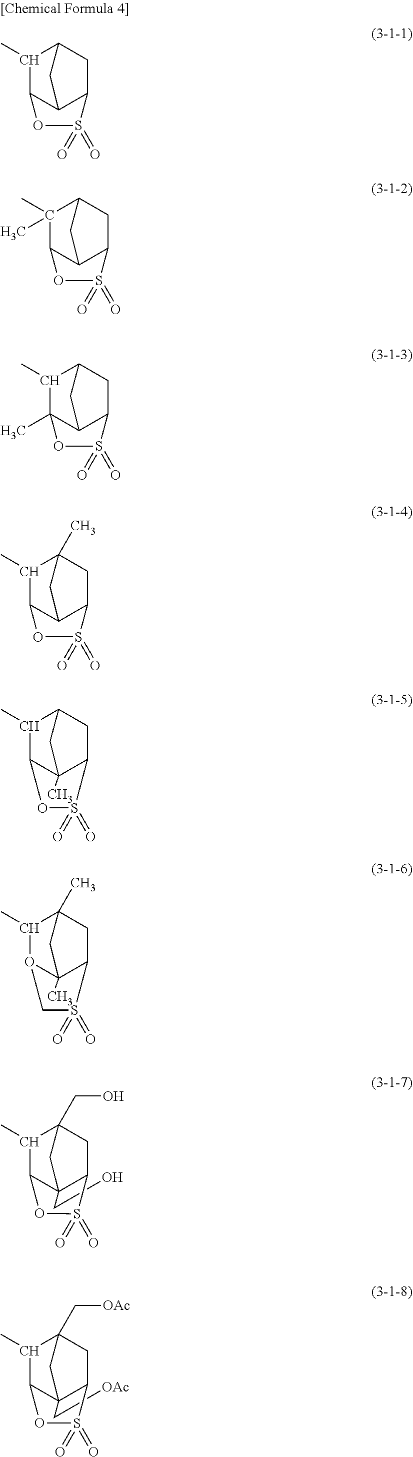

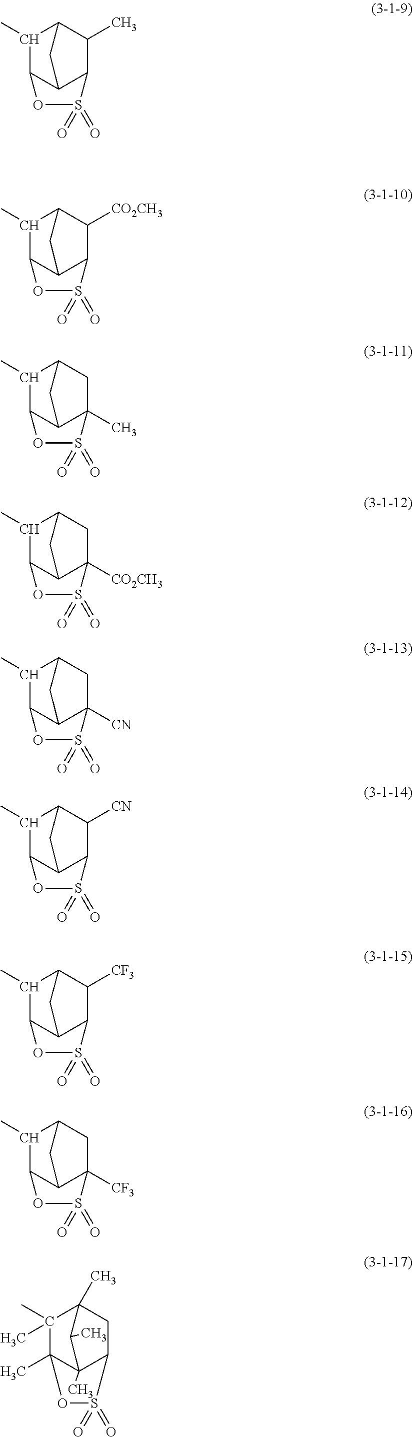

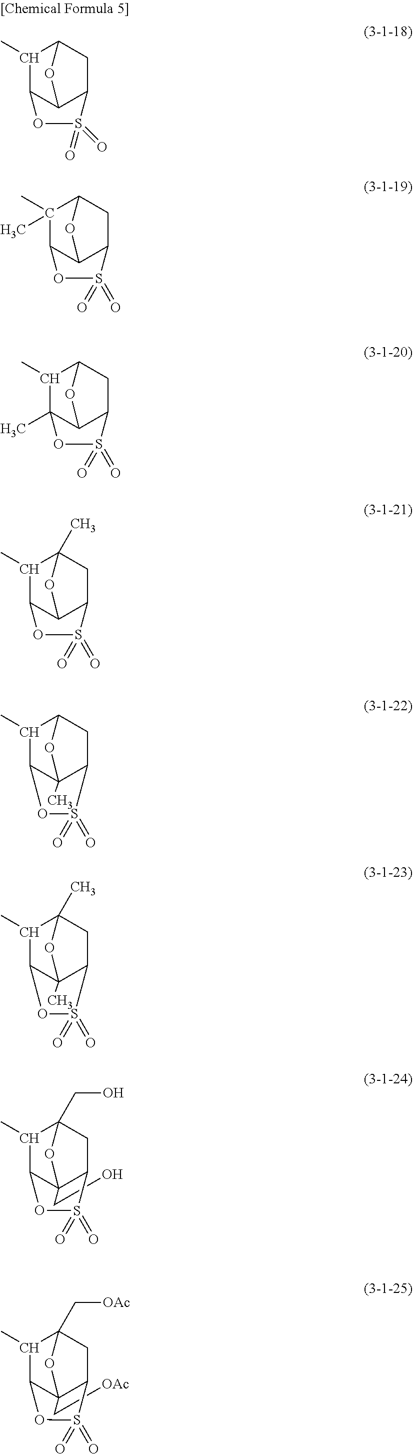

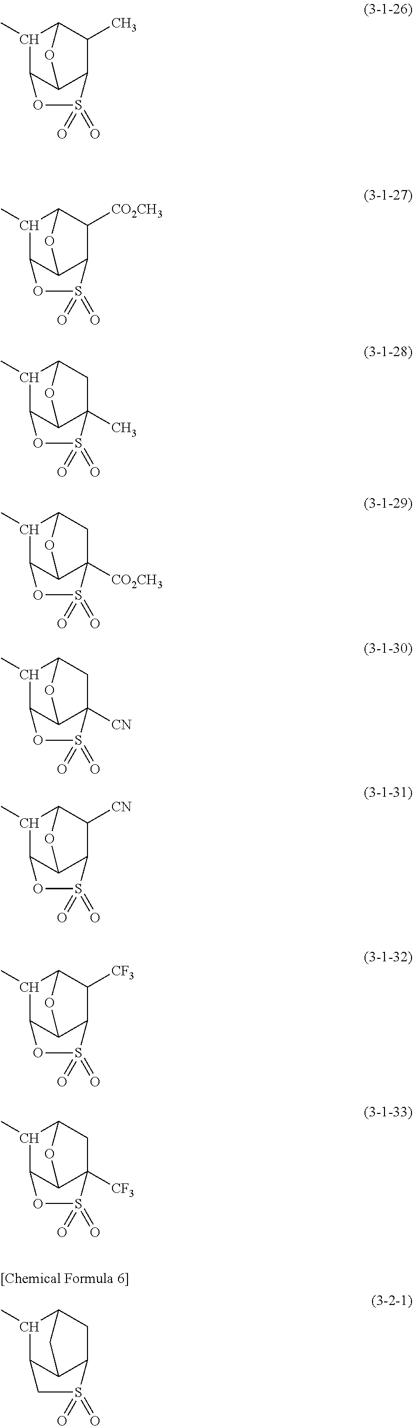

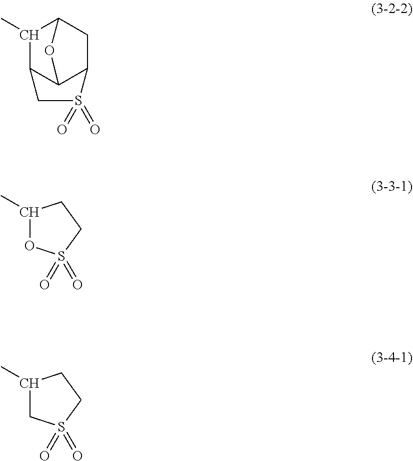

Among the examples shown above, as R³, a cyclic group represented by general formula (3-1), (3-3) or (3-4) above is preferable, and a cyclic group represented by general formula (3-1) above is particularly desirable.

More specifically, as R³, it is preferable to use at least one cyclic group selected from the group consisting of cyclic groups represented by chemical formulas (3-1-1), (3-1-18), (3-3-1) and (3-4-1) above, and a cyclic group represented by chemical formula (3-1-1) above is particularly desirable.

In the present invention, as the structural unit (a0-1), structural units represented by general formulas (a0-11-1), (a0-12-1) and (a0-12-2) shown below are particularly desirable.

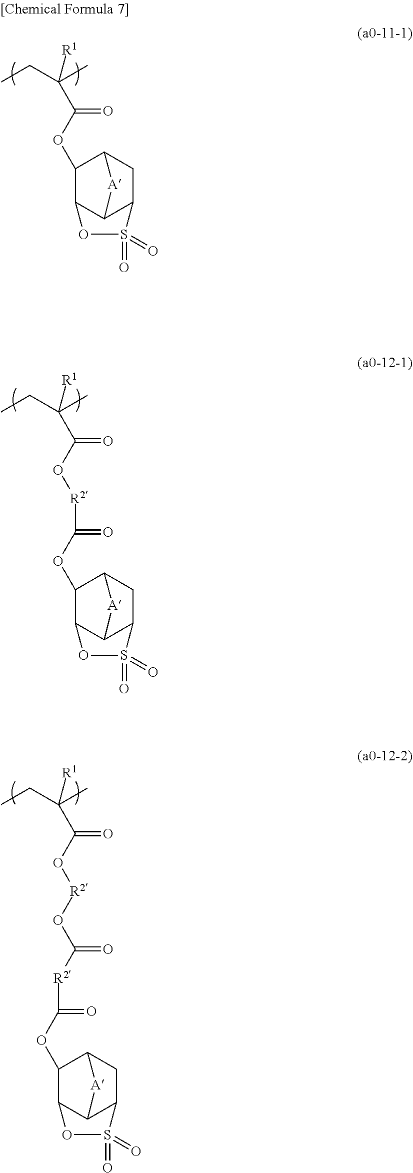

In the formulas, R¹ represents a hydrogen atom, an alkyl group of 1 to 5 carbon atoms or a halogenated alkyl group of 1 to 5 carbon atoms; the plurality of R^{2′} each independently represents a linear or branched alkylene group; and A′ represents an oxygen atom, a sulfur atom, or an alkylene group of 1 to 5 carbon atoms which may contain an oxygen atom or a sulfur atom.

The linear or branched alkylene group for R^{2′} preferably has 1 to 10 carbon atoms, more preferably 1 to 8 carbon atoms, still more preferably 1 to 5 carbon atoms, still more preferably 1 to 3 carbon atoms, and most preferably 1 or 2 carbon atoms.

A′ is preferably a methylene group, an oxygen atom (—O—) or a sulfur atom (—S—).

In the present invention, the longer the R² moiety in formula (a0-1) above, the higher the sensitivity. Therefore, it is preferable to use a structural unit as those represented by formula (a0-12-2) above when high sensitivity is required, and to use a structural unit as those represented by formula (a0-11-1) above when low sensitivity is required.

As the structural unit (a0-1), one type of structural unit may be used alone, or two or more types of structural units may be used in combination.

In terms of achieving excellent properties with respect to MEF, the shape of a formed resist pattern (for example, rectangularity in the case of a line pattern and circularity in the case of a hole pattern), in-plane uniformity of contact holes (CDU), line width roughness (LWR) and the like in the formation of a resist pattern using a positive resist composition containing the component (A1), the amount of the structural unit (a0-1) within the component (A1), based on the combined total of all structural units constituting the component (A1) is preferably 1 to 70 mol %, more preferably 5 to 65 mol %, and still more preferably 10 to 60 mol %.

Further, because the structural unit (a0-1) in the present invention acts like conventional acid generators, the sensitivity of the obtained resist composition can be determined by appropriately adjusting the amount of the structural unit (a0-1) within the component (A1) or the component (A′). More specifically, it is preferable to increase the amount of the structural unit (a0-1) when a high level of sensitivity is required for the resist composition, and to reduce the amount of the structural unit (a0-1) when a low level of sensitivity is required for the resist composition.

(Structural Unit (a1))

The structural unit (a1) is a structural unit containing an acid dissociable, dissolution inhibiting group.

As the acid dissociable, dissolution inhibiting group in the structural unit (a1), any of the groups that have been proposed as acid dissociable, dissolution inhibiting groups for the base resins of chemically amplified resists can be used, provided the group has an alkali dissolution-inhibiting effect that renders the entire component (A1) insoluble in an alkali developing solution prior to dissociation, and then following dissociation by action of acid, increases the solubility of the entire component (A1) in the alkali developing solution. Generally, groups that form either a cyclic or chain-like tertiary alkyl ester with the carboxyl group of the (meth)acrylic acid or the like, and acetal-type acid dissociable, dissolution inhibiting groups such as alkoxyalkyl groups are widely known.

Here, a tertiary alkyl ester describes a structure in which an ester is formed by substituting the hydrogen atom or the like of a carboxyl group of the (meth)acrylic acid or the like with a chain-like or cyclic tertiary alkyl group, and a tertiary carbon atom within the chain-like or cyclic tertiary alkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable, dissolution inhibiting groups”.

Examples of these tertiary alkyl ester-type acid dissociable, dissolution inhibiting groups include aliphatic branched, acid dissociable, dissolution inhibiting groups and cyclic group-containing acid dissociable, dissolution inhibiting groups.

The cyclic group may be either an aliphatic cyclic group or an aromatic cyclic group.

In the description of the present invention, the term “aliphatic branched” refers to a branched structure having no aromaticity.

The “aliphatic branched acid dissociable, dissolution inhibiting group” is not limited to structures constituted of only carbon atoms and hydrogen atoms (not limited to hydrocarbon groups), but is preferably a hydrocarbon group.

Further, the “hydrocarbon group” may be either saturated or unsaturated, but is preferably saturated.

Examples of aliphatic branched, acid dissociable, dissolution inhibiting groups include tertiary alkyl groups of 4 to 8 carbon atoms, and specific examples include a tert-butyl group, tert-pentyl group and tert-heptyl group.

The term “aliphatic cyclic group” refers to a monocyclic group or polycyclic group that has no aromaticity.

The “aliphatic cyclic group” within the structural unit (a1) has 3 to 20 carbon atoms and may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring structure of the “aliphatic cyclic group” exclusive of substituents is not limited to structures constituted of only carbon and hydrogen (not limited to hydrocarbon groups), but is preferably a hydrocarbon group, and the number of carbon atoms therein is preferably within a range from 5 to 15.

Further, the “hydrocarbon group” may be either saturated or unsaturated, but is preferably saturated. Furthermore, the “aliphatic cyclic group” is preferably a polycyclic group.

Examples of such aliphatic cyclic groups include groups in which one or more hydrogen atoms have been removed from a monocycloalkane or a polycycloalkane such as a bicycloalkane, tricycloalkane or tetracycloalkane, and which may or may not be substituted with an alkyl group of 1 to 5 carbon atoms, a fluorine atom or a fluorinated alkyl group. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

Examples of the aromatic cyclic groups include aromatic cyclic groups of 6 to 20 carbon atoms. Specific examples include groups in which one hydrogen atom has been removed from naphthalene, anthracene, phenanthrene or pyrene or the like. Specific examples include a 1-naphthyl group, a 2-naphthyl group, a 1-anthryl group, a 2-anthryl group, a 1-phenanthryl group, a 2-phenanthryl group, a 3-phenanthryl group and a 1-pyrenyl group, and of these, a 2-naphthyl group is particularly preferred industrially.

Examples of the cyclic group-containing acid dissociable, dissolution inhibiting group include groups having a tertiary carbon atom within the ring structure of a cyclic alkyl group. Specific examples include a 2-methyl-2-adamantyl group and a 2-ethyl-2-adamantyl group. Alternatively, as shown in the following general formulas (a1″-1) to (a1″-9), groups having a cyclic group such as an adamantyl group, cyclohexyl group, cyclopentyl group, norbornyl group, tricyclodecyl group, tetracyclododecyl group, naphthyl group or phenyl group, and a branched alkylene group having a tertiary carbon atom bonded to the cyclic group, may also be used.

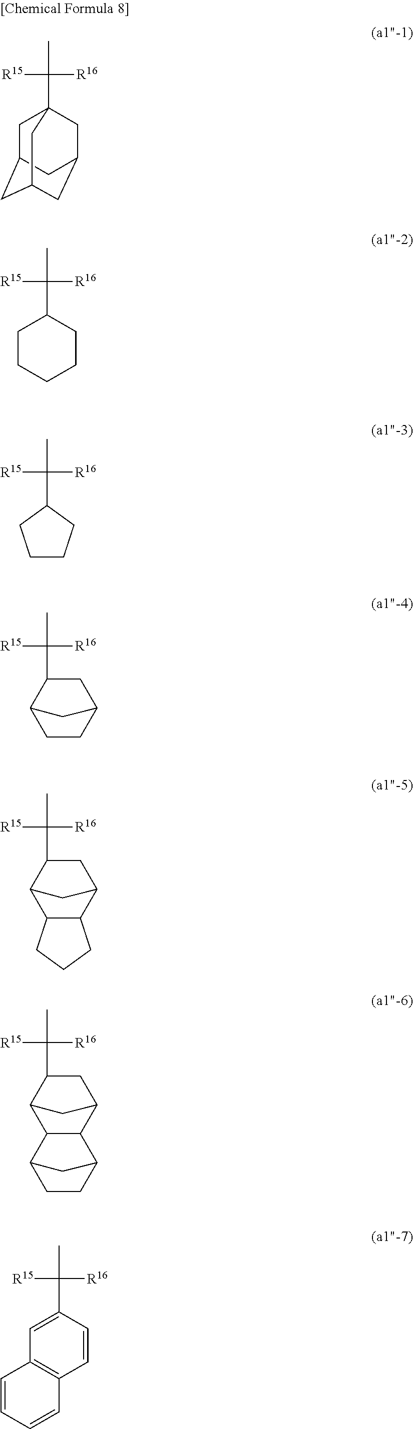

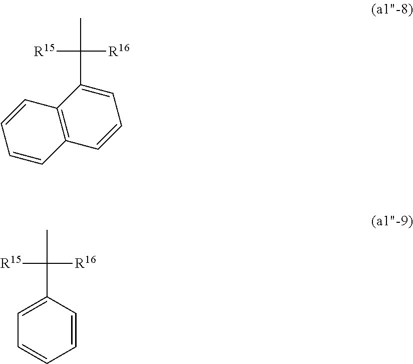

In the formulas, each of R¹⁵ and R¹⁶ represents an alkyl group (which may be either linear or branched, and preferably has 1 to 5 carbon atoms).

The tertiary alkyl ester-type acid dissociable, dissolution inhibiting group is preferably a group represented by formula (p0) shown below, and more preferably a group represented by formula (p0-1) shown below.

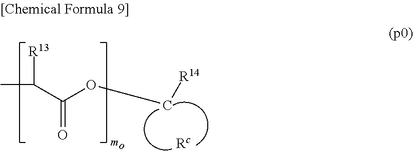

In the formula, m₀ represents 0 or 1; R¹³ represents a hydrogen atom or a methyl group; R¹⁴ represents an alkyl group (which may be either linear or branched, and preferably has 1 to 5 carbon atoms); and R^{c} represents a group that forms an aliphatic cyclic group with the carbon atoms to which this R^{c} group is bonded.

Examples of R^{c} include the same aliphatic cyclic groups as those described above, and a polycyclic aliphatic cyclic group is preferred.

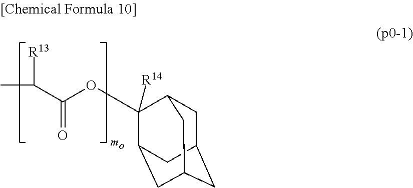

In the formula, m₀ represents 0 or 1; R¹³ represents a hydrogen atom or a methyl group; and R¹⁴ represents an alkyl group (which may be either linear or branched, and preferably has 1 to 5 carbon atoms).

R¹⁴ is more preferably an alkyl group of 1 to 3 carbon atoms, and still more preferably a methyl group or an ethyl group.

An “acetal-type acid dissociable, dissolution inhibiting group” generally substitutes a hydrogen atom at the terminal of an alkali-soluble group such as a carboxyl group or a hydroxyl group, so as to be bonded with an oxygen atom. When acid is generated upon exposure, the generated acid acts to break the bond between the acetal-type acid dissociable, dissolution inhibiting group and the oxygen atom to which the acetal-type, acid dissociable, dissolution inhibiting group is bonded.

Examples of acetal-type acid dissociable, dissolution inhibiting groups include groups represented by general formula (p1) shown below.

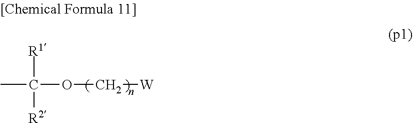

In formula (p1), each of R^{1′} and R^{2′} independently represents a hydrogen atom or an alkyl group of 1 to 5 carbon atoms; n represents an integer of 0 to 3; and W represents an aliphatic cyclic group or an alkyl group of 1 to 5 carbon atoms.

In general formula (p1) above, n represents an integer of 0 to 3, and is preferably an integer of 0 to 2, more preferably 0 or 1, and most preferably 0.

Examples of the alkyl group of 1 to 5 carbon atoms for R^{1′} and R^{2′} include the same groups as those listed above for the alkyl group of 1 to 5 carbon atoms for R¹ within formula (a0-1), and a methyl group or an ethyl group is preferable, and a methyl group is particularly desirable.

In the present invention, it is preferable that at least one of R^{1′} and R^{2′} be a hydrogen atom. That is, it is preferable that the acid dissociable, dissolution inhibiting group (p1) is an acetal-type acid dissociable, dissolution inhibiting group represented by general formula (p1-1) shown below.

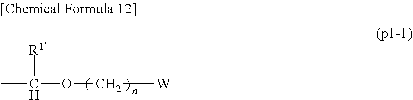

In formula (p1-1), R^{1′} represents a hydrogen atom or an alkyl group of 1 to 5 carbon atoms; n represents an integer of 0 to 3; and W represents an aliphatic cyclic group or an alkyl group of 1 to 5 carbon atoms.

Examples of the alkyl group of 1 to 5 carbon atoms for W include the same groups as those listed above for the alkyl group of 1 to 5 carbon atoms for R¹ within formula (a0-1).

As the aliphatic cyclic group for W, any of the aliphatic monocyclic/polycyclic groups which have been proposed for conventional ArF resists and the like can be appropriately selected for use. For example, the same “aliphatic cyclic groups” as those described above in connection with the “tertiary alkyl ester-type acid dissociable, dissolution inhibiting groups” can be used.

Preferred examples of acetal-type acid dissociable, dissolution inhibiting groups represented by general formula (p1-1) above include groups represented by formulas (11) to (24) shown below.

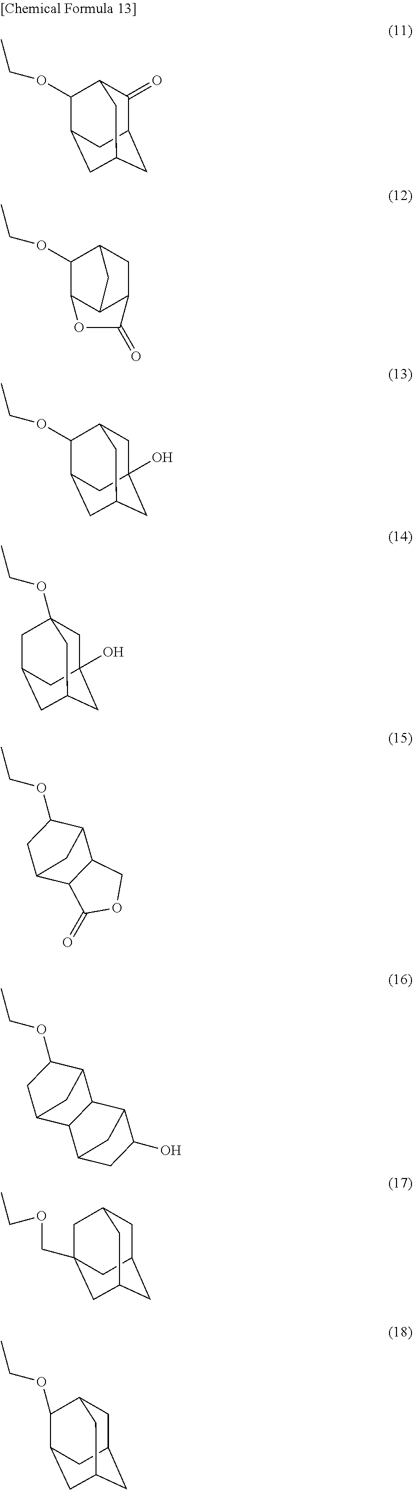

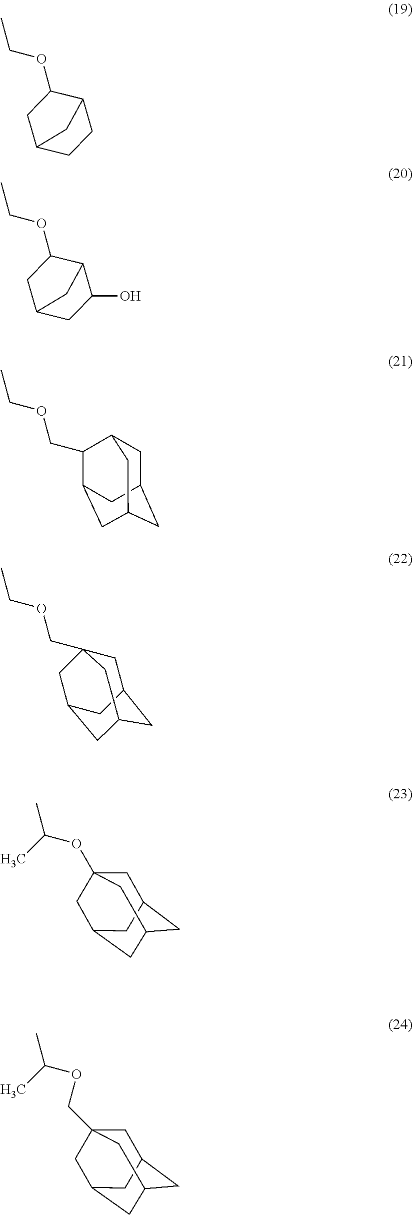

Further, as the acetal-type, acid dissociable, dissolution inhibiting group, groups represented by general formula (p2) shown below can also be used.

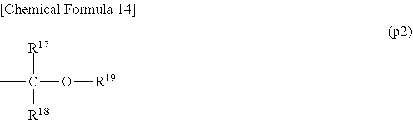

In formula (p2), R¹⁷ and R¹⁸ each independently represents a linear or branched alkyl group or a hydrogen atom; and R¹⁹ represents a linear, branched or cyclic alkyl group. Alternatively, each of R¹⁷ and R¹⁹ may independently represent a linear or branched alkylene group, wherein R¹⁷ is bonded to R¹⁹ to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cyclic alkyl group, it preferably has 4 to 15 carbon atoms, more preferably 4 to 12 carbon atoms, and most preferably 5 to 10 carbon atoms. Examples of the cyclic alkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane. Of these, a group in which one or more hydrogen atoms have been removed from adamantane is preferable.

Further, in the above formula, each of R¹⁷ and R¹⁹ may independently represent a linear or branched alkylene group (and preferably an alkylene group of 1 to 5 carbon atoms), wherein R¹⁹ is bonded to R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include a tetrahydropyranyl group and tetrahydrofuranyl group.

In the present invention, the structural unit (a1) may be a structural unit (a11) derived from an acrylate ester containing an acid dissociable, dissolution inhibiting group, or may be a structural unit (a12) in which either at least a portion of the hydroxyl group hydrogen atoms of a structural unit derived from hydroxystyrene or the hydrogen atom of the —C(═O)OH group of a structural unit derived from a vinylbenzoic acid have been protected with a substituent containing an acid dissociable, dissolution inhibiting group.

The structural units (a11) and (a12) will be described below.

(Structural Unit (a11))

The structural unit (a11) is a structural unit derived from an acrylate ester containing an acid dissociable, dissolution inhibiting group.

As the structural unit (a11), it is preferable to use at least one member selected from the group consisting of structural units represented by general formula (a11-0-1) shown below and structural units represented by general formula (a11-0-2) shown below.

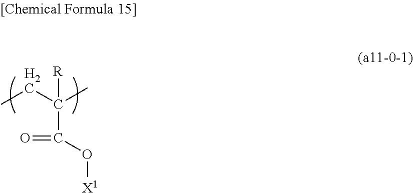

In the formula, R represents a hydrogen atom, an alkyl group of 1 to 5 carbon atoms or a halogenated alkyl group of 1 to 5 carbon atoms, and X¹ represents an acid dissociable, dissolution inhibiting group.

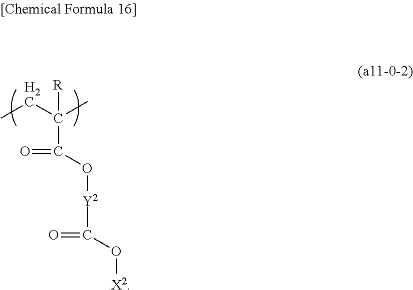

In the formula, R represents a hydrogen atom, an alkyl group of 1 to 5 carbon atoms or a halogenated alkyl group of 1 to 5 carbon atoms; X² represents an acid dissociable, dissolution inhibiting group; and Y² represents a divalent linking group.

In general formula (a11-0-1) shown above, the alkyl group of 1 to 5 carbon atoms or halogenated alkyl group of 1 to 5 carbon atoms for R is the same as defined above for the alkyl group of 1 to 5 carbon atoms or halogenated alkyl group of 1 to 5 carbon atoms that may be bonded to the α-position of an aforementioned acrylate ester.

X¹ is not particularly limited, as long as it is an acid dissociable, dissolution inhibiting group. Examples thereof include the aforementioned tertiary alkyl ester-type acid dissociable, dissolution inhibiting groups and acetal-type acid dissociable, dissolution inhibiting groups, and tertiary alkyl ester-type acid dissociable, dissolution inhibiting groups are preferable.

In general formula (a11-0-2), R is the same as defined for R in general formula (a11-0-1) above.

X² is the same as defined for X¹ in general formula (a11-0-1).

The divalent linking group for Y² is the same as defined above for R² in general formula (a0-1).

Specific examples of the structural unit (a11) include structural units represented by general formulas (a11-1) to (a11-4) shown below.

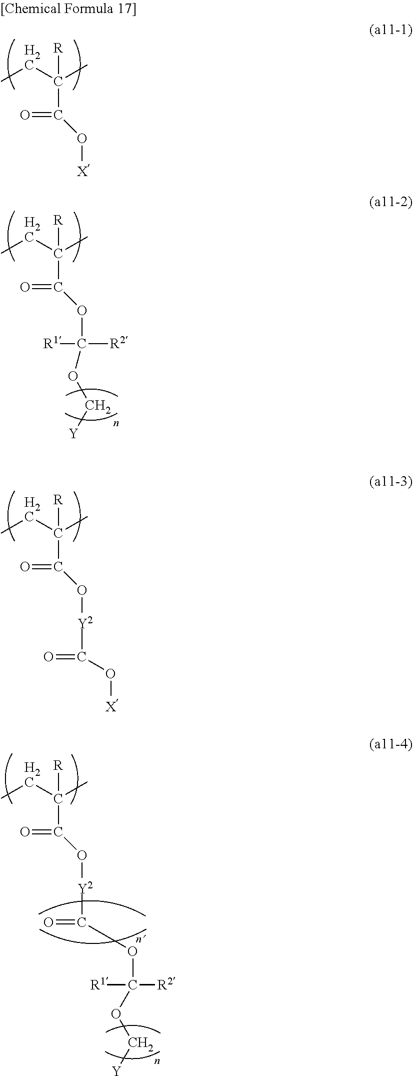

In the formulas, X′ represents a tertiary alkyl ester-type acid dissociable, dissolution inhibiting group; Y represents an alkyl group of 1 to 5 carbon atoms or an aliphatic cyclic group; n represents an integer of 0 to 3; n′ represents 0 or 1; Y² represents a divalent linking group; R represents a hydrogen atom, an alkyl group of 1 to 5 carbon atoms or a halogenated alkyl group of 1 to 5 carbon atoms; and each of R^{1′} and R^{2′} independently represents a hydrogen atom or an alkyl group of 1 to 5 carbon atoms.

In the formulas, examples of the tertiary alkyl ester-type acid dissociable, dissolution inhibiting group for X′ include the same groups as the “tertiary alkyl ester-type acid dissociable, dissolution inhibiting groups” listed above.

Examples of R^{1′}, R^{2′}, n and Y include the same groups and numbers as those listed above for R^{1′}, R^{2′}, n and W in general formula (p1) described above in connection with the “acetal-type acid dissociable, dissolution inhibiting groups”.

As Y², the same groups as those listed above for R² in general formula (a0-1) may be used.

Specific examples of structural units represented by general formula (a11-1) to (a11-4) are shown below.

In each of the following formulas, R^{α} represents a hydrogen atom, a methyl group or a trifluoromethyl group.

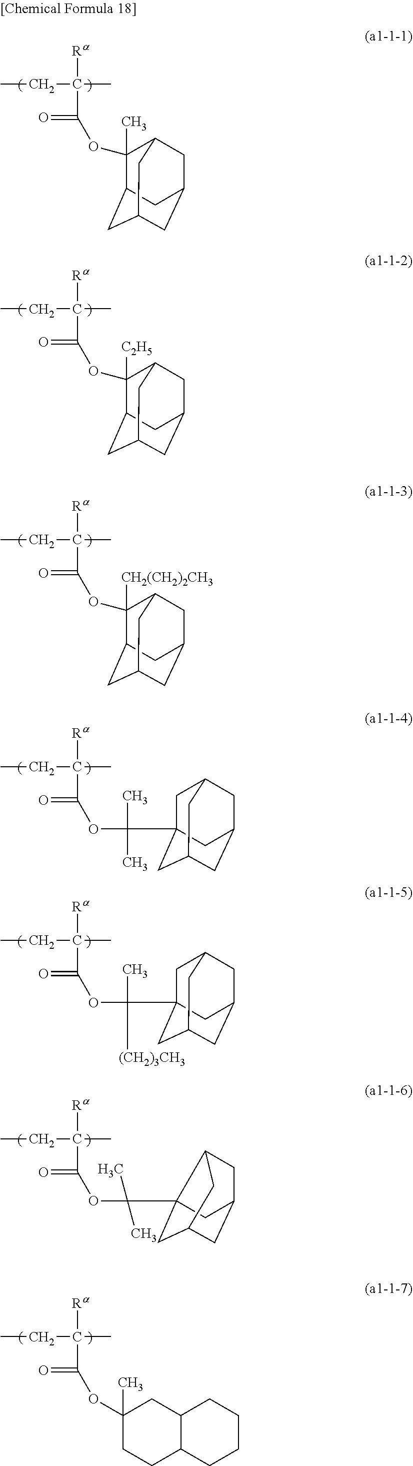

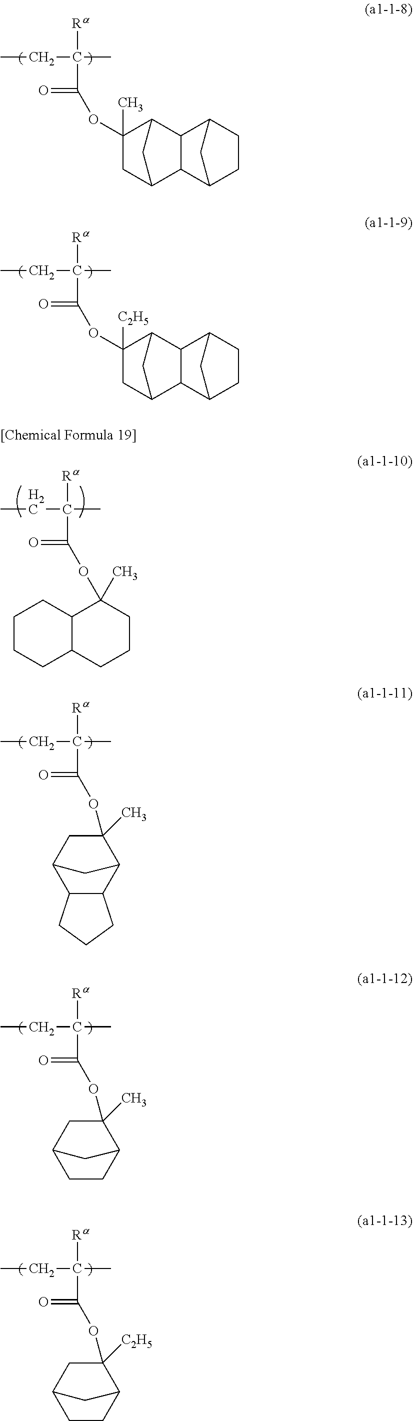

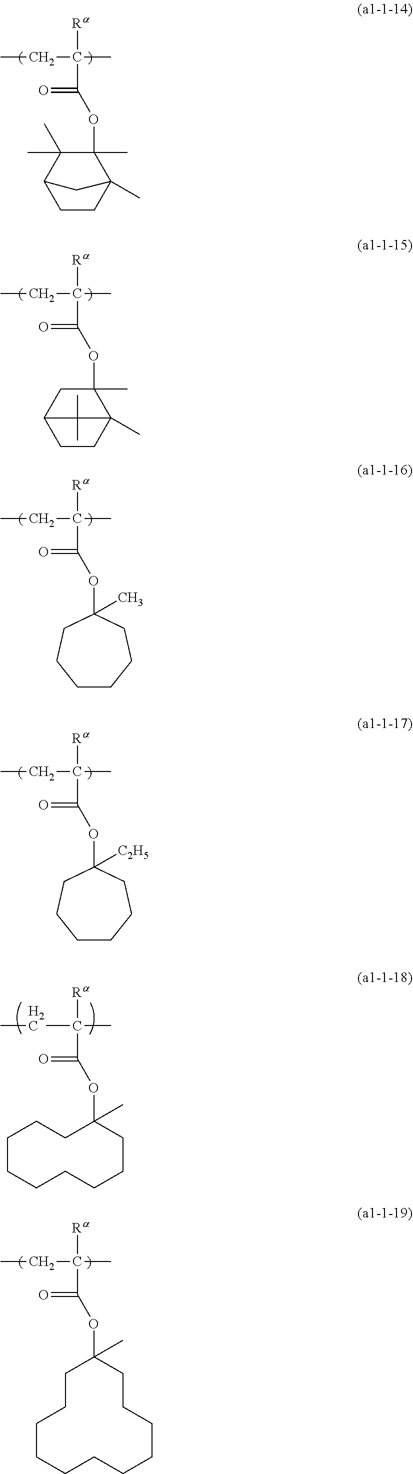

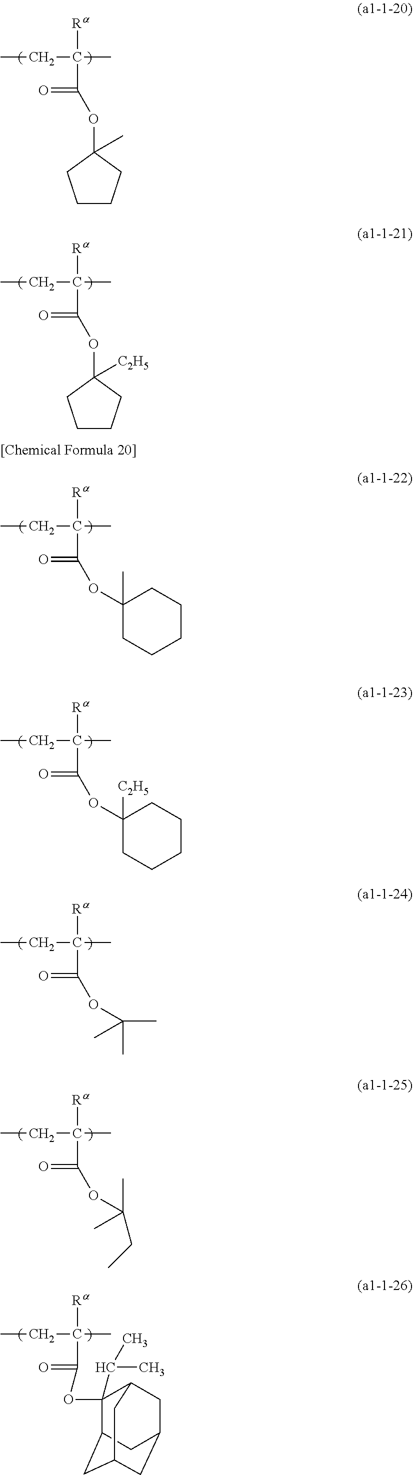

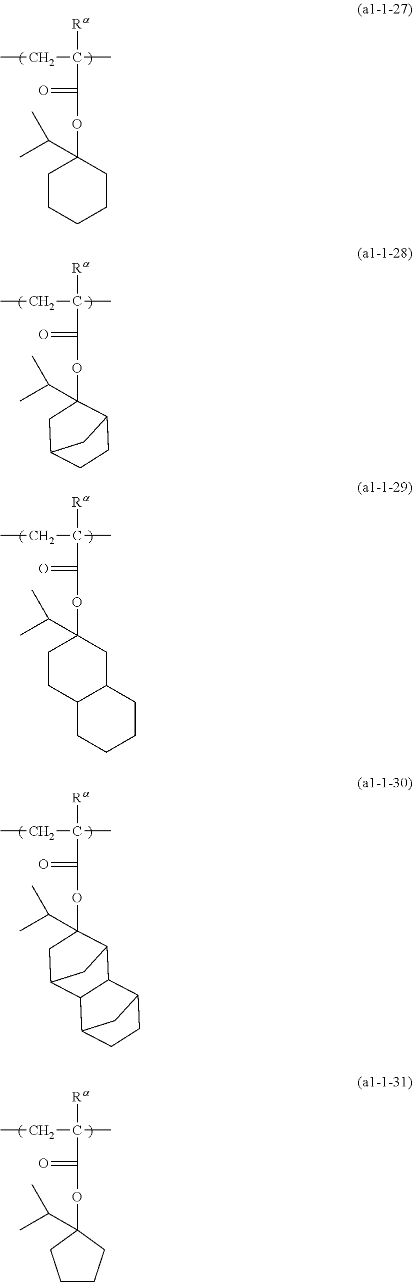

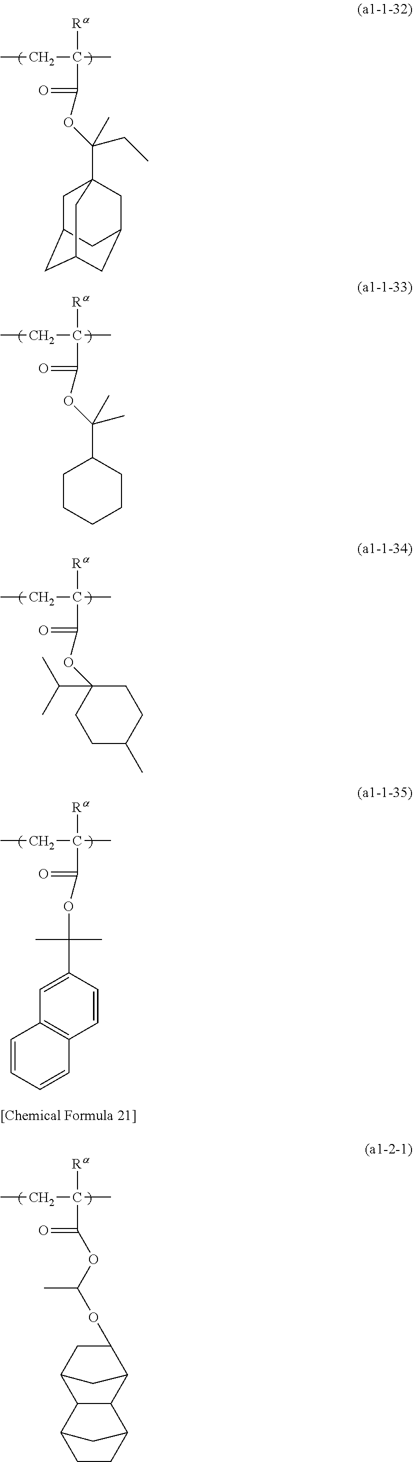

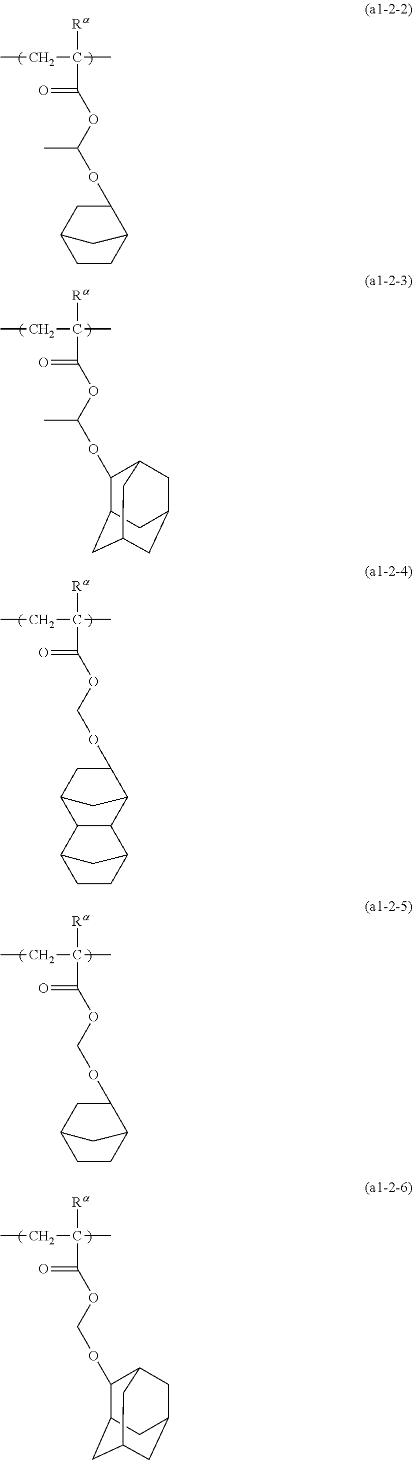

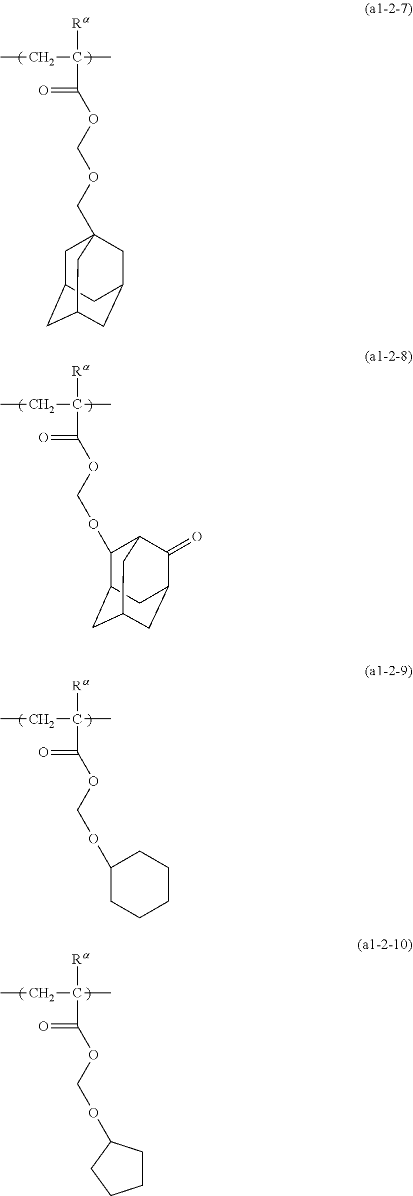

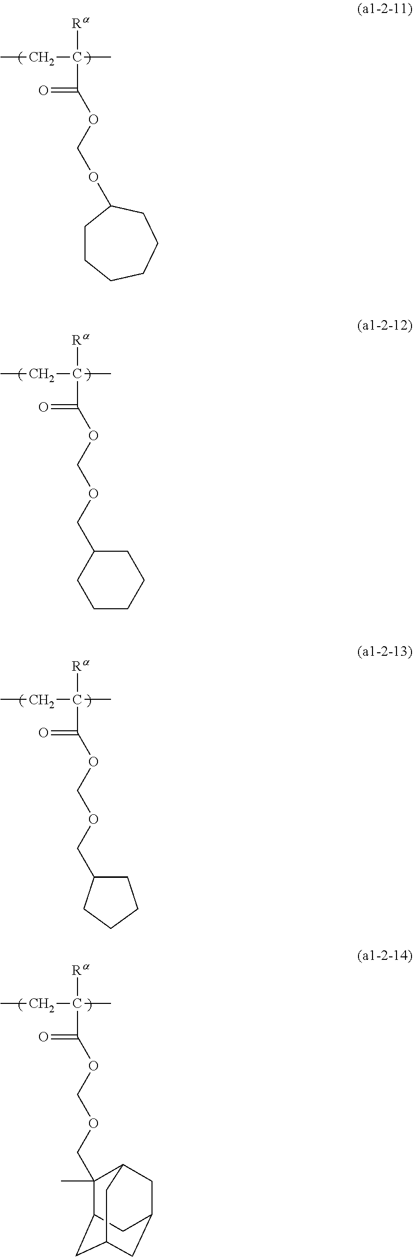

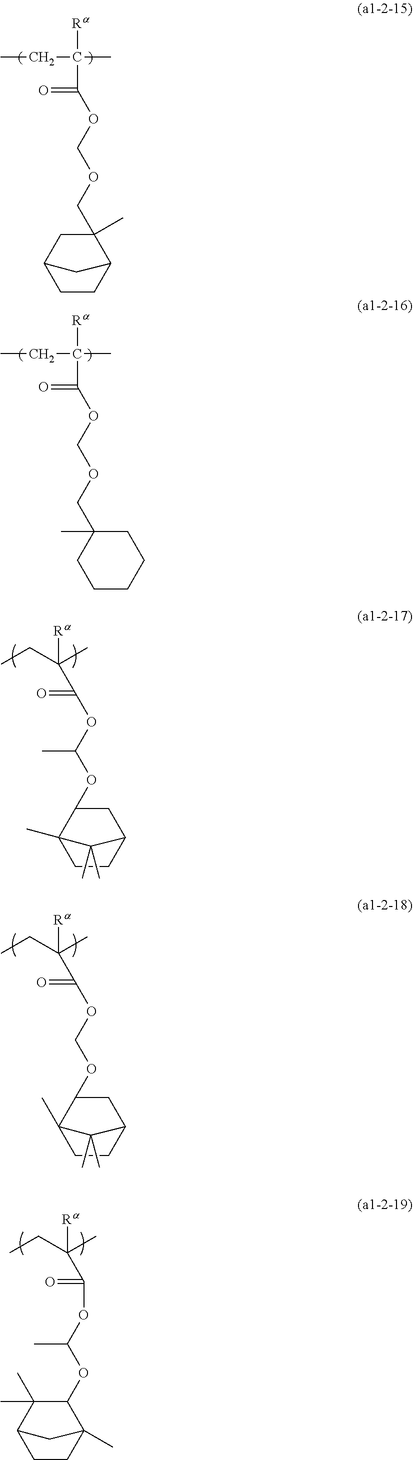

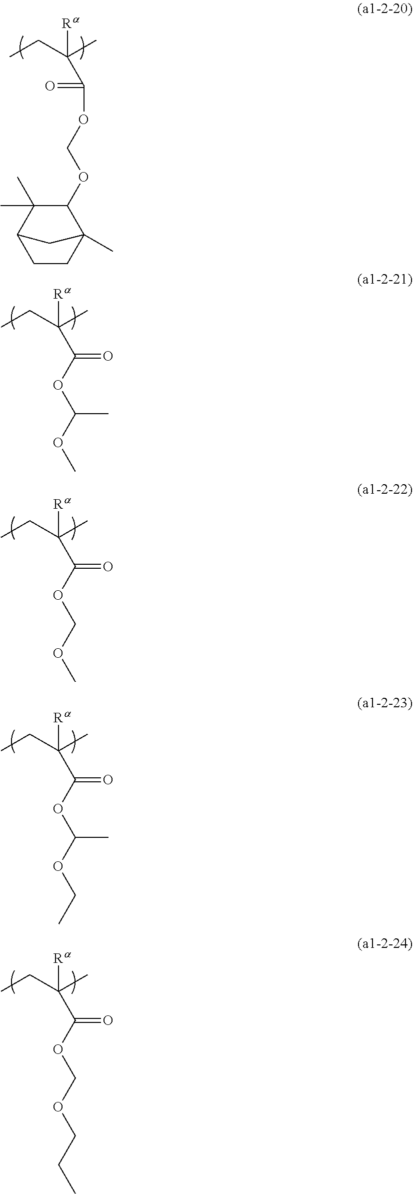

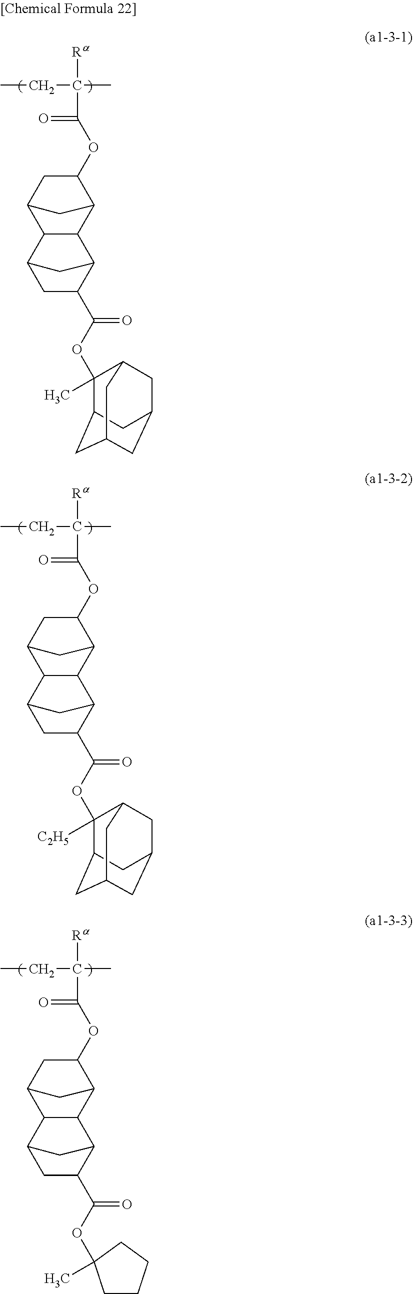

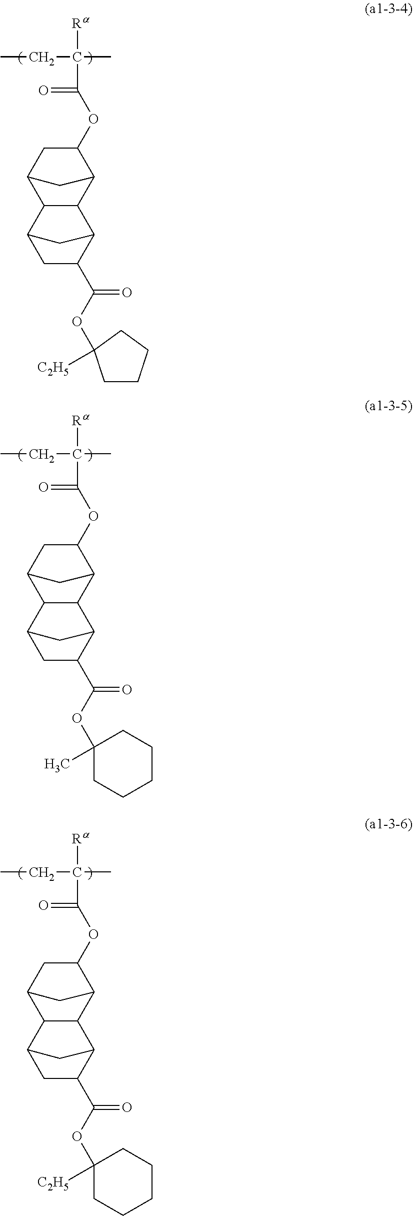

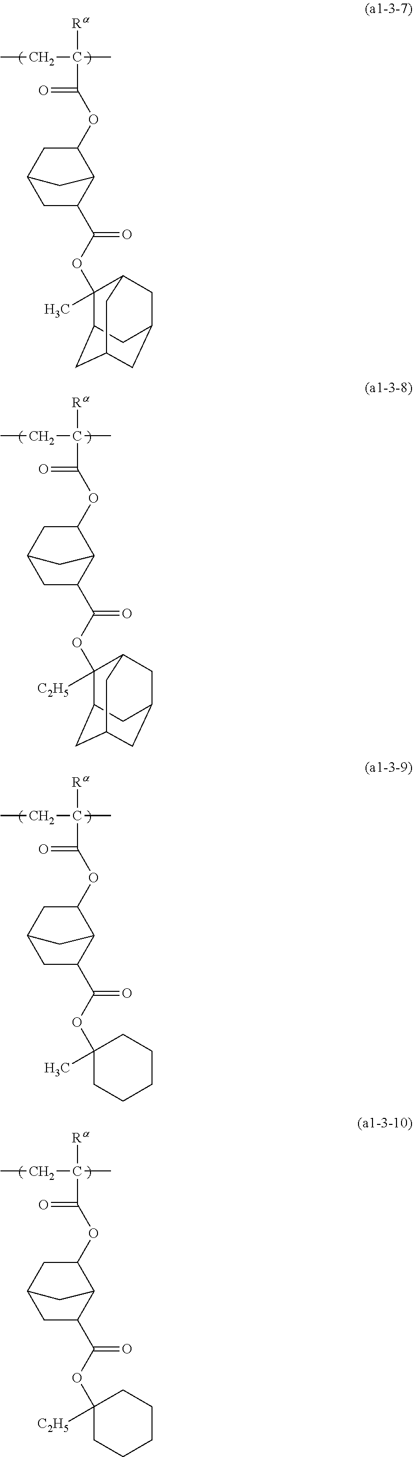

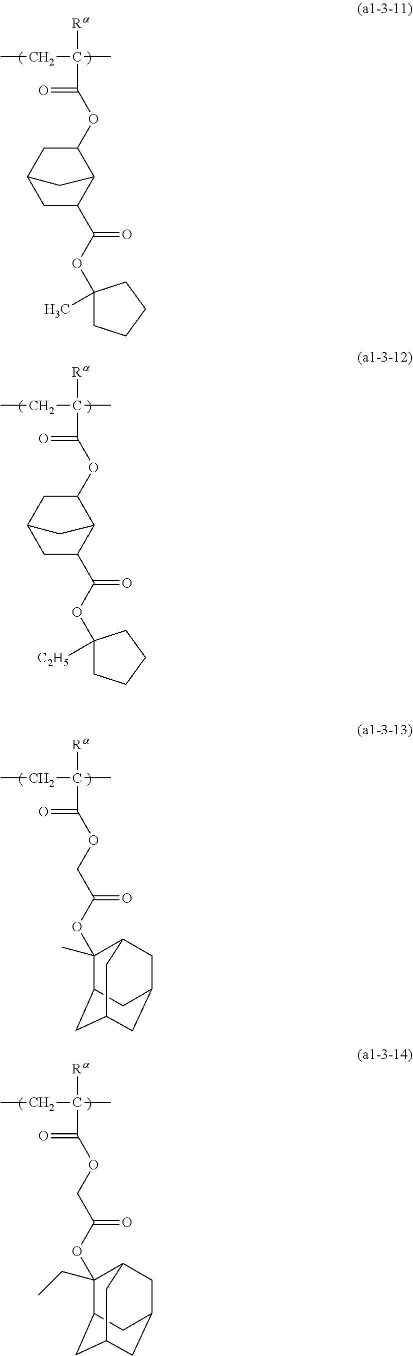

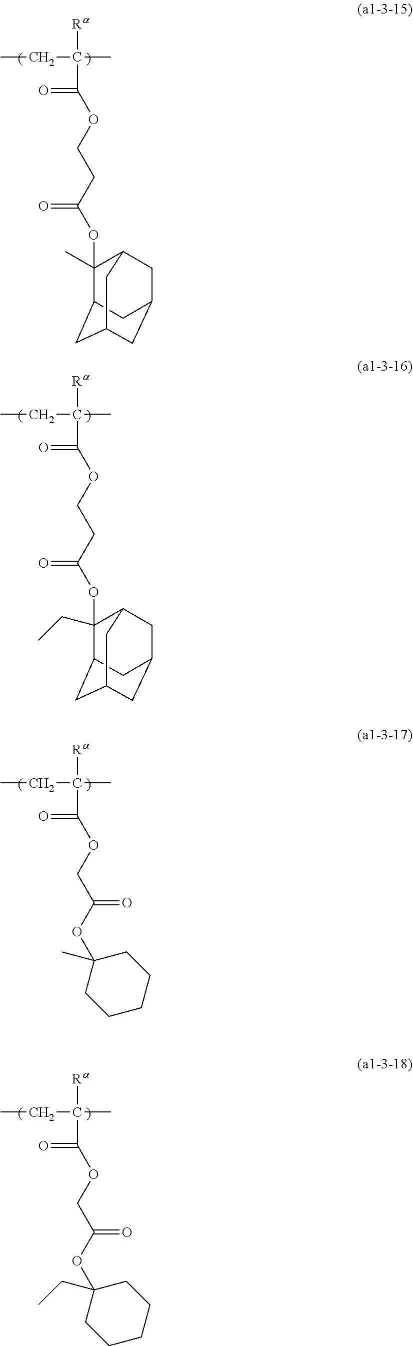

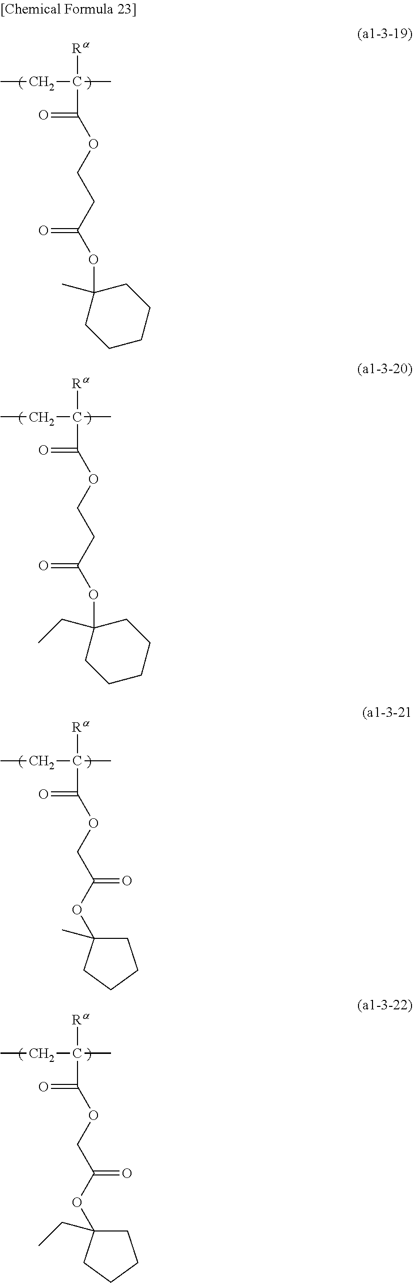

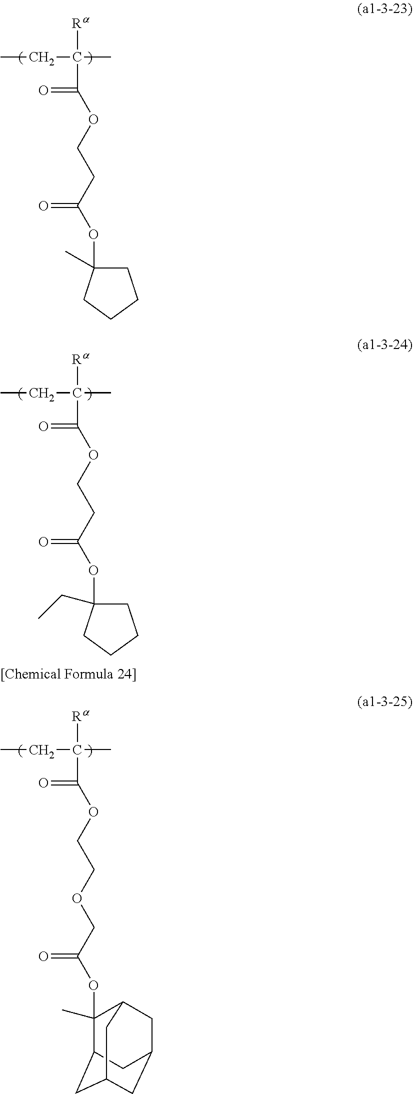

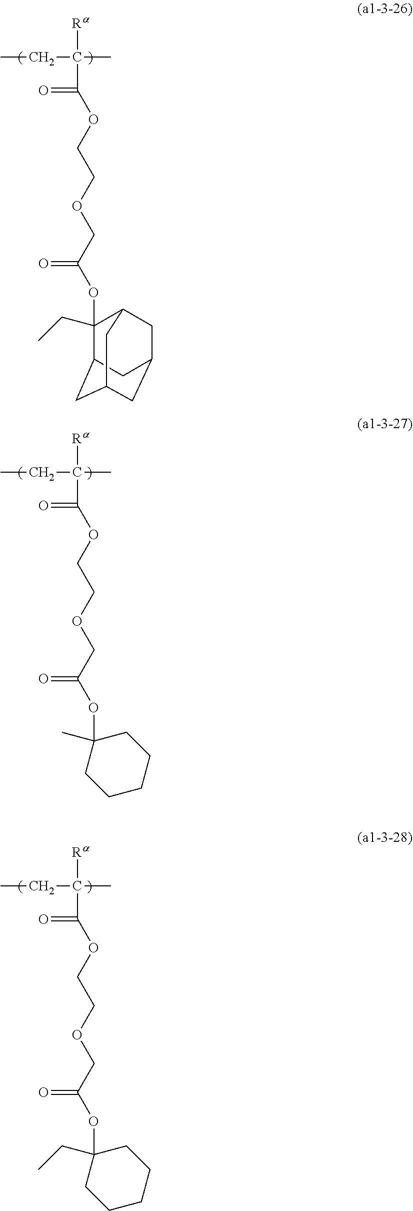

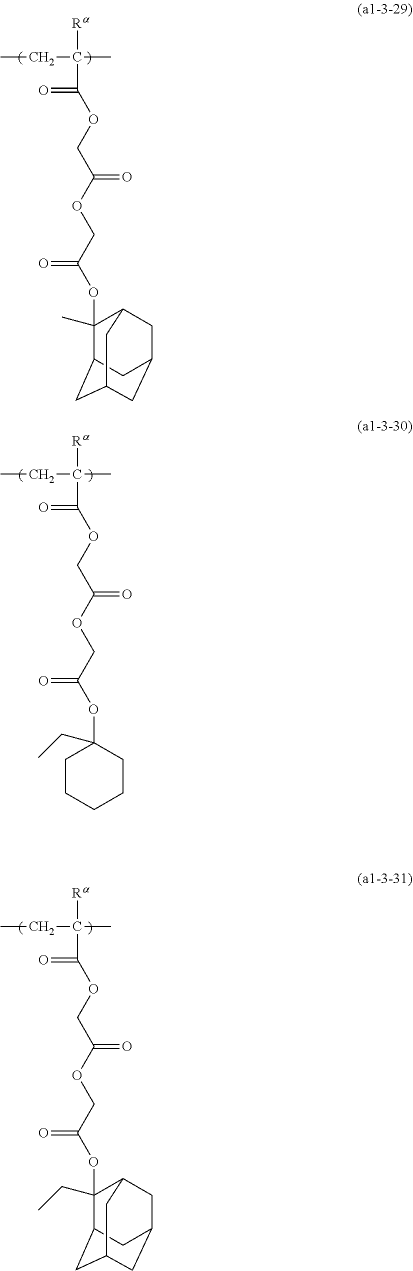

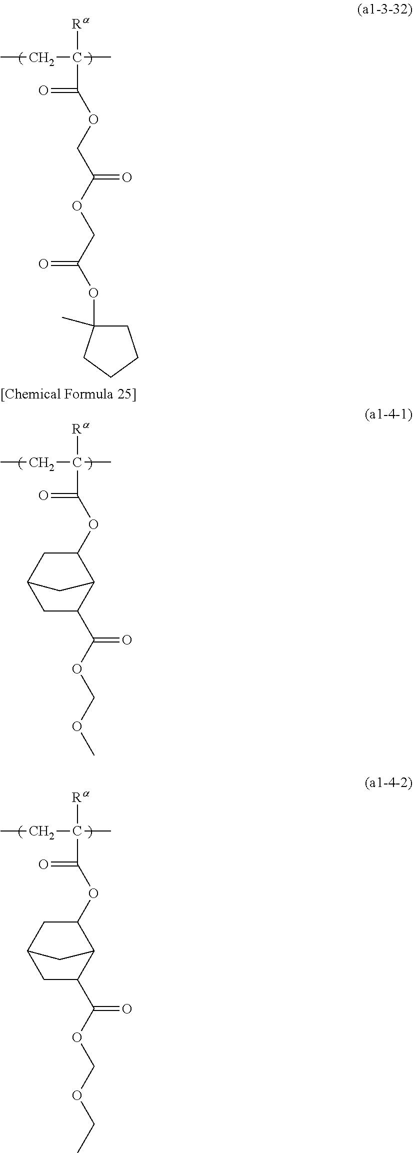

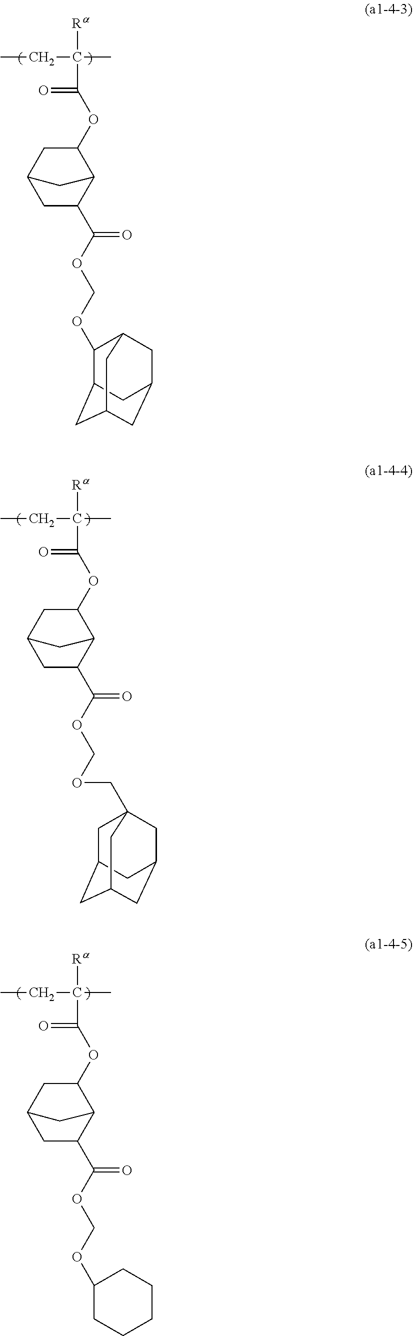

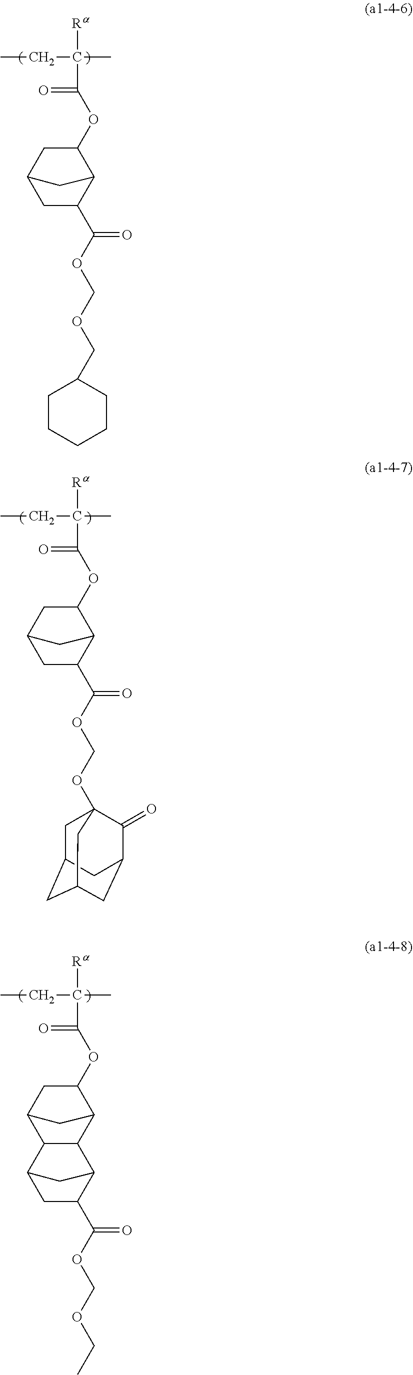

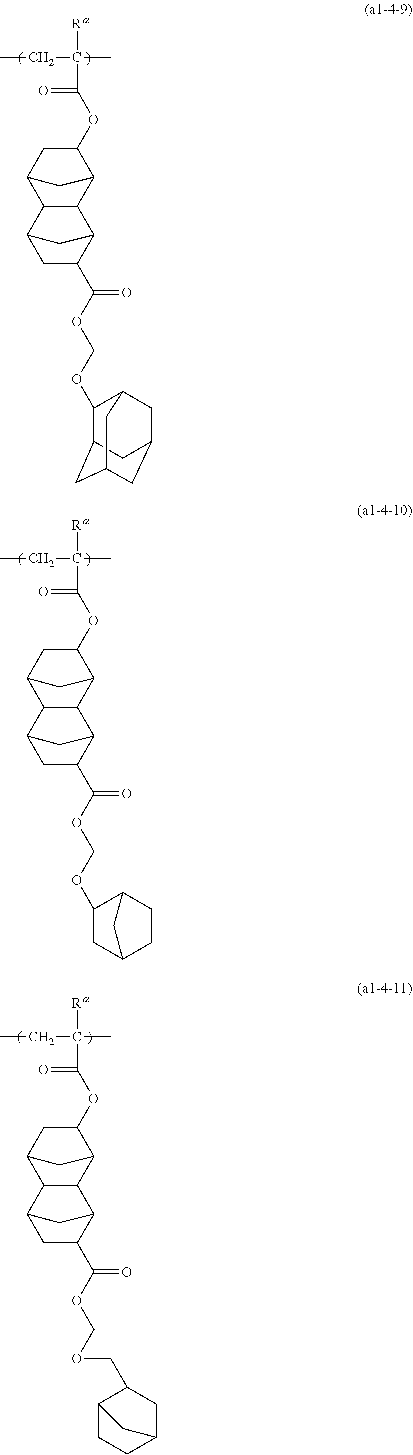

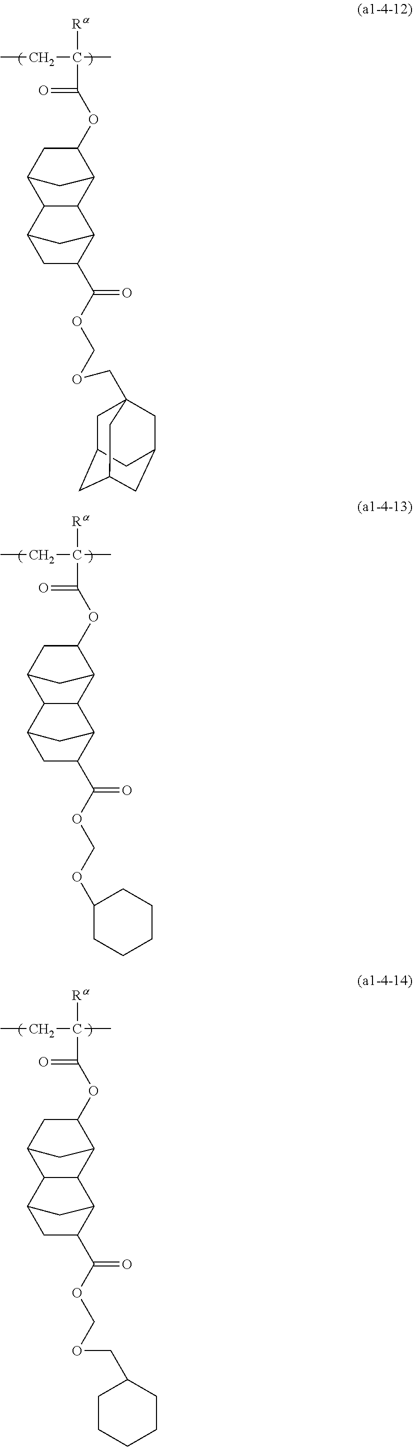

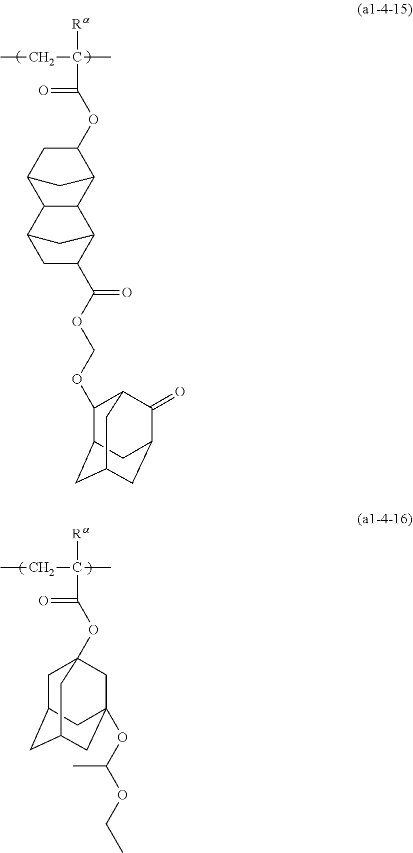

As the structural unit (a11), one type of structural unit may be used alone, or two or more types of structural units may be used in combination.

Among these, structural units represented by general formula (a11-1), (a11-2) or (a11-3) are preferable, and more specifically, the use of at least one structural unit selected from the group consisting of structural units represented by formulas (a1-1-1) to (a1-1-4), formulas (a1-1-20) to (a1-1-23), formula (a1-1-26), formulas (a1-1-32) to (a1-1-35), formulas (a1-2-1) to (a1-2-24), formula (a1-3-13) and formulas (a1-3-25) to (a1-3-28) is more preferable. As the structural units represented by general formula (a11-4), structural units represented by general formula (a1-4-16) are preferred.

Further, as the structural unit (a11), structural units represented by general formula (a1-1-01) shown below, which includes the structural units represented by formulas (a1-1-1) to (a1-1-3) and formula (a1-1-26), structural units represented by general formula (a1-1-02) shown below, which includes the structural units represented by formulas (a1-1-16) to (a1-1-17) and formulas (a1-1-20) to (a1-1-23), structural units represented by general formula (a1-3-01) shown below, which includes the structural units represented by formulas (a1-3-25) to (a1-3-26), and structural units represented by general formula (a1-3-02) shown below, which includes the structural units represented by formulas (a1-3-27) to (a1-3-28) are preferred.

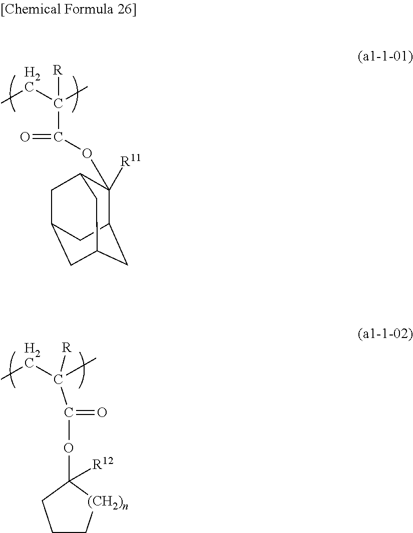

In the formulas, each R independently represents a hydrogen atom, an alkyl group of 1 to 5 carbon atoms or a halogenated alkyl group of 1 to 5 carbon atoms, R¹¹ represents an alkyl group of 1 to 5 carbon atoms; R¹² represents an alkyl group of 1 to 5 carbon atoms; and h represents an integer of 1 to 6.

In general formula (a1-1-01), R is the same as defined for R in general formula (a11-0-1) above. The alkyl group of 1 to 5 carbon atoms for R¹¹ is the same as the alkyl group of 1 to 5 carbon atoms defined for R above, and is preferably a methyl group, an ethyl group or an isopropyl group.

In general formula (a1-1-02), R is the same as defined for R in general formula (a11-0-1) above. The alkyl group of 1 to 5 carbon atoms for R¹² is the same as the alkyl group of 1 to 5 carbon atoms defined for R above, and is preferably a methyl group, an ethyl group or an isopropyl group. h is preferably 1 or 2, and most preferably 2.

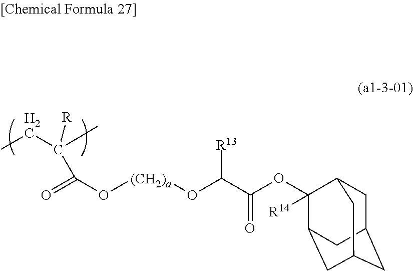

In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; and a represents an integer of 1 to 10.

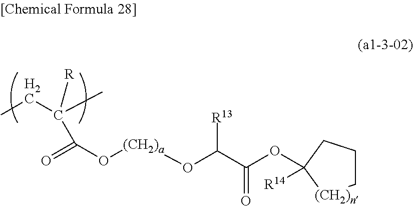

In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; a represents an integer of 1 to 10; and n′ represents an integer of 1 to 6.

In general formulas (a1-3-01) and (a1-3-02) above, R is the same as defined above for R in formula (a11-0-1).

R¹³ is preferably a hydrogen atom.

The alkyl group of 1 to 5 carbon atoms for R¹⁴ is the same as the alkyl group of 1 to 5 carbon atoms defined above for R, and is preferably a methyl group or an ethyl group.

n′ is preferably 1 or 2, and most preferably 2.

a is preferably an integer of 1 to 8, more preferably an integer of 2 to 5, and most preferably 2.

In the component (A1), the amount of the structural unit (a11) based on the combined total of all structural units constituting the component (A1) is preferably 5 to 80 mol %, more preferably 10 to 80 mol %, and still more preferably 15 to 75 mol %. By making the amount of the structural unit (a11) at least as large as the lower limit of the above-mentioned range, a pattern can be easily formed using a resist composition prepared from the component (A1). On the other hand, by making the amount of the structural unit (a11) no more than the upper limit of the above-mentioned range, a good balance can be achieved with the other structural units.

(Structural Unit (a12))

In the present invention, the structural unit (a12) is a structural unit in which either at least a portion of the hydroxyl group hydrogen atoms of a structural unit derived from hydroxystyrene or the hydrogen atom of the —C(═O)OH group of a structural unit derived from a vinylbenzoic acid have been protected with a substituent containing an acid dissociable, dissolution inhibiting group.

In the structural unit (a12), preferred examples of the substituent containing an acid dissociable, dissolution inhibiting group include the tertiary alkyl ester-type acid dissociable, dissolution inhibiting groups and acetal-type acid dissociable, dissolution inhibiting groups described above in connection with the structural unit (a11).

Of the structural units included within the definition of the structural unit (a12), preferred examples of structural units include those represented by general formulas (a12-1) to (a12-5) shown below.

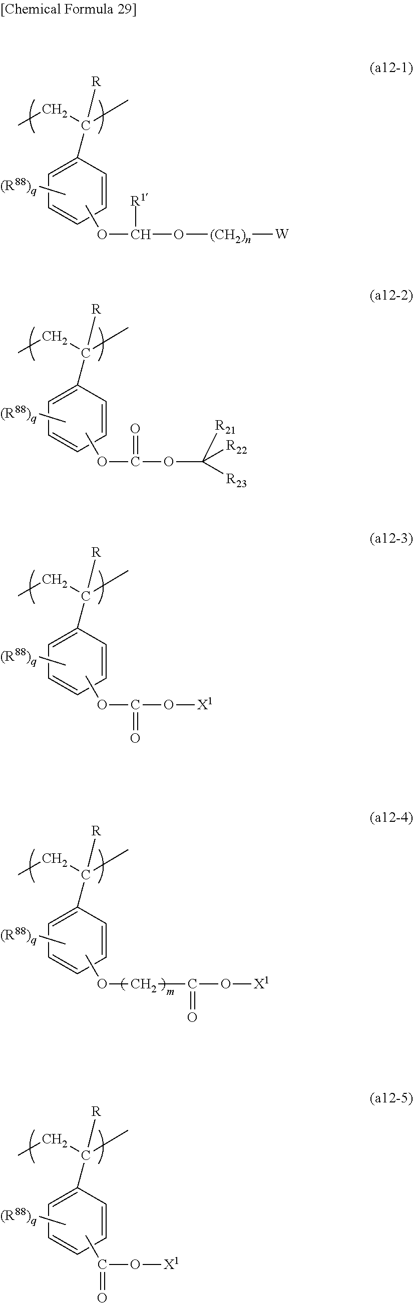

In formulas (a12-1) to (a12-5), R represents a hydrogen atom, an alkyl group of 1 to 5 carbon atoms or a halogenated alkyl group of 1 to 5 carbon atoms; R⁸⁸ represents a halogen atom, an alkyl group of 1 to 5 carbon atoms or a halogenated alkyl group of 1 to 5 carbon atoms; q represents an integer of 0 to 4; R^{1′} represents a hydrogen atom or an alkyl group of 1 to 5 carbon atoms; n represents an integer of 0 to 3; W represents an aliphatic cyclic group, an aromatic cyclic hydrocarbon group or an alkyl group of 1 to 5 carbon atoms; m is from 1 to 3; each of R²¹, R²² and R²³ independently represents a linear or branched alkyl group; and X¹ represents an acid dissociable, dissolution inhibiting group.

In formulas (a12-1) to (a12-5) above, the bonding position of the groups “—O—CHR^{1′}—O—(CH₂)ₙ—W”, “—O—C(O)—O—C(R²¹)(R²²)(R²³)”, “—O—C(O)—O—X¹”, “—O—CH₂)ₘ—C(O)—O—X¹” and “—C(O)—O—X¹” at the phenyl group may be any one of the o-position, the m-position, or the p-position of the phenyl group, and the p-position is most desirable, as the effects of the present invention become excellent.

R⁸⁸ represents a halogen atom, an alkyl group of 1 to 5 carbon atoms or a halogenated alkyl group of 1 to 5 carbon atoms.

Examples of the alkyl group of 1 to 5 carbon atoms for R⁸⁸ include the same groups as those listed above for the alkyl group of 1 to 5 carbon atoms for R¹ within formula (a0-1).

Examples of the halogen atom for R⁸⁸ include a fluorine atom, a chlorine atom, a bromine atom and an iodine atom, and a fluorine atom is preferable.

When q is 1, the substitution position of R⁸⁸ may be any of the o-position, the m-position and the p-position.

When q is 2, a desired combination of the substitution positions can be used.

However, 1≦p+q≦5.

q represents an integer of 0 to 4, preferably 0 or 1, and most preferably 0 from an industrial viewpoint.

n represents an integer of 0 to 3, and is preferably an integer of 0 to 2, more preferably 0 or 1, and most preferably 0.

The aliphatic cyclic group for W is a monovalent aliphatic cyclic group. The aliphatic cyclic group can be selected appropriately, for example, from the multitude of groups that have been proposed for conventional ArF resists. Specific examples of the aliphatic cyclic group include an aliphatic monocyclic group of 5 to 7 carbon atoms and an aliphatic polycyclic group of 10 to 16 carbon atoms.

The aliphatic cyclic group may or may not have a substituent. Examples of substituents include an alkyl group of 1 to 5 carbon atoms, an alkoxy group of 1 to 5 carbon atoms, a fluorine atom, a fluorinated alkyl group of 1 to 5 carbon atoms which is substituted by a fluorine atom, and an oxygen atom (═O).

The basic ring of the aliphatic cyclic group exclusive of substituents is not limited to be constituted from only carbon and hydrogen (not limited to hydrocarbon groups), and may include an oxygen atom or the like in the ring structure.

As the aliphatic monocyclic group of 5 to 7 carbon atoms, a group in which one hydrogen atom has been removed from a monocycloalkane can be mentioned, and specific examples include a group in which one hydrogen atom has been removed from cyclopentane, cyclohexane or the like.

Examples of the aliphatic polycyclic group of 10 to 16 carbon atoms include groups in which one hydrogen atom has been removed from a bicycloalkane, tricycloalkane, tetracycloalkane or the like. Specific examples include groups in which one hydrogen atom has been removed from a polycycloalkane such as adamantane, norbornane, isobornane, tricyclodecane or tetracyclododecane. Of these, an adamantyl group, a norbornyl group and a tetracyclododecyl group is preferred industrially, and an adamantyl group is particularly desirable.

As the aromatic cyclic hydrocarbon group for W, aromatic polycyclic groups of 10 to 16 carbon atoms can be mentioned. Examples of such aromatic polycyclic groups include groups in which one hydrogen atom has been removed from naphthalene, anthracene, phenanthrene or pyrene. Specific examples include a 1-naphthyl group, a 2-naphthyl group, a 1-anthryl group, a 2-anthryl group, a 1-phenanthryl group, a 2-phenanthryl group, a 3-phenanthryl group and a 1-pyrenyl group, and a 2-naphthyl group is particularly preferred industrially.

As the alkyl group of 1 to 5 carbon atoms for W, the same groups as the above-mentioned alkyl groups of 1 to 5 carbon atoms that may be bonded to the α-position of an aforementioned acrylate ester can be used, and a methyl group or an ethyl group is more preferable, and an ethyl group is most preferable.

R²¹ to R²³ are preferably an alkyl group of 1 to 5 carbon atoms, more preferably an alkyl group of 1 to 3 carbon atoms, and specific examples thereof include the same alkyl groups of 1 to 5 carbon atoms as those described above that may be bonded to the α-position of an aforementioned acrylate ester.

Examples of X¹ include the same groups as those described above in relation to the tertiary alkyl group containing group and alkoxyalkyl group.

m is preferably 1 or 2, and more preferably 1.

Of the various possibilities described above, the structural unit (a12) is particularly preferably the structural unit represented by the above-mentioned general formula (a12-1) or (a12-4).

Specific examples of preferred structures for the structural unit (a12) are shown below.

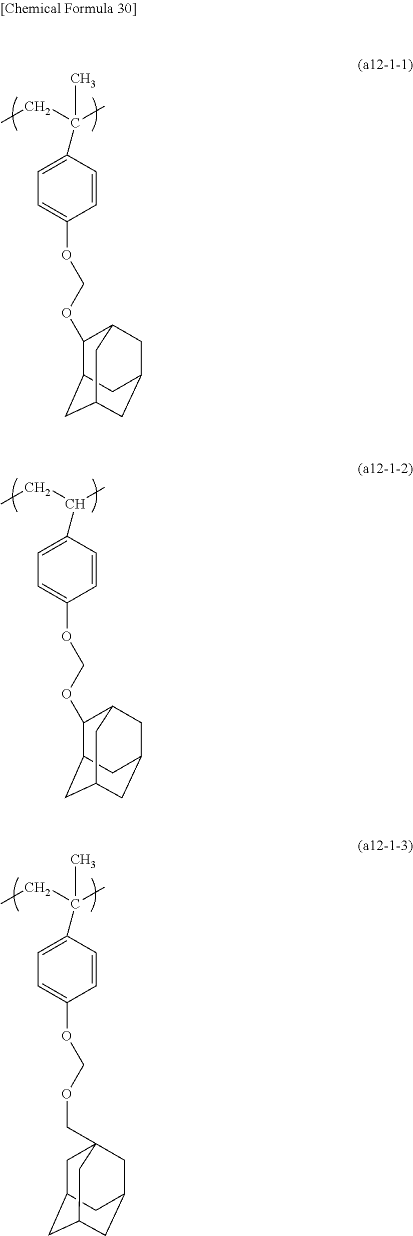

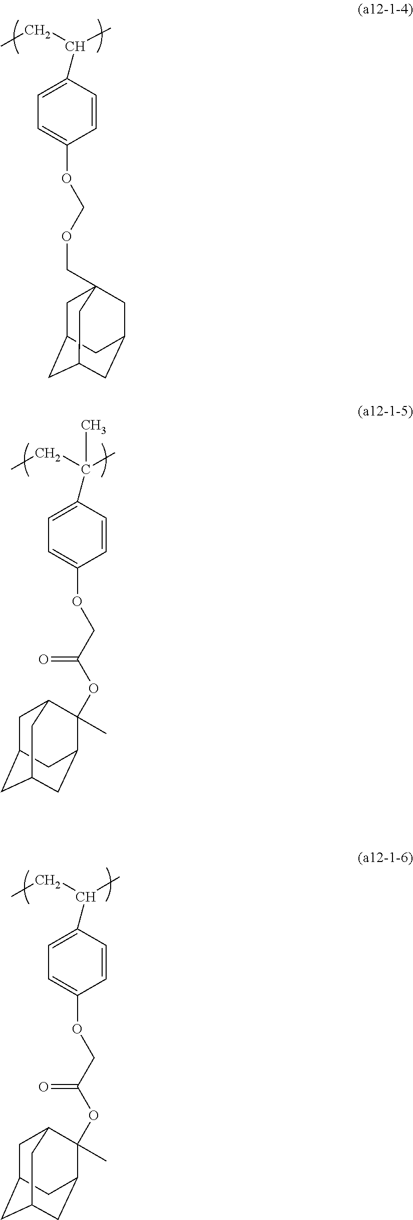

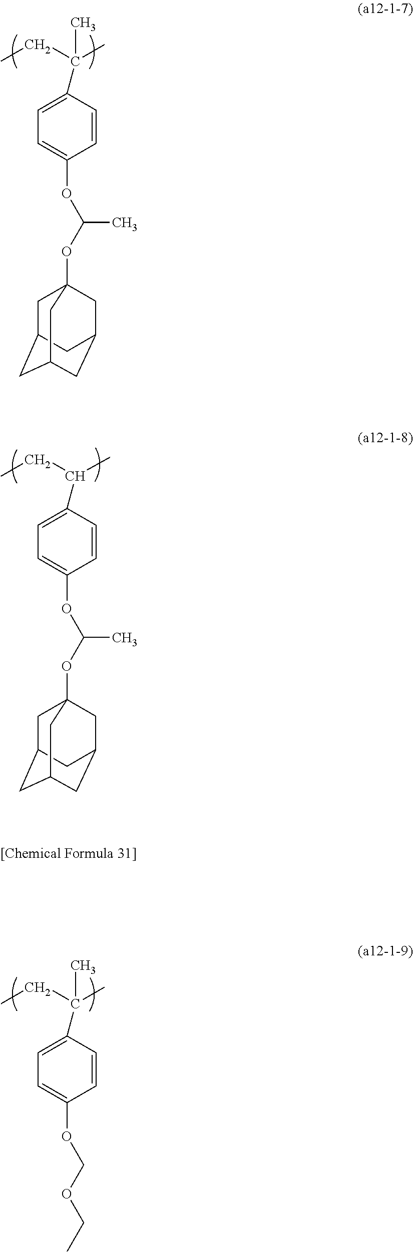

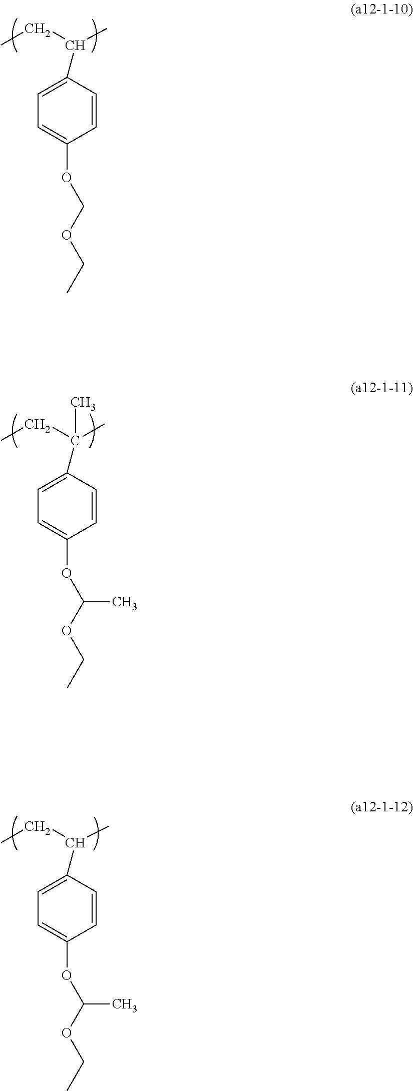

As the structural unit (a12), among the examples shown above, at least one structural unit selected from those represented by chemical formulas (a12-1-1) to (a12-1-12) is preferable, and those represented by chemical formulas (a12-1-1) to (a12-1-2) and (a12-1-5) to (a12-1-12) are most preferable, as the effects of the present invention become excellent.

As the structural unit (a12), one type of structural unit may be used alone, or two or more types of structural units may be used in combination.

(Structural Unit (a2))

The structural unit (a2) is a structural unit derived from an acrylate ester containing a lactone-containing cyclic group.

The term “lactone-containing cyclic group” refers to a cyclic group including one ring containing a —O—C(O)— structure (lactone ring). This “lactone ring” is counted as the first ring, so that a lactone-containing cyclic group in which the only ring structure is the lactone ring is referred to as a monocyclic group, and groups that also contain other ring structures are described as polycyclic groups regardless of the structure of the other rings.

When the component (A1) is used for forming a resist film, the lactone-containing cyclic group of the structural unit (a2) is effective in improving the adhesion between the resist film and the substrate, and increasing the compatibility with the developing solution containing water.

As the structural unit (a2), there is no particular limitation, and an arbitrary structural unit may be used.

Specific examples of lactone-containing monocyclic groups include groups in which one hydrogen atom has been removed from a 4- to 6-membered lactone ring, including a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specifically, examples of the structural unit (a2) include structural units represented by general formulas (a2-1) to (a2-5) shown below.

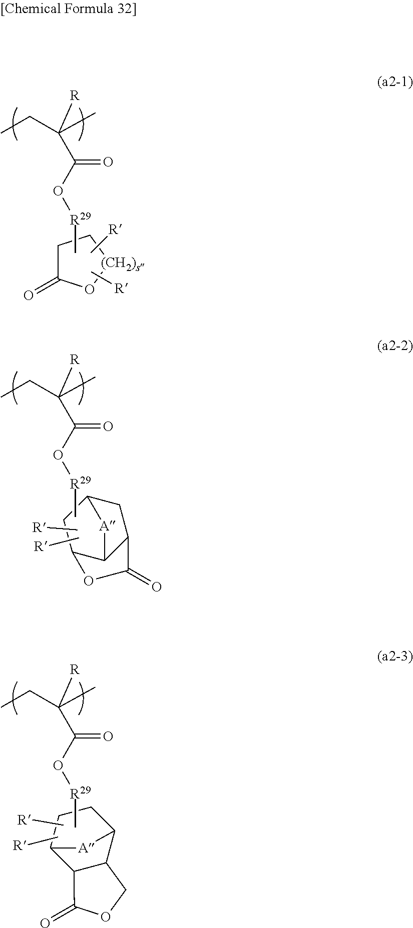

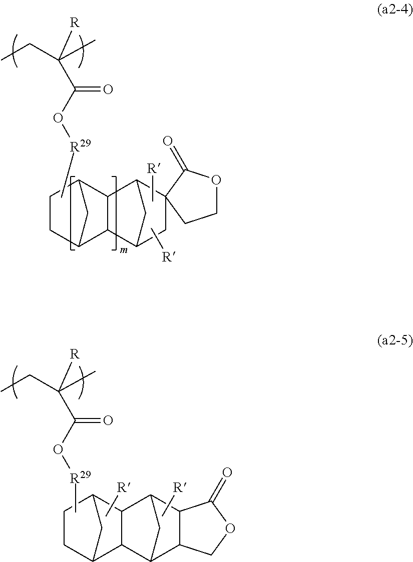

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″; R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m is 0 or 1.

In general formulas (a2-1) to (a2-5), R is the same as defined above for R in the structural unit (a1).

Examples of the alkyl group of 1 to 5 carbon atoms for R′ include a methyl group, ethyl group, propyl group, n-butyl group or tert-butyl group.

Examples of the alkoxy group of 1 to 5 carbon atoms for R′ include a methoxy group, ethoxy group, n-propoxy group, iso-propoxy group, n-butoxy group or tert-butoxy group.

In terms of industrial availability, R′ is preferably a hydrogen atom.

The alkyl group for R″ may be any of linear, branched or cyclic.

In those cases where R″ represents a linear or branched alkyl group, the alkyl group preferably has 1 to 10 carbon atoms, and more preferably 1 to 5 carbon atoms.

In those cases where R″ represents a cyclic alkyl group, the cyclic alkyl group preferably has 3 to 15 carbon atoms, more preferably 4 to 12 carbon atoms, and most preferably 5 to 10 carbon atoms. Examples of the cyclic alkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

A″ is the same as defined above for A′ in general formula (3-1). A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylmethylene group is more preferable, and a methylene group is particularly desirable.

R²⁹ represents a single bond or a divalent linking group. Examples of the divalent linking groups include the same divalent linking groups as those described above for R² in general formula (a0-1). Among these, an alkylene group, an ester bond (—C(═O)—O—) or a combination thereof is preferable. The alkylene group as a divalent linking group for R²⁹ is preferably a linear or branched alkylene group. Specific examples of alkylene groups include the same linear alkylene groups and branched alkylene groups as those listed above for the aliphatic hydrocarbon group within the description for R².

As R²⁹, a single bond or —R^{29′}—C(═O)—O—[wherein R^{29′} represents a linear or branched alkylene group] is particularly desirable.

The linear or branched alkylene group for R^{29′} preferably has 1 to 10 carbon atoms, more preferably 1 to 8 carbon atoms, still more preferably 1 to 5 carbon atoms, still more preferably 1 to 3 carbon atoms, and most preferably 1 or 2 carbon atoms.

As the linear alkylene group for R^{29′}, a methylene group or an ethylene group is preferable, and a methylene group is particularly desirable. As the branched alkylene group for R^{29′}, an alkylmethylene group or an alkylethylene group is preferable, and —CH(CH₃)—, —C(CH₃)₂— or —C(CH₃)₂CH₂— is particularly desirable.

In general formula (a2-1), s″ is preferably 1 or 2.

Specific examples of the structural units represented by the aforementioned general formulas (a2-1) to (a2-5) are shown below. In each of the following formulas, R^{α} represents a hydrogen atom, a methyl group or a trifluoromethyl group.

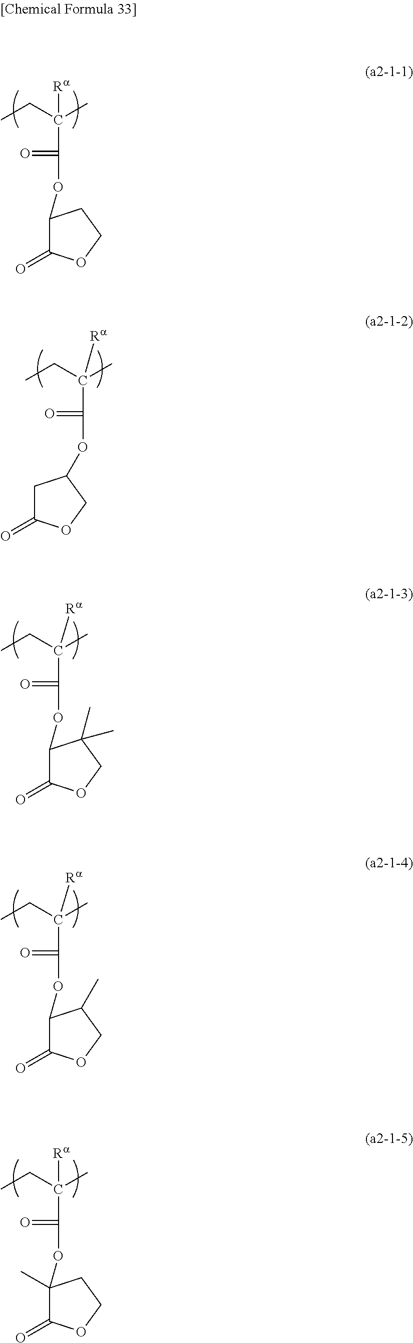

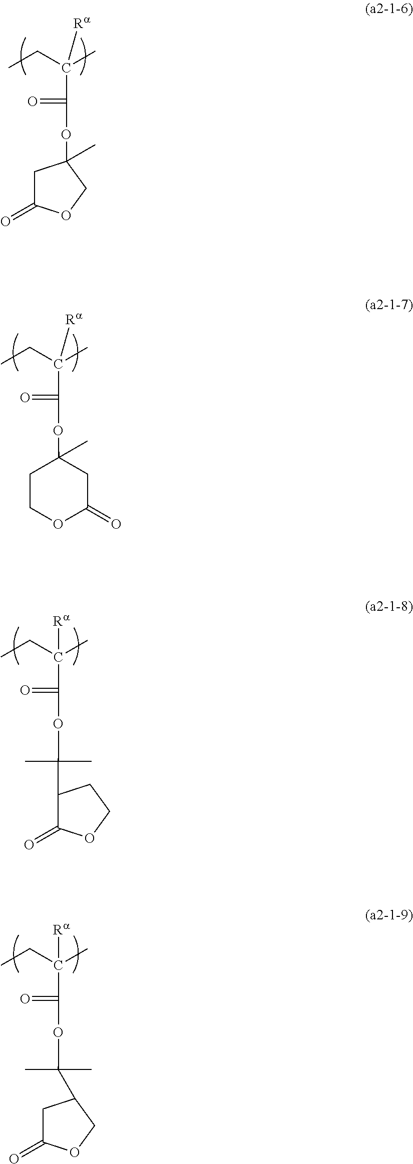

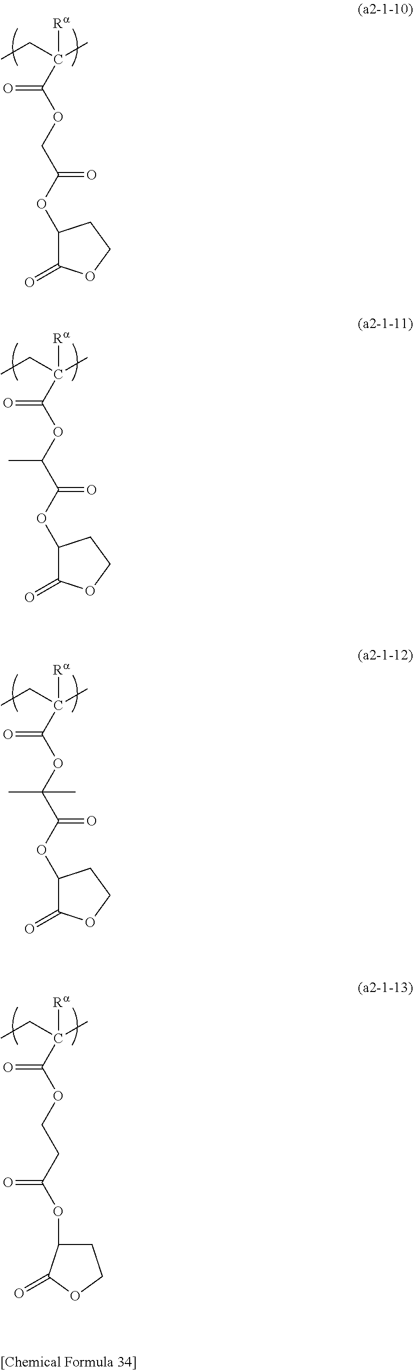

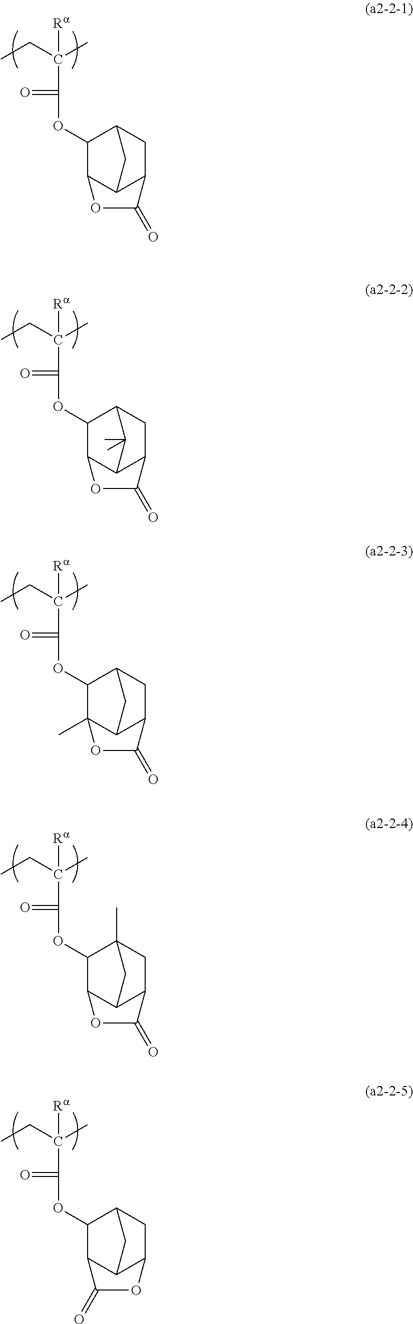

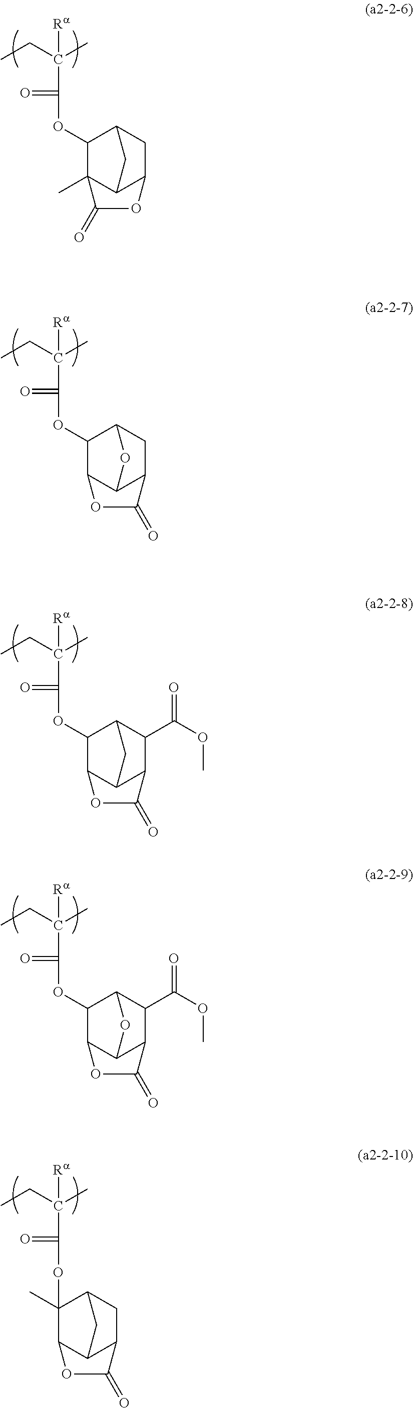

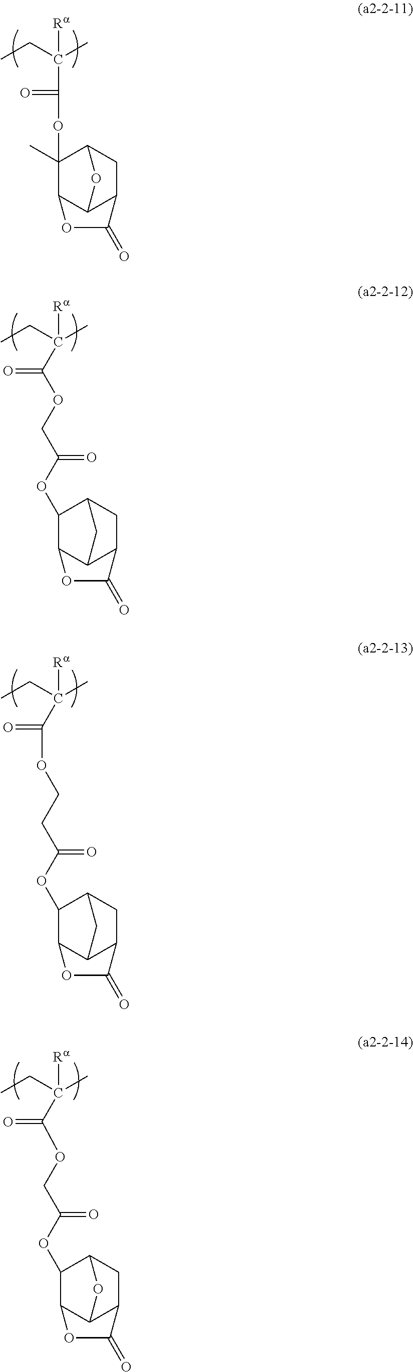

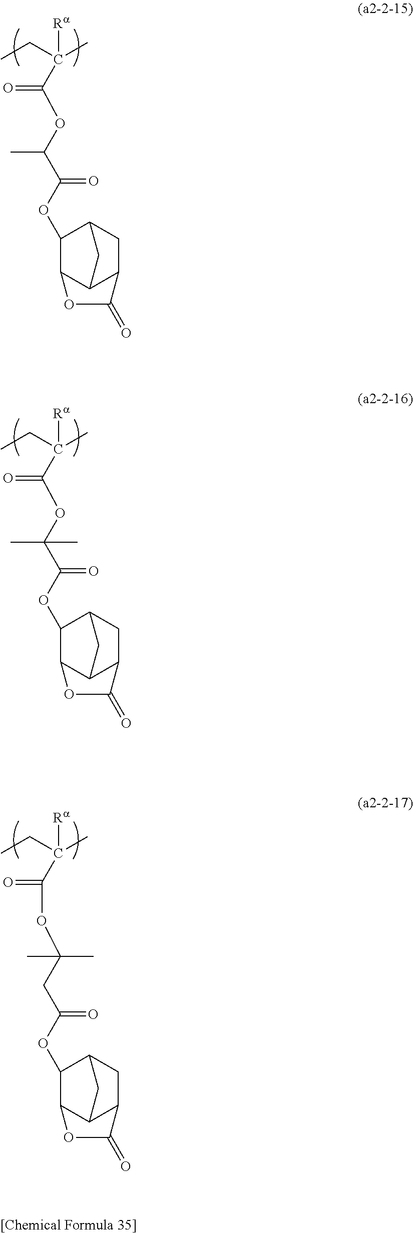

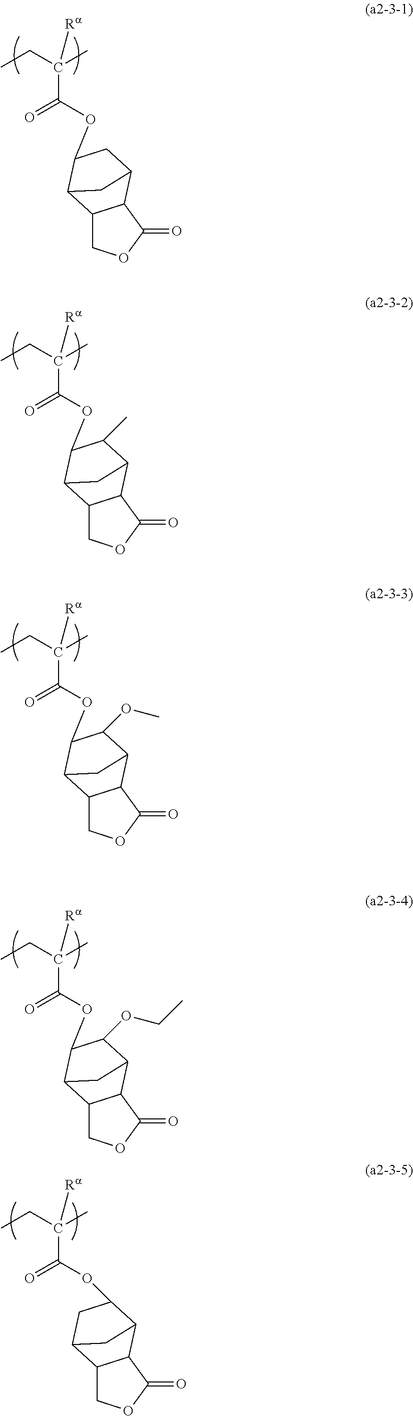

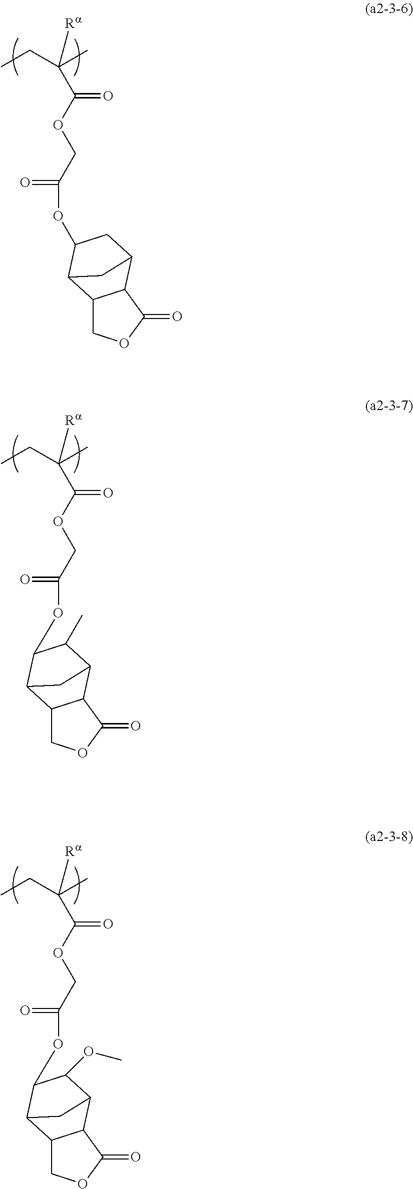

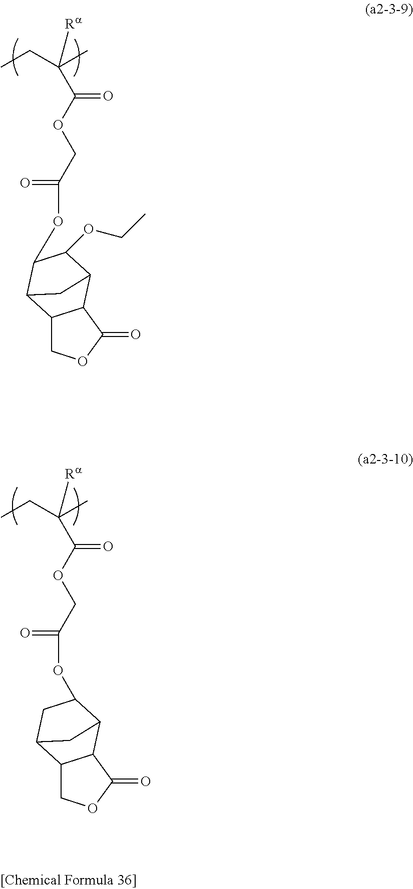

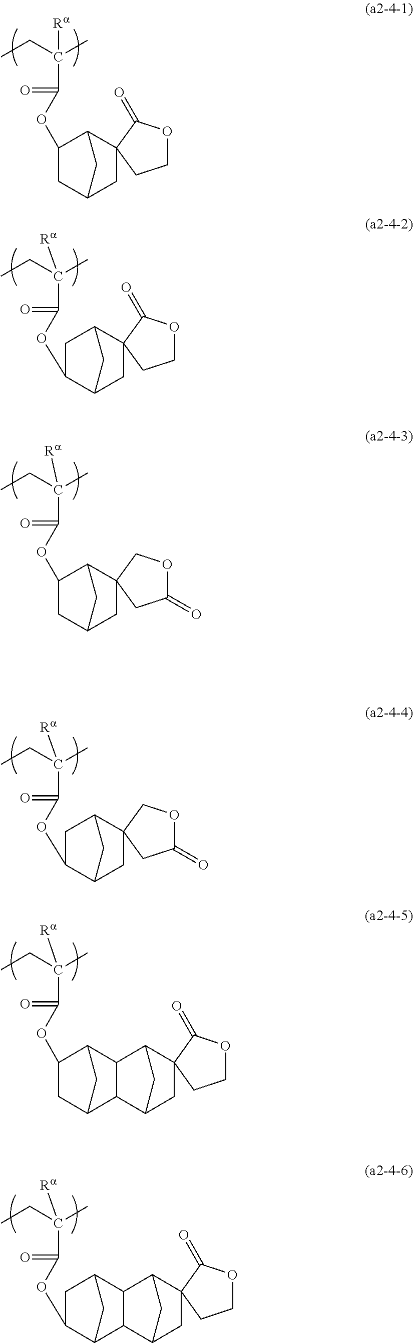

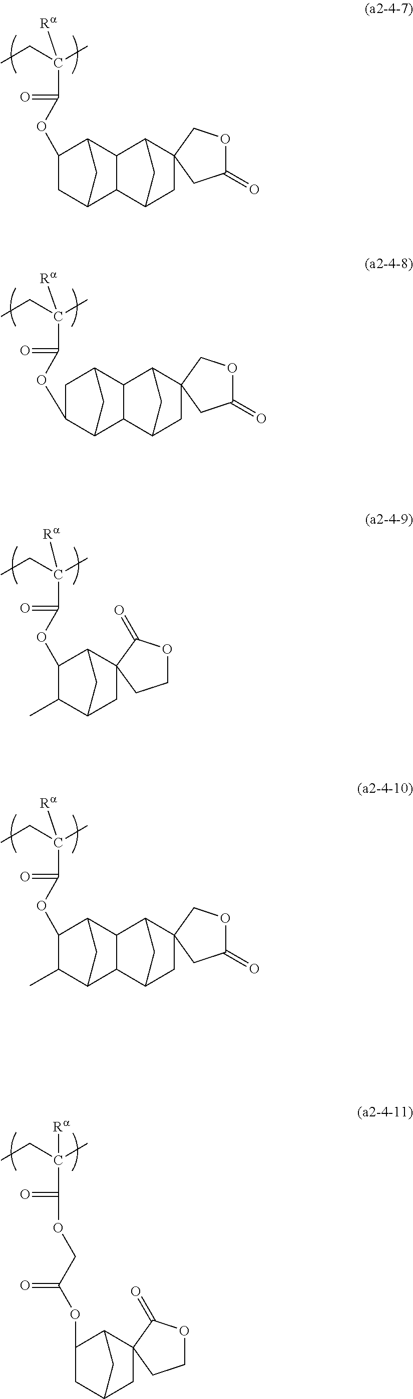

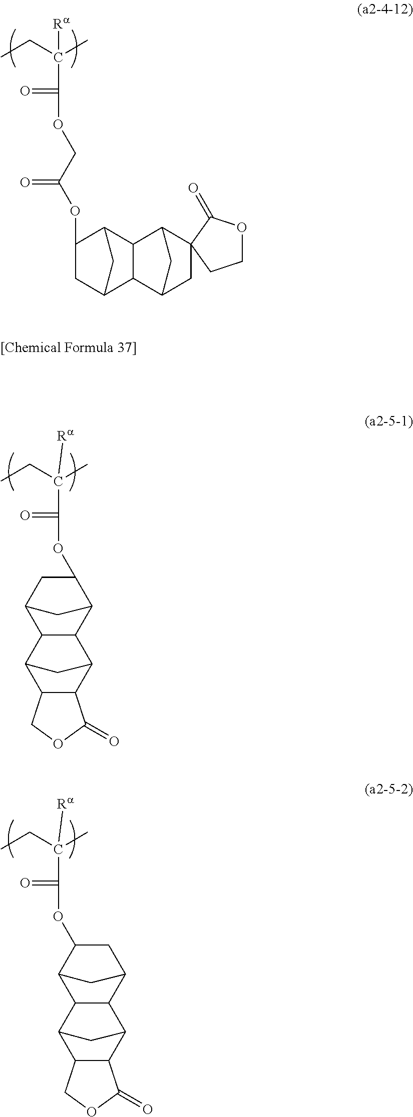

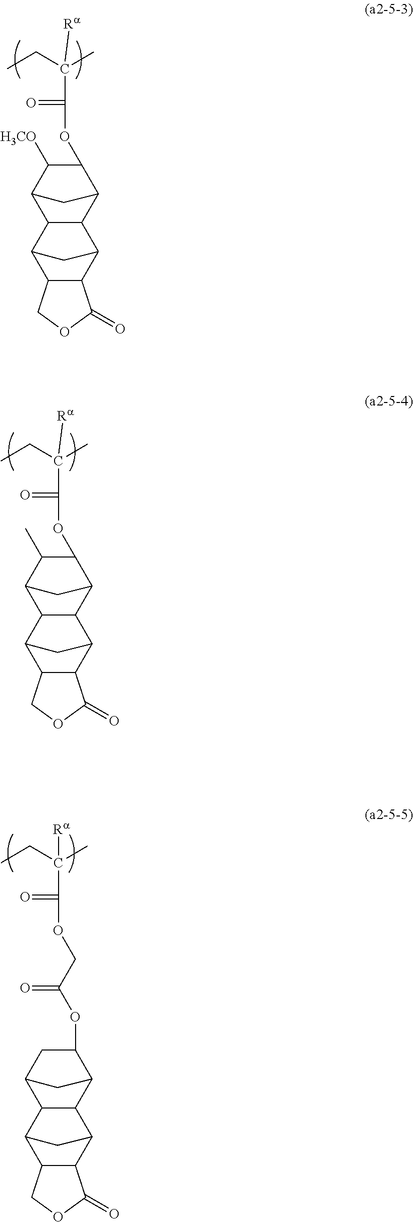

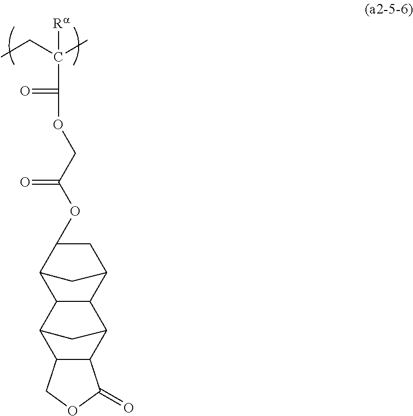

In the component (A1), as the structural unit (a2), one type of structural unit may be used alone, or two or more types of structural units may be used in combination.

In the present invention, when the component (A1) includes the structural unit (a2), it preferably includes, as the structural unit (a2), at least one type of structural unit selected from the group consisting of structural units represented by any one of the general formulas (a2-1) to (a2-5) above, more preferably at least one type of structural unit selected from the group consisting of structural units represented by any one of the general formulas (a2-1) to (a2-3) above, and most preferably at least one structural unit selected from the group consisting of structural units represented by the general formula (a2-1) or (a2-2) above.

In those cases where the component (A1) includes the structural unit (a2), in terms of improving the adhesion between a substrate and a resist film formed using a positive resist composition containing the component (A1) and increasing the compatibility with a developing solution, the amount of the structural unit (a2) within the component (A1), based on the combined total of all structural units constituting the component (A1) is preferably 5 to 70 mol %, more preferably 10 to 65 mol %, still more preferably 15 to 65 mol %, and most preferably 20 to 60 mol %. By ensuring the above-mentioned range, MEF and the pattern shape can be further improved, and CDU can also be improved.

(Structural Unit (a3))

The structural unit (a3) is a structural unit derived from an acrylate ester containing a polar group-containing aliphatic hydrocarbon group.

When the component (A1) includes the structural unit (a3), the hydrophilicity of the component (A′) is improved, and hence, the compatibility of the component (A′) with the developing solution is improved. As a result, the alkali solubility of the exposed portions improves, which contributes to favorable improvements in the resolution.

Examples of the polar group include a hydroxyl group, cyano group, carboxyl group, or hydroxyalkyl group in which some of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and polycyclic aliphatic hydrocarbon groups (polycyclic groups).

These polycyclic groups can be selected appropriately from the multitude of groups that have been proposed for the resins of resist compositions designed for use with ArF excimer lasers. The polycyclic group preferably has 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

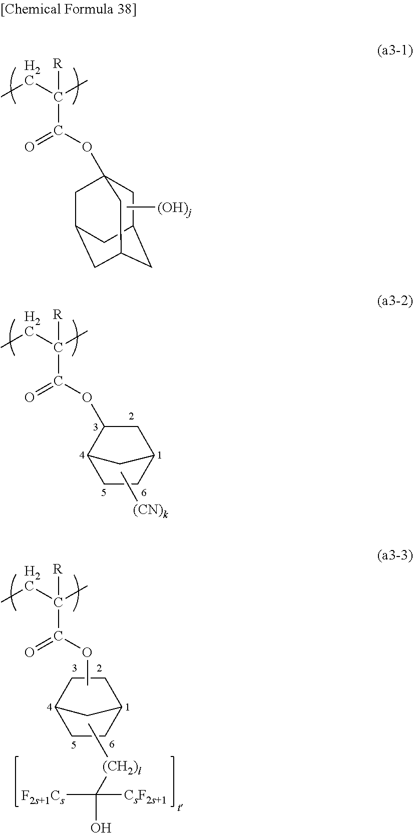

In the formulas, R represents a hydrogen atom, an alkyl group of 1 to 5 carbon atoms or a halogenated alkyl group of 1 to 5 carbon atoms; j is an integer of 1 to 3; k is an integer of 1 to 3; t′ is an integer of 1 to 3; l is an integer of 1 to 5; and s is an integer of 1 to 3.

In general formula (a3-1), j is preferably 1 or 2, and more preferably 1. When j is 2, structural units in which the hydroxyl groups are bonded to the 3rd and 5th positions of the adamantyl group are preferred. When j is 1, structural units in which the hydroxyl group is bonded to the 3rd position of the adamantyl group are preferred.

j is preferably 1, and structural units in which the hydroxyl group is bonded to the 3rd position of the adamantyl group are particularly desirable.

In formula (a3-2), k is preferably 1. The cyano group is preferably bonded to the 5th or 6th position of the norbornyl group.

In formula (a3-3), t′ is preferably 1, l is preferably 1 and s is preferably 1. Further, it is preferable that a 2-norbornyl group or 3-norbornyl group be bonded to the terminal of the carboxyl group of the acrylic acid. The fluorinated alkyl alcohol is preferably bonded to the 5th or 6th position of the norbornyl group.

As the structural unit (a3), one type of structural unit may be used alone, or two or more types of structural units may be used in combination.

When the component (A1) includes the structural unit (a3), in the component (A1), the amount of the structural unit (a3) based on the combined total of all structural units constituting the component (A1) is preferably 1 to 50 mol %, more preferably 3 to 45 mol %, and still more preferably 5 to 40 mol %. By making the amount of the structural unit (a3) at least as large as the lower limit of the above-mentioned range, the effect of using the structural unit (a3) can be satisfactorily achieved. On the other hand, by making the amount of the structural unit (a3) no more than the upper limit of the above-mentioned range, a good balance can be achieved with the other structural units.

### (Other Structural Units)

The component (A1) may also have a structural unit other than the above-mentioned structural units (a1) to (a3) (hereafter, referred to as “structural unit (a4)”), as long as the effects of the present invention are not impaired.

As the structural unit (a4), any other structural unit which cannot be classified as one of the above structural units (a1) to (a3) can be used without any particular limitation, and any of the multitude of conventional structural units used within resist resins for ArF excimer lasers, KrF excimer lasers, EUV, EB or the like can be used.

Preferable examples of the structural unit (a4) include a structural unit derived from an acrylate ester which contains a non-acid-dissociable aliphatic polycyclic group, a structural unit derived from a styrene monomer, a structural unit derived from a vinylnaphthalene monomer and a structural unit that corresponds to the structural unit (a5) to be described later. Examples of this polycyclic group include the same groups as the polycyclic groups described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecanyl group, adamantyl group, tetracyclododecanyl group, isobornyl group, and norbornyl group is particularly desirable. These polycyclic groups may be substituted with a linear or branched alkyl group of 1 to 5 carbon atoms.

Specific examples of the structural unit (a4) include structural units with structures represented by general formulas (a4-1) to (a4-5) shown below.

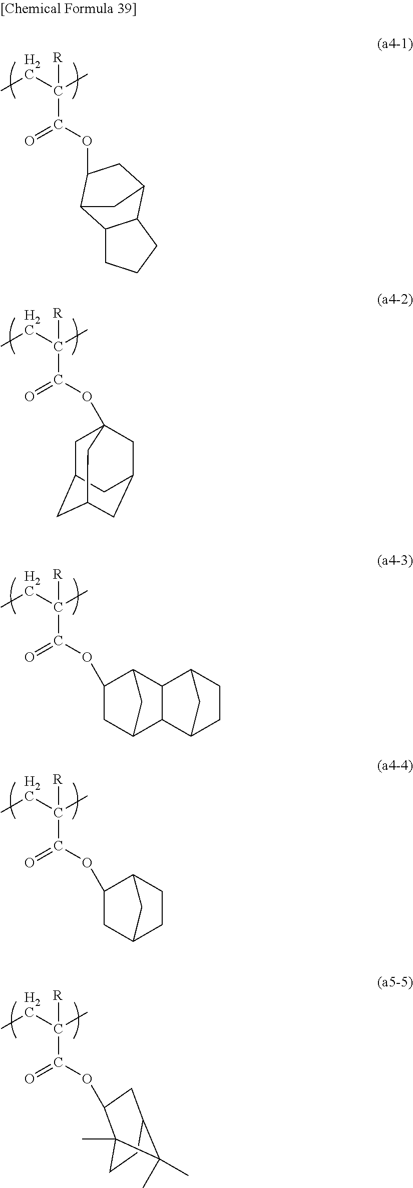

In the formulas, R represents a hydrogen atom, an alkyl group of 1 to 5 carbon atoms or a halogenated alkyl group of 1 to 5 carbon atoms.

As the structural unit (a4), one type of structural unit may be used alone, or two or more types of structural units may be used in combination.

When the structural unit (a4) is included in the component (A1), the amount of the structural unit (a4) based on the combined total of all structural units constituting the component (A1) is preferably 1 to 20 mol %, more preferably 1 to 15 mol %, and still more preferably 1 to 10 mol %.

The component (A1) is a copolymer including the structural unit (a0-1) and the structural unit (a1).

Examples of such copolymers include a copolymer consisting of the structural units (a0-1) and (a1), a copolymer consisting of the structural units (a0-1), (a1) and (a3), a copolymer consisting of the structural units (a0-1), (a1), (a2) and (a3), a copolymer consisting of the structural units (a0-1), (a1) and (a2), and a copolymer consisting of the structural units (a0-1), (a1), (a2), (a3) and (a4).

In the present invention, as the component (A1), a copolymer that includes a combination of structural units represented by general formulas (A1-11) to (A1-17) shown below is particularly desirable. In each of the following formulas, R, R¹, R^{2′}, A′, R¹¹, R¹², R²⁹, s″, h, j, R¹⁵ and R¹⁶ are the same as defined above, and the plurality of R, R¹⁵ and R¹⁶ in the formulas may be the same or different from each other.

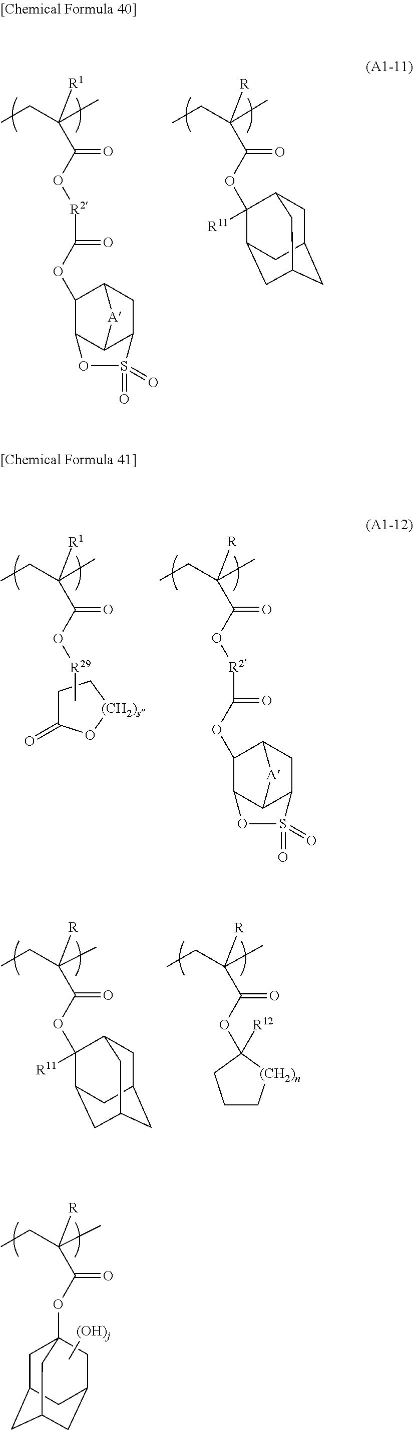

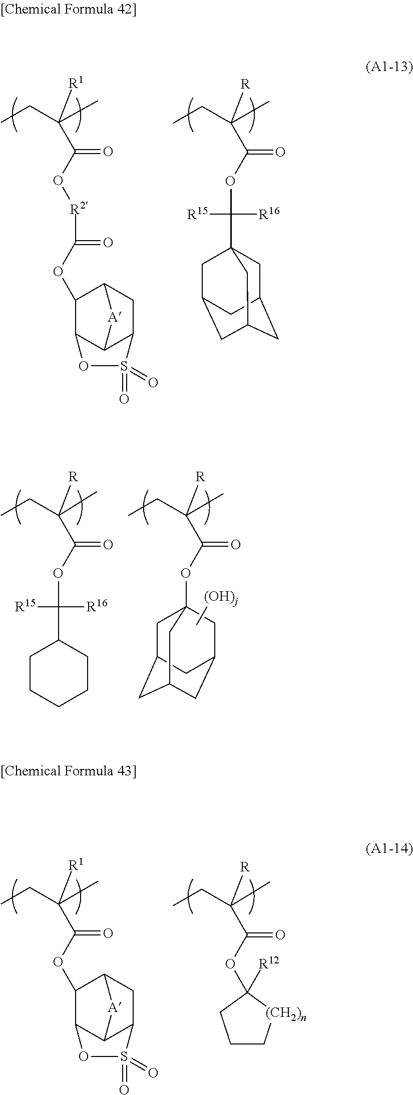

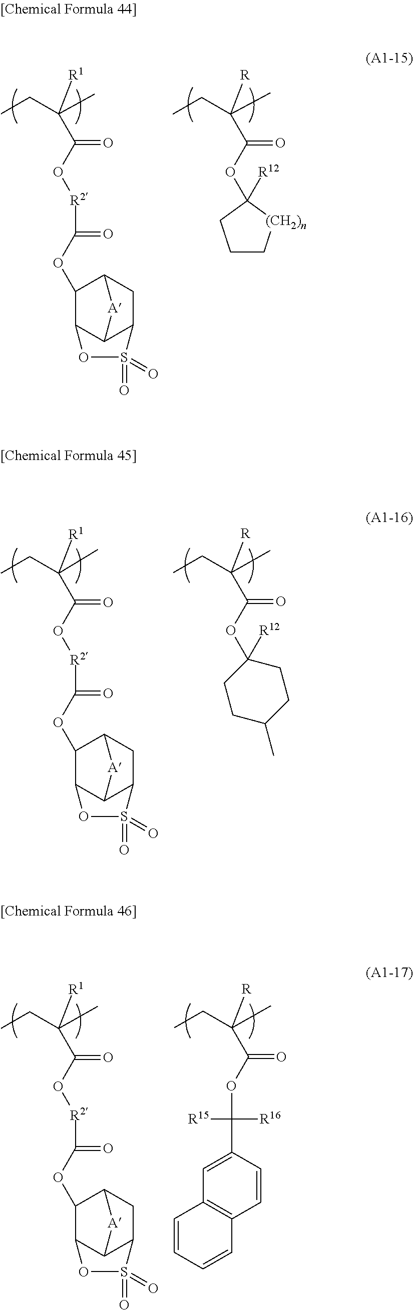

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,500 to 20,000. Provided the weight average molecular weight is not more than the upper limit of the above-mentioned range, the component (A1) exhibits satisfactory solubility in a resist solvent when used as a resist, whereas provided the weight average molecular weight is at least as large as the lower limit of the above-mentioned range, the dry etching resistance and cross-sectional shape of the resist pattern can be improved.

Further, the dispersity (Mw/Mn) of the component (A1) is not particularly limited, but is preferably 1.0 to 5.0, more preferably 1.0 to 3.0, and most preferably 1.2 to 2.5.

Here, Mn is the number average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH during the above polymerization, a —C(CF₃)₂—OH group can be introduced at the terminals of the component (A1). Such a copolymer having an introduced hydroxyalkyl group in which some of the hydrogen atoms of the alkyl group are substituted with fluorine atoms is effective in reducing developing defects and LER (line edge roughness: unevenness of the side walls of a line pattern).

As the monomers for deriving the corresponding structural units, commercially available monomers may be used, or the monomers may be synthesized by a conventional method.

For example, as a monomer for deriving the structural unit (a0-1), a compound represented by general formula (I) shown below (hereafter referred to as “compound (I)”) can be used.

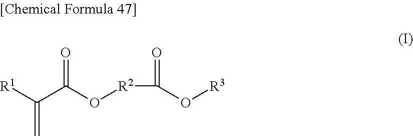

In formula (I), R¹ represents a hydrogen atom, an alkyl group of 1 to 5 carbon atoms or a halogenated alkyl group of 1 to 5 carbon atoms; R² represents a single bond or a divalent linking group; and R³ represents a cyclic group that contains —SO₂— within the ring skeleton thereof.

The method for producing the compound (I) is not particularly limited, and the compound (I) can be produced by a conventional method. For example, in the presence of a base, a compound (X-2) represented by general formula (X-2) shown below is added to a solution obtained by dissolving a compound (X-1) represented by general formula (X-1) shown below in a reaction solvent, and a reaction is effected to thereby obtain a compound (I).

Examples of the base include inorganic bases such as sodium hydride, K₂CO₃ and Cs₂CO₃; and organic bases such as triethylamine, 4-dimethylaminopyridine (DMAP) and pyridine. Examples of condensing agents include carbodiimide reagents such as ethyldiisopropylaminocarbodiimide hydrochloride (EDCI), dicyclohexylcarboxylmide (DCC), diisopropylcarbodiimide and carbodiimidazole; tetraethyl pyrophosphate; and benzotriazole-N-hydroxytrisdimethylaminophosphonium hexafluorophosphide (Bop reagent).

If desired, an acid may be used. As the acid, any acid generally used for dehydration/condensation may be used. Specific examples include inorganic acids such as hydrochloric acid, sulfuric acid and phosphoric acid; and organic acids such as methanesulfonic acid, trifluoromethanesulfonic acid, benzenesulfonic acid and p-toluenesulfonic acid. These acids can be used individually, or in a combination of two or more.

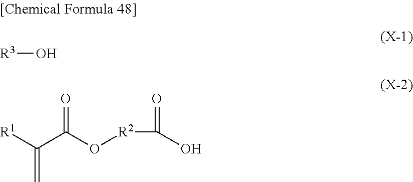

In the formulas (X-1) and (X-2) above, R¹, R² and R³ are the same as defined above.

The structure of the compound obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

In the component (A′), as the component (A1), one type of component may be used alone, or two or more types may be used in combination.

In the component (A′), the amount of the component (A1) based on the total weight of the component (A′) is preferably 25% by weight or more, more preferably 50% by weight or more, still more preferably 75% by weight or more, and may be even 100% by weight. When the amount of the component (A1) is 25% by weight or more, various lithography properties are improved.

### [Component (A2)]

In the present invention, the component (A′) may contain a resin component (A2) (hereafter, referred to as “component (A2)”) other than the aforementioned component (A1). The component (A2) can be selected appropriately from the conventional resins used for ArF excimer lasers, KrF excimer lasers, EUV, EB or the like.

Specific examples of preferred resins for the component (A2) include a resin obtained by copolymerizing at least one structural unit selected from the group consisting of the aforementioned structural units (a1), (a2), (a3) and (a4), and a main chain decomposition type resin.

As the main chain decomposition type resin, a polymer (A21) having a core portion represented by general formula (1) shown below and an arm portion that is bonded to the core portion and is also composed of a polymer chain obtained by an anionic polymerization method is preferred.

[Chemical Formula 49]

PX—Y)ₐ (1)

In formula (1), P represents an organic group having a valence of a; a represents an integer of 2 to 20; Y represents an arylene group or an alkylene group of 1 to 12 carbon atoms; and X represents any one of the bonding groups represented by general formulas (2) to (5) shown below which can be cleaved by the action of acid.

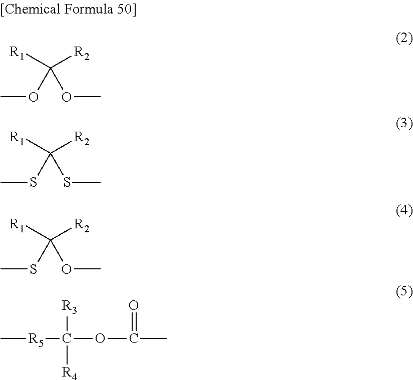

In formulas (2) to (5), each of R¹, R², R³ and R⁴ independently represents a linear, branched or cyclic alkyl group of 1 to 12 carbon atoms which may be substituted with a halogen atom or an epoxy group, an aryl group which may be substituted with a halogen atom or an epoxy group, or a hydrogen atom; and R⁵ represents a linear, branched or cyclic alkylene group of 1 to 12 carbon atoms which may be substituted with a halogen atom or an epoxy group, an arylene group which may be substituted with a halogen atom or an epoxy group, or a single bond.

### (Core Portion)

The core portion of the polymer (A21) is represented by general formula (1) above.

In general formula (1) above, a represents an integer of 2 to 20, and a is preferably an integer of 2 to 15, and more preferably an integer of 3 to 10. When a is in the above range, resolution is improved and pattern shape is excellent.

P represents an organic group having a valence of a. That is, for example, when P is divalent (a=2), the core portion of the polymer (A21) has a structure in which two “—X—Y” groups are bonded to P. When P is trivalent (a=3), the core portion has a structure in which three “—X—Y” groups are bonded to P. As the valence a of P increases, the number of “—X—Y” groups bonded to P increases, and thus the polymer (A21) has a more dense radial structure.

The organic group for P preferably has 1 to 20 carbon atoms, more preferably 2 to 15 carbon atoms, and most preferably 3 to 12 carbon atoms.

Examples of the organic group include an aliphatic hydrocarbon group and an aromatic hydrocarbon group.

The aliphatic hydrocarbon group may be either chain-like or cyclic or a combination thereof, and may be either saturated or unsaturated.

Examples of the aromatic hydrocarbon group include a hydrocarbon group containing an aromatic hydrocarbon ring. For example, the aromatic hydrocarbon group may be composed of an aromatic hydrocarbon ring, or a combination of an aromatic hydrocarbon ring and an aliphatic hydrocarbon group.

The organic group may contain, in the group, a linking group such as an ether group, a polyether group, an ester group [—C(═O)—O—], a carbonyl group [—C(═O)—], —NH—, —N═, —NH—C(═O)— and —NR²⁵— (R²⁵ represents an alkyl group) or a silicon atom.

As the alkyl group for R²⁵, a lower alkyl group of 1 to 5 carbon atoms can be used.

Further, some or all of the hydrogen atoms of the organic group may or may not be substituted with alkyl groups, alkoxy groups, halogen atoms or hydroxyl groups.

The alkyl group with which hydrogen atoms of the organic group may be substituted is preferably an alkyl group of 1 to 5 carbon atoms, and more preferably a methyl group, an ethyl group, a propyl group, an n-butyl group or a tert-butyl group.

The alkoxy group with which hydrogen atoms of the organic group may be substituted is preferably an alkoxy group of 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom with which hydrogen atoms of the organic group may be substituted include a fluorine atom, a chlorine atom, a bromine atom and an iodine atom, and a fluorine atom is preferable.

Specific examples of the organic group for P include groups represented by the formulas shown below.

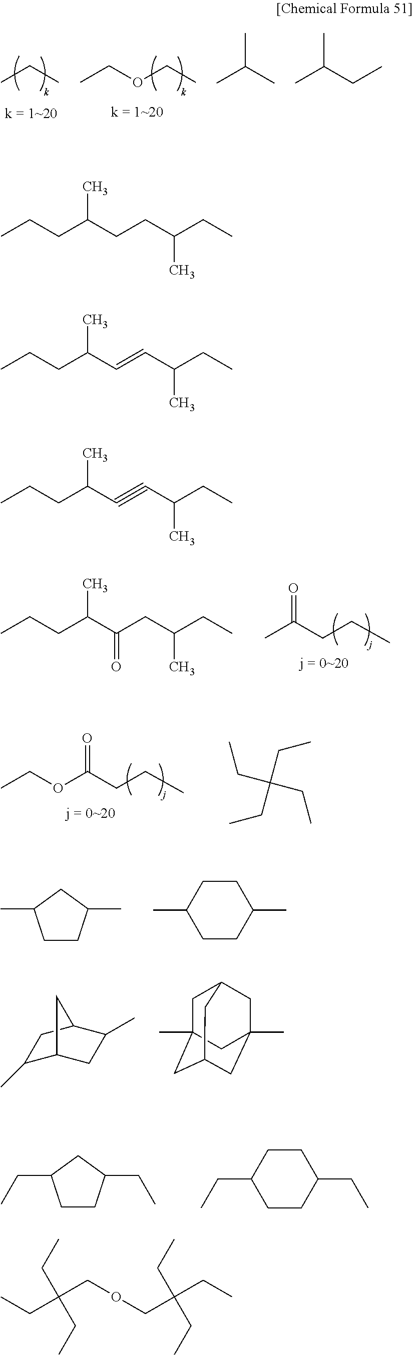

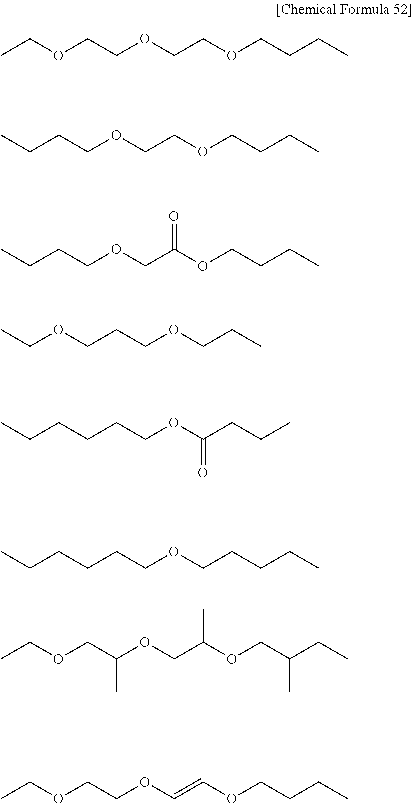

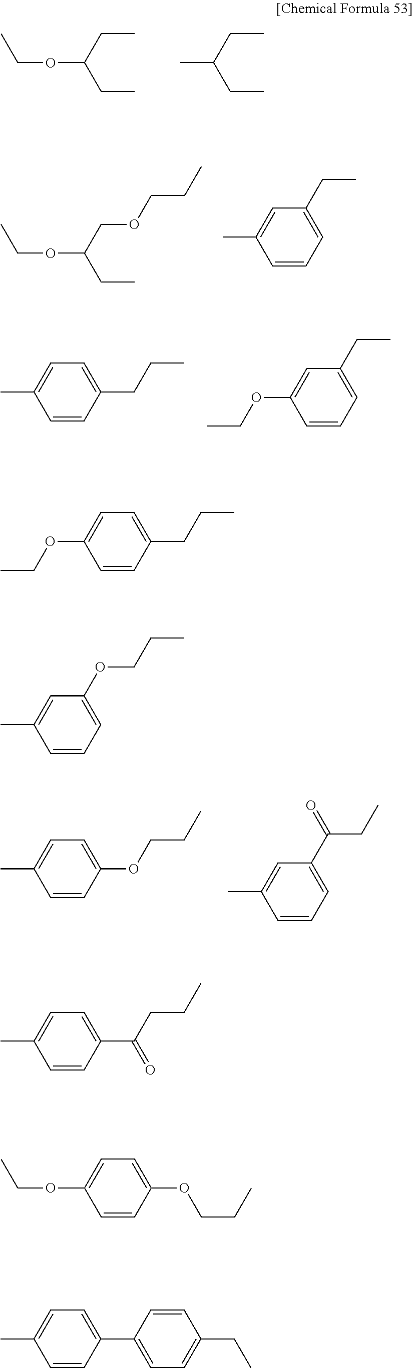

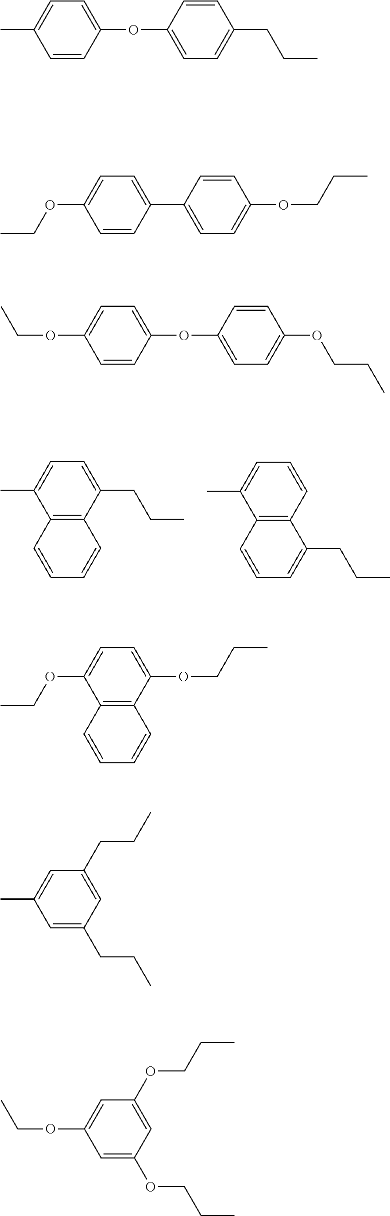

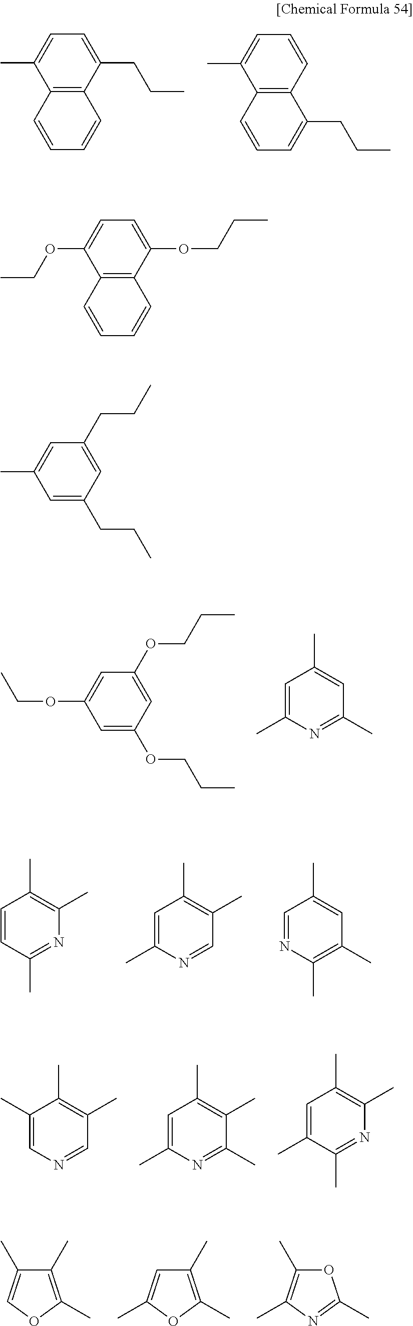

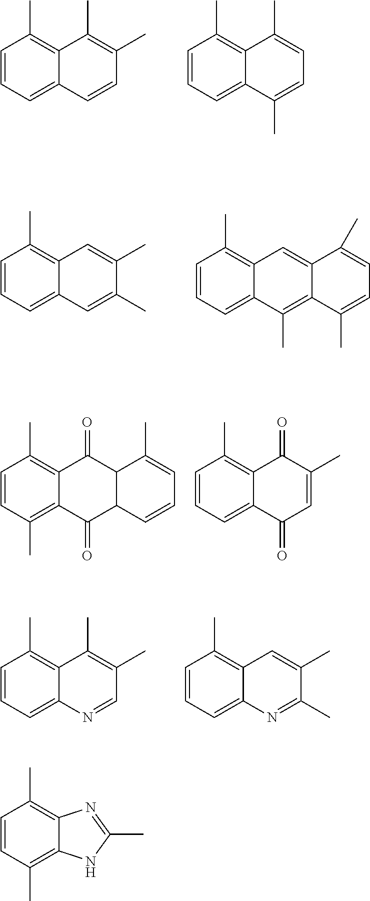

In general formula (1) above, Y represents an arylene group or an alkylene group of 1 to 12 carbon atoms.

The arylene group for Y is not particularly limited and includes, for example, a group in which two hydrogen atoms have been removed from an aromatic hydrocarbon ring of 6 to 20 carbon atoms. In terms of synthesizing at low cost, a group in which two hydrogen atoms have been removed from an aromatic hydrocarbon ring of 6 to 10 carbon atoms is preferable.

Specific examples of the arylene group include groups in which two hydrogen atoms have been removed from benzene, biphenyl, fluorene, naphthalene, anthracene, phenanthrene or pyrene, and a group in which two hydrogen atoms have been removed from benzene or naphthalene is particularly desirable.

Some or all of the hydrogen atoms in the aromatic hydrocarbon ring of the arylene group may or may not be substituted with substituents such as an alkyl group, an alkoxy group, a halogen atom, a halogenated alkyl group and a hydroxyl group (a group or atom other than a hydrogen atom).

The alkyl group with which the hydrogen atoms of the arylene group may be substituted is preferably an alkyl group of 1 to 5 carbon atoms, and particularly preferably a methyl group, an ethyl group, a propyl group, an n-butyl group or a tert-butyl group.

The alkoxy group with which the hydrogen atoms of the arylene group may be substituted is preferably an alkoxy group of 1 to 5 carbon atoms, more preferably a methoxy group, an ethoxy group, an n-propoxy group, an iso-propoxy group, an n-butoxy group or a tert-butoxy group, and particularly preferably a methoxy group or an ethoxy group.

The halogen atom with which the hydrogen atoms of the arylene group may be substituted is preferably a fluorine atom.

Examples of the halogenated alkyl group with which the hydrogen atoms of the arylene group may be substituted include a group in which some or all of the hydrogen atoms of the alkyl group listed above as the substituent of the arylene group have been substituted with halogen atoms. Examples of the halogen atom in the halogenated alkyl group include the same halogen atoms as those listed above as the substituents of the arylene group.

As the halogenated alkyl group, a fluorinated alkyl group is particularly desirable.

The alkylene group for Y is preferably a linear alkylene group or a branched alkylene group. The alkylene group has 1 to 12 carbon atoms, preferably 1 to 10 carbon atoms, more preferably 1 to 5 carbon atoms, and still more preferably 1 carbon atom (namely a methylene group), and most preferably, all of the a Y groups are methylene groups.

Some or all of the hydrogen atoms of the alkylene group may or may not be substituted with substituents (a group or atom other than a hydrogen atom). Examples of the substituents with which the hydrogen atoms of the alkylene group may be substituted include an alkyl group of 1 to 4 carbon atoms, an alkoxy group of 1 to 4 carbon atoms, and a hydroxyl group.

Among these, Y is more preferably an alkylene group of 1 to 12 carbon atoms, still more preferably a linear alkylene group, and most preferably an alkylene group of 1 carbon atom (namely, a methylene group) or 2 carbon atoms (namely, an ethylene group).

In general formula (1) above, X represents any one of bonding groups represented by general formulas (2) to (5) shown below which can be cleaved by the action of acid. Here, the expression “can be cleaved by the action of acid” means that because a partial structure of the structural unit (a0-1) acts like an acid upon exposure, a bond of a main chain of the polymer (A21) can be cleaved at the core portion.

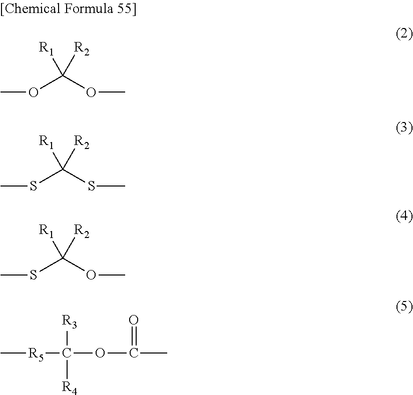

In general formulas (2) to (5) above, each of R¹, R², R³ and R⁴ independently represents a linear, branched or cyclic alkyl group of 1 to 12 carbon atoms which may be substituted with an alkoxy group, a hydroxyl group, a halogen atom or an epoxy group; an aryl group which may be substituted with an alkoxy group, a hydroxyl group, a halogen atom or an epoxy group; an alkoxy group; a hydroxyl group; or a hydrogen atom.

Examples of the halogen atom include a fluorine atom, a chlorine atom, a bromine atom and an iodine atom, and a fluorine atom is particularly desirable.

The alkyl group has 1 to 12 carbon atom and is preferably linear or branched, and more preferably an ethyl group or a methyl group.

The aryl group preferably has 6 to 20 carbon atoms, and examples thereof include a phenyl group and a naphthyl group.

The alkoxy group preferably has 1 to 5 carbon atoms and is more preferably a methoxy group, ethoxy group, n-propoxy group, iso-propoxy group, n-butoxy group or tert-butoxy group.

Of the various possibilities, groups in which both R¹ and R² are hydrogen atoms are particularly desirable. With respect to R³ and R⁴, it is preferred that either both of them represent an alkyl group; one of them represents an alkoxy group while the other represents an alkyl group; or one of them represents an alkoxy group while the other represents a hydrogen atom.

In general formula (5) above, R⁵ represents a linear, branched or cyclic alkylene group of 1 to 12 carbon atoms which may be substituted with an alkoxy group, a hydroxyl group, a halogen atom or an epoxy group; an arylene group which may be substituted with an alkoxy group, a hydroxyl group, a halogen atom or an epoxy group; or a single bond.

Examples of the halogen atom for R⁵ include the same halogen atoms as those listed above for R¹ to R⁴.

Examples of the alkoxy group for R⁵ include the same alkoxy groups as those listed above for R¹ to R⁴.

Examples of the alkylene group or arylene group for R⁵ include groups in which one hydrogen atom has been removed from the alkyl groups or aryl groups for R¹ to R⁴.

Of the various possibilities, R⁵ is preferably an alkylene group or a single bond.

Among bonding groups represented by general formulas (2) to (5) shown above, a bonding group represented by general formula (2) above and a bonding group represented by general formula (4) above are preferable, and a bonding group represented by general formula (2) above is most preferable, as the effects of the present invention become excellent.

Specific examples of suitable core portions of the polymer (A21) are shown below.

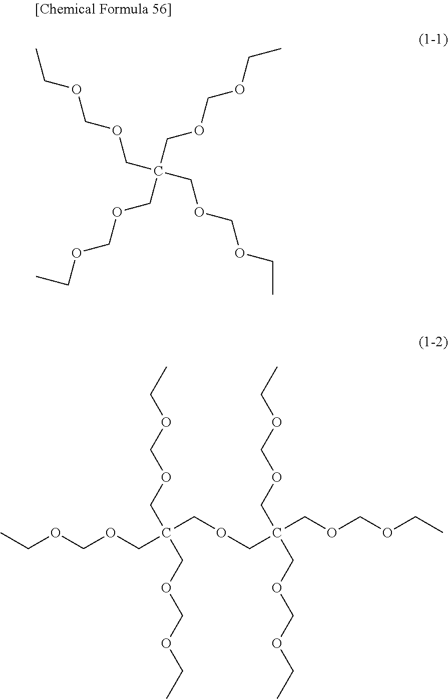

### (Arm Portion)

The arm portion of the polymer (A21) is bonded to the aforementioned core portion and is also composed of a polymer chain obtained by an anionic polymerization method.

The polymer chain to be bonded to the core portion is preferably bonded to each terminal (a terminal of Y in formula (1) above on the opposite side to X) of the core portion.

The polymer chains to be bonded to the core portion may be the same or different at the core portion, and the polymer chains are preferably the same with each other in terms of achieving superior effects for the present invention.

The polymer chain constituting the arm portions preferably has a structural unit derived from a hydroxystyrene derivative (hereafter, referred to as a structural unit (a5)).

Further the polymer chain constituting the arm portions preferably includes a structural unit (a1′) containing an acid dissociable, dissolution inhibiting group.

(Structural Unit (a5))

A structural unit (a5) is a structural unit derived from a hydroxystyrene derivative.

In the present description and claims, the term “hydroxystyrene derivative” is used as a general concept that includes hydroxystyrene, those in which the hydrogen atom on the α-position of a hydroxystyrene has been substituted with another substituent such as an alkyl group and a halogenated alkyl group, and derivatives thereof.

Unless specified otherwise, the α-position (the carbon atom on the α-position) refers to the carbon atom to which the benzene ring is bonded.

The term “structural unit derived from a hydroxystyrene derivative” refers to a structural unit which is formed by the cleavage of the ethylenic double bond of a hydroxystyrene derivative.

Preferred examples of the structural unit (a5) include structural units represented by general formula (a5-1) shown below.

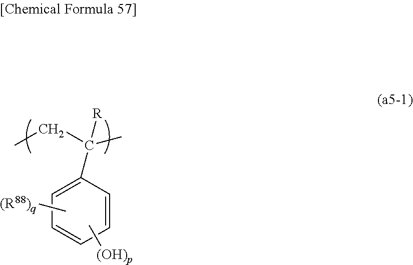

In formula (a5-1), R represents a hydrogen atom, an alkyl group of 1 to 5 carbon atoms or a halogenated alkyl group of 1 to 5 carbon atoms; R⁸⁸ represents an alkyl group of 1 to 5 carbon atoms or a halogen atom; p represents an integer of 1 to 3; and q represents an integer of 0 to 4, with the proviso that 1≦p+q≦5.

In general formula (a5-1) above, R is the same as the groups defined above for R¹ in formula (a0-1), is preferably a hydrogen atom or an alkyl group of 1 to 5 carbon atoms, and is most preferably a hydrogen atom or a methyl group.

p represents an integer of 1 to 3, and preferably 1.

The bonding position for the hydroxyl group may be any of the o-position, the m-position or the p-position of the phenyl group. When p is 1, the p-position is preferable in terms of availability and low cost. When p is 2 or 3, a desired combination of the substitution positions can be used.

q represents an integer of 0 to 4, preferably 0 or 1, and most preferably 0 from an industrial viewpoint.

Examples of the alkyl group of 1 to 5 carbon atoms for R⁸⁸ include the same alkyl groups of 1 to 5 carbon atoms as those listed above for R.

Examples of the halogen atom for R⁸⁸ include a fluorine atom, a chlorine atom, a bromine atom and an iodine atom, and a fluorine atom is preferable.

When q is 1, the substitution position of R⁸⁸ may be any of the o-position, the m-position and the p-position.

When q is 2, a desired combination of the substitution positions can be used.

However, 1≦p+q≦5.

As the structural unit (a5), one type of structural unit may be used alone, or two or more types of structural units may be used in combination.

The amount of the structural unit (a5) is preferably from 50 to 90 mol %, more preferably from 55 to 90 mol %, and still more preferably from 60 to 88 mol %, based on the combined total of all structural units constituting the polymer chain that serves as the arm portion. By making the amount of the structural unit (a5) at least as large as the lower limit of the above-mentioned range enables a suitable level of alkali solubility to be achieved. On the other hand, by making the amount of the structural unit (a5) no more than the upper limit of the above-mentioned range, a good balance can be achieved with the other structural units.

(Structural Unit (a1′))

As a structural unit (a1′) containing an acid dissociable, dissolution inhibiting group, the same structural units as those listed above as the structural unit (a1) can be used. Of the various possibilities, the structural unit (a1′) is preferably the structural unit (a12) described above.

As the structural unit (a1′), one type of structural unit may be used alone, or two or more types of structural units may be used in combination.

The amount of the structural unit (a1′) is preferably from 5 to 50 mol %, more preferably from 10 to 40 mol %, and still more preferably from 14 to 35 mol %, based on the combined total of all structural units constituting the polymer chain that serves as the arm portion. By making the amount of the structural unit (a1′) at least as large as the lower limit of the above-mentioned range, a pattern can be easily formed using a positive resist composition prepared. On the other hand, by making the amount of the structural unit (a1′) no more than the upper limit of the above-mentioned range, a good balance can be achieved with the other structural units.

The polymer chain constituting the arm portions of the polymer (A21) may also have a structural unit (hereafter, referred to as a structural unit (a6)) derived from styrene, as well as the structural unit (a5) and the structural unit (a1′).

For example, when the polymer chain constituting the arm portions is allowed to include the structural unit (a6), solubility in an alkali developing solution can be adjusted. It is also preferred since the dry etching resistance improves.

In the present description, the term “styrene” is used as a general concept that includes styrene, and those in which the hydrogen atom on the α-position of a styrene has been substituted with another substituent such as an alkyl group and a halogenated alkyl group.

The expression “structural unit derived from a styrene” refers to a structural unit which is formed by the cleavage of the ethylenic double bond of a styrene. Regarding the styrene, the hydrogen atoms of the phenyl group may be substituted with substituents such as an alkyl group of 1 to 5 carbon atoms.

Preferred examples of the structural unit (a6) include structural units represented by general formula (a6-1) shown below.

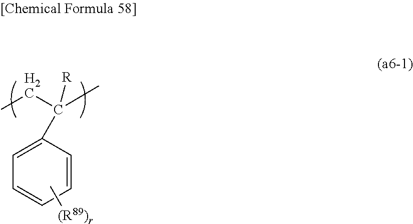

In formula (a6-1), R represents a hydrogen atom, an alkyl group of 1 to 5 carbon atoms or a halogenated alkyl group of 1 to 5 carbon atoms; R⁸⁹ represents an alkyl group of 1 to 5 carbon atoms or a halogen atom; and r represents an integer of 0 to 3.

In general formula (a6-1) above, R and R⁸⁹ are the same as defined for R and R⁸⁸ in formula (a5-1) above, respectively.

r represents an integer of 0 to 3, preferably 0 or 1, and most preferably 0 from an industrial viewpoint.

When r is 1, the substitution position of R⁸⁹ may be any of the o-position, m-position and p-position of the phenyl group. When r is 2 or 3, a desired combination of the substitution positions can be used.

As the structural unit (a6), one type of structural unit may be used alone, or two or more types of structural units may be used in combination.

When the arm portions of the polymer (A21) include the structural unit (a6), the amount of the structural unit (a6) is preferably from 1 to 20 mol %, more preferably from 3 to 15 mol %, and still more preferably from 5 to 15 mol %, based on the combined total of all structural units constituting the polymer chain that serves as the arm portion. Ensuring that this amount is at least as large as the lower limit of the above-mentioned range yields an improvement in the effects achieved by including the structural unit (a6), whereas by ensuring that the amount is not more than the upper limit of the above range, a good balance can be achieved with the other structural units.

Further, as other structural units of the arm portions of the polymer (A21), any of the multitude of conventionally known structural units used within resist resins for ArF excimer lasers or KrF excimer lasers such as structural units derived from an acrylate ester containing a lactone-containing cyclic group, structural units derived from an acrylate ester containing a polar group-containing aliphatic hydrocarbon group, and structural units derived from an acrylate ester containing a non-acid-dissociable aliphatic polycyclic group can be used.

In the present invention, the arm portions of the polymer (A21) are preferably composed of a polymer chain including at least one type of structural unit selected from the group consisting of the structural unit (a5) and the structural unit (a1′). Examples of such arm portions (polymer chain) include arm portions including the structural units (a5) and (a1′) and arm portions including the structural units (a5), (a1′) and (a6).

As the arm portions, arm portions including two types of structural units represented by general formula (A12-1) shown below are particularly desirable.

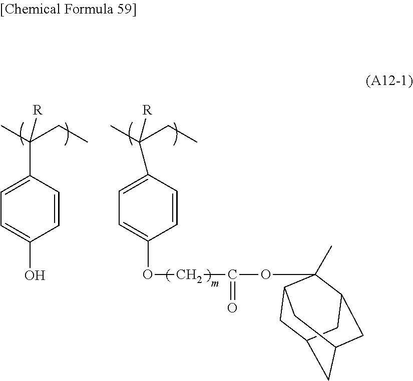

In the formula, R represents a hydrogen atom, an alkyl group of 1 to 5 carbon atoms or a halogenated alkyl group of 1 to 5 carbon atoms; and m is 1 or 2.

### (Method of Producing Polymer (A21))

The method of producing a polymer (A21) is not particularly limited and examples thereof include the following production method. A coupling agent for anionic polymerization is used as a material for providing the core portion represented by general formula (1) above, and the coupling agent for anionic polymerization is reacted with a polymer for providing arm portions obtained by an anionic polymerization method (hereafter, referred to as a polymer (a)) to synthesize a polymer (A21′). Subsequently, all or some of protecting groups for protecting phenolic hydroxy groups or the like in the polymer (A21′) are eliminated, and then an acid dissociable, dissolution inhibiting group or the like is preferably introduced, thereby producing a polymer (A21).

Such a method is preferred because it is easy to control each reaction and to control the structure of the polymer (A21).

The method of producing the polymer (A21) will be described in more detail below.

In the present invention, it is preferable to use a coupling agent for anionic polymerization as a material for providing the core portion represented by general formula (1) shown above.

More specifically, as the coupling agent for anionic polymerization, a compound represented by general formula (1′) shown below can be used because it exhibits excellent reactivity with the polymer (a) for providing arm portions, and the polymer (A21) can be easily produced.

[Chemical Formula 60]

PX—Y—Z)ₐ (1′)

In formula (1′), P, X, Y and a are the same as defined above for P, X, Y and a in general formula (1), respectively; and Z represents a halogen atom or an epoxy group represented by general formula (6) shown below.

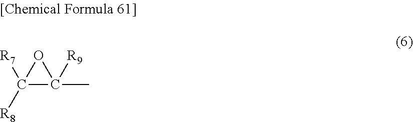

In formula (6), each of R⁷, R⁸ and R⁹ independently represents a hydrogen atom or an alkyl group of 1 to 12 carbon atoms.

In general formula (1′) above, P, X, Y and a are the same as defined above for P, X, Y and a in general formula (1) shown above.

Z represents a halogen atom or an epoxy group represented by general formula (6) above. Examples of the halogen atom include a chlorine atom, a bromine atom and an iodine atom. Of these, a chlorine atom and bromine atom are preferable and a bromine atom is most preferable.

In the present invention, when Z in general formula (1′) above is a chlorine atom, Y to be bonded thereto is preferably a methylene group.

Further, when Z in general formula (1′) above is a bromine atom, Y to be bonded thereto is preferably an alkylene group of 1 to 4 carbon atoms, and most preferably an alkylene group of 2 carbon atoms (ethylene group).

In general formula (6) above, each of R⁷, R⁸ and R⁹ independently represents a hydrogen atom or an alkyl group of 1 to 5 carbon atoms, preferably.

As the coupling agent for anionic polymerization represented by general formula (1′) above, for example, a compound represented by general formula (1′-1) shown below can be used.

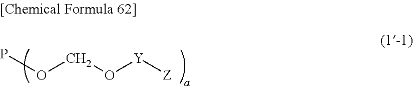

In formula (1′-1), P, Y, Z and a are the same as defined above for P, Y, Z and a in general formula (1) shown above, respectively.

More specifically, as the coupling agent for anionic polymerization, compounds represented by chemical formulas (1′-1-1) to (1′-1-4) shown below can be used.

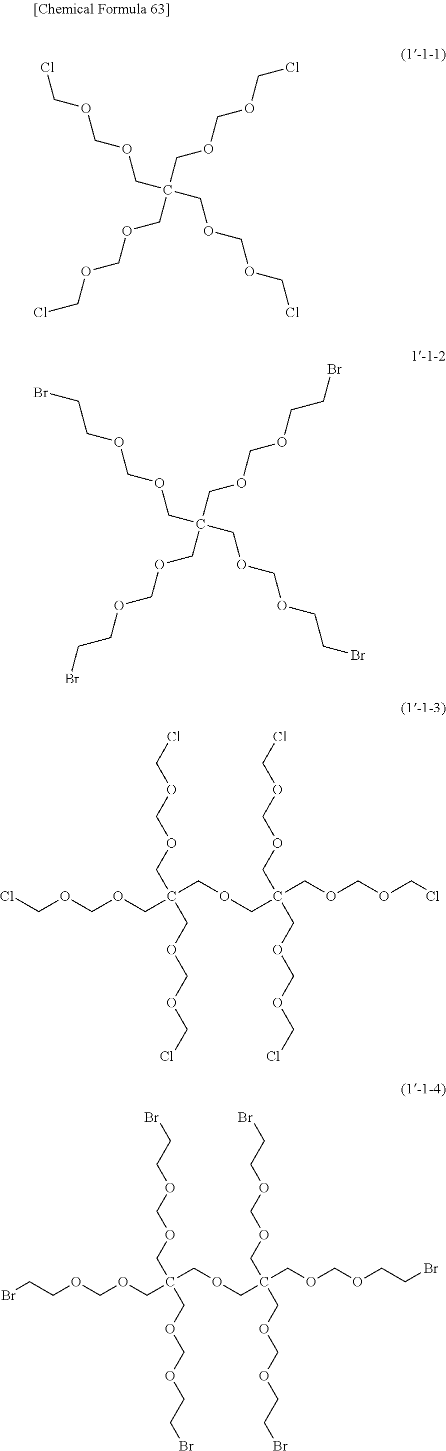

A method of producing a coupling agent for anionic polymerization represented by general formula (1′) above is not particularly limited, and, for example, a coupling agent for anionic polymerization containing a bonding group represented by general formula (1′) above can be produced by reacting a polyhydric alcohol (having a valence of a) with a chloromethyl halogen-substituted alkylether.

The polymer (a) for providing arm portions can be obtained, for example, through an anionic polymerization reaction of a monomer (hydroxystyrene derivative compound) for providing the aforementioned structural unit (a5), and, if desired, an anionically polymerizable monomer for providing other structural units, in the presence of an anionic polymerization initiator.

Examples of the anionic polymerization initiator include an alkali metal atom or an organic alkali metal compound.

Examples of the alkali metal atom include lithium, sodium, potassium and cesium atoms.

As the organic alkali metal compound, alkylated, allylated and arylated compounds of the above alkali metal atoms can be used. Specific examples thereof include ethyl lithium, n-butyl lithium, s-butyl lithium, t-butyl lithium, ethyl sodium, lithium biphenyl, lithium naphthalene, lithium triphenyl, sodium naphthalene, α-methylstyrene sodium dianion, 1,1-diphenylhexyl lithium and 1,1-diphenyl-3-methylpentyl lithium.

An anionic polymerization method of synthesizing a polymer (a) for providing arm portions can be conducted by any of a method of adding dropwise an anionic polymerization initiator in a monomer solution or a monomer mixed solution and a method of adding dropwise a monomer solution or a monomer mixed solution to a solution containing an anionic polymerization initiator. Of these methods, a method of adding dropwise a monomer solution or a monomer mixed solution to a solution containing an anionic polymerization initiator is preferable as it is easy to control a molecular weight and molecular weight distribution.

The anionic polymerization method of synthesizing the polymer (a) is preferably conducted under an atmosphere of an inert gas such as nitrogen or argon in an organic solvent at a temperature of −100 to 50° C., and more preferably at a temperature of −100 to 40° C.

Examples of the organic solvent used in the anionic polymerization method of synthesizing the polymer (a) include organic solvents typically used in an anionic polymerization method, for example, aliphatic hydrocarbons such as n-hexane and n-heptane; alicyclic hydrocarbons such as cyclohexane and cyclopentane; aromatic hydrocarbons such as benzene and toluene; ethers such as diethylether, tetrahydrofuran (THF) and dioxane; anisole, hexamethylphosphoramide and the like. Of these, toluene, n-hexane and THF are preferable.

These organic solvents can be used individually, or in combination as a mixed solvent.

When the polymer (a) for providing arm portions is a copolymer, the polymer can be in any polymer form such as a random copolymer, a partial block copolymer or a complete block copolymer. These polymers can be appropriately synthesized by selecting the method of adding a monomer used for polymerization.

The reaction of linking the polymer (a) for providing arm portions with a coupling agent for anionic polymerization for providing a core portion to synthesize the polymer (A21′) can be conducted by adding a coupling agent for anionic polymerization in the polymerization reaction solution after completion of the anionic polymerization of synthesizing the polymer (a).

Such a reaction is preferably conducted under an atmosphere of an inert gas such as nitrogen or argon in an organic solvent at a temperature of −100 to 50° C., and more preferably at a temperature of −80 to 40° C. As a result, the structure of the polymer (A21′) can be controlled and also a polymer having narrow molecular weight distribution can be obtained.

Further, the synthesis reaction of the polymer (A21′) can be continuously conducted in an organic solvent used in the anionic polymerization reaction of synthesizing the polymer (a) for providing arm portions, and also can be conducted after changing the composition by newly adding a solvent, or replacing the solvent with another solvent. The solvent, which can be used herein, may be the same organic solvent as that used in the anionic polymerization reaction of synthesizing the polymer (a) for providing arm portions.

The reaction of eliminating removing the protecting groups protecting the phenolic hydroxy groups or the like from the polymer (A21′) obtained in this manner is preferably conducted in the presence of a single solvent or a mixed solvent of two or more solvents selected from the solvents mentioned above in the polymerization reaction; alcohols such as methanol and ethanol; ketones such as acetone, methyl ethyl ketone and methyl isobutyl ketone (MIBK); polyhydric alcohol derivatives such as methyl cellosolve and ethyl cellosolve; and water, at a temperature within a range from room temperature to 150° C. using an acidic reagent as a catalyst, such as hydrochloric acid, sulfuric acid, oxalic acid, hydrogen chloride gas, hydrobromic acid, p-toluenesulfonic acid, 1,1,1-trifluoroacetic acid, and bisulfates represented by LiHSO₄, NaHSO₄ or KHSO₄. All or some of the protecting groups protecting the phenolic hydroxy groups can be eliminated by appropriately combining the types and concentrations of solvents, the types and added amounts of catalysts, and the reaction temperatures and reaction times in this reaction.

Note that when the arm portions of the polymer (A21) include a structural unit derived from an acrylate ester, ester groups of the structural unit can be converted into carboxy groups by hydrolysis.

This hydrolysis can be conducted by a method known in the relevant technical field, and, for example, can be conducted by acid hydrolysis under the same conditions as those for elimination of the above protecting groups. Hydrolysis of the ester groups is preferably conducted simultaneously with the elimination of protecting groups of phenolic hydroxyl groups. The thus obtained polymer (A21) containing a structural unit derived from an acrylate ester in the arm portion is particularly desirable as a resist material because it exhibits a high level of alkali solubility.

Further, after eliminating the protecting groups protecting the phenolic hydroxy groups from the polymer (A21′), protecting groups such as the acid dissociable, dissolution inhibiting groups mentioned above in connection with the explanation of the structural unit (a1) may be newly introduced.

These protecting groups can be introduced by a known method (for example, a method of reacting a protecting-group precursor compound containing a halogen atom in the presence of a basic catalyst).

The polymer (A21) obtained by the above production method can be used without being purified, or may be used after purification, if necessary.

The purification can be conducted by a method typically used in the relevant technical field and can be conducted, for example, by a fractional reprecipitation method. In the fractional reprecipitation method, reprecipitation is preferably conducted using a mixed solvent of a solvent exhibiting a high level of polymer solubility and a solvent exhibiting a low level of polymer solubility. For example, purification can be conducted by a method of dissolving the polymer (A21) with heating in a mixed solvent, followed by cooling, or by a method of dissolving the polymer (A21) in a solvent exhibiting a high level of polymer solubility, followed by the addition of a solvent exhibiting a low level of polymer solubility thereto to precipitate the polymer (A21).

The Mw/Mn value of the polymer (A21) is preferably from 1.01 to 3.00, more preferably from 1.01 to 2.00, and still more preferably from 1.01 to 1.50. Provided the Mw/Mn value of the polymer (A21) is not more than the upper limit of the above-mentioned range, the component (A2) exhibits satisfactory solubility in a resist solvent when used as a resist, whereas provided the Mw/Mn value of the polymer (A21) is at least as large as the lower limit of the above-mentioned range, the dry etching resistance and cross-sectional shape of the resist pattern can be improved.

Mw of the polymer (A21) is preferably from 1,000 to 1,000,000, more preferably from 1,500 to 500,000, still more preferably from 1,500 to 50,000, and most preferably from 2,000 to 20,000. When Mw of the polymer (A21) is within the above-mentioned range, the effects of the present invention are improved.

Further, Mw of the arm portion in the polymer (A21) is preferably from 300 to 50,000, more preferably from 500 to 10,000, and most preferably 500 to 8,000. Further, the average number of structural units (i.e., the average number of monomers) constituting the arm portion is preferably from 2 to 50, and more preferably from 3 to 30. When the average number of structural units is within the above-mentioned range, the effects of the present invention are improved.

In the component (A2), as the polymer (A21), one type may be used alone, or two or more types may be used in combination.

In the present invention, as the component (A2), one type of resin may be used alone, or two or more types of resins may be used in combination.

In the present invention, as the component (A2), components containing a resin that includes a combination of structural units represented by general formulas (A2-11) to (A2-14) shown below or those containing a resin represented by general formula (A2-15) shown below are particularly desirable. In each of the following formulas, R, R^{1′}, R¹¹, R¹², R²⁹, s″, h and j are the same as defined above, and the plurality of R, R¹¹ and R^{1′} in the formulas may be the same or different from each other.

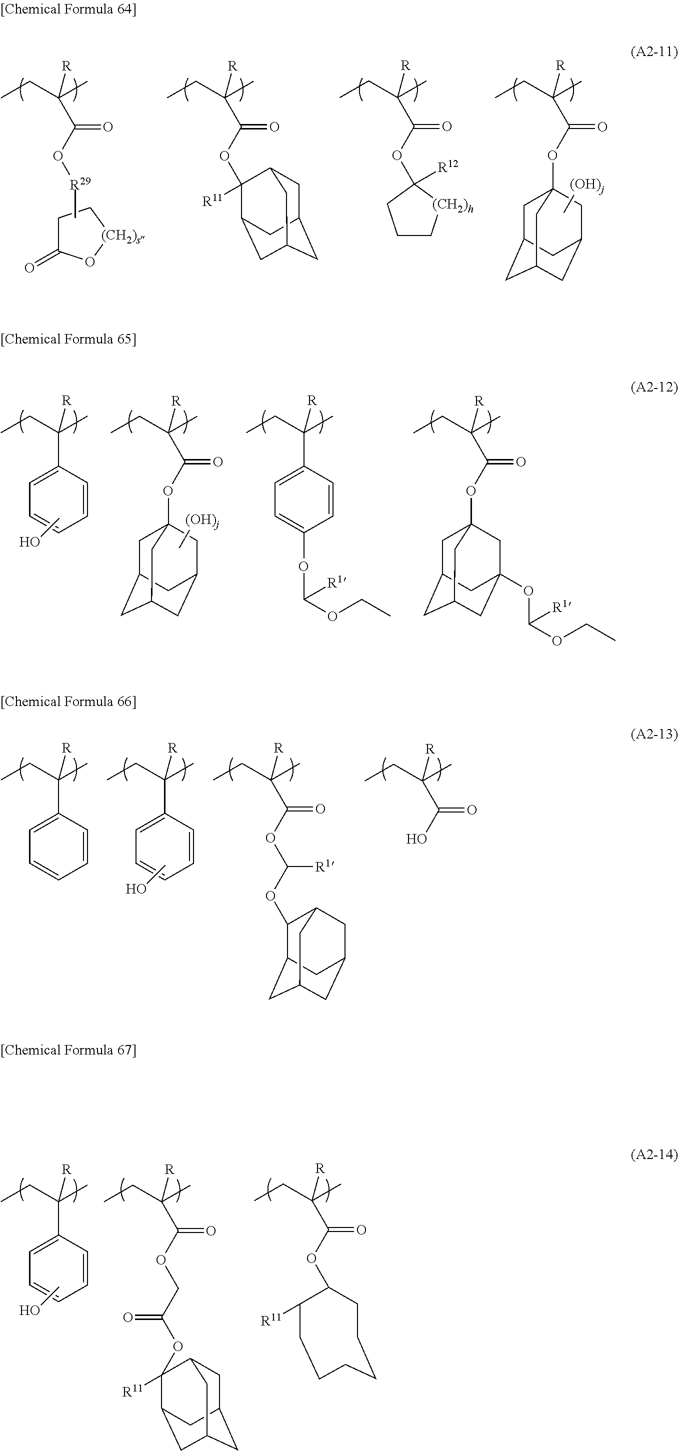

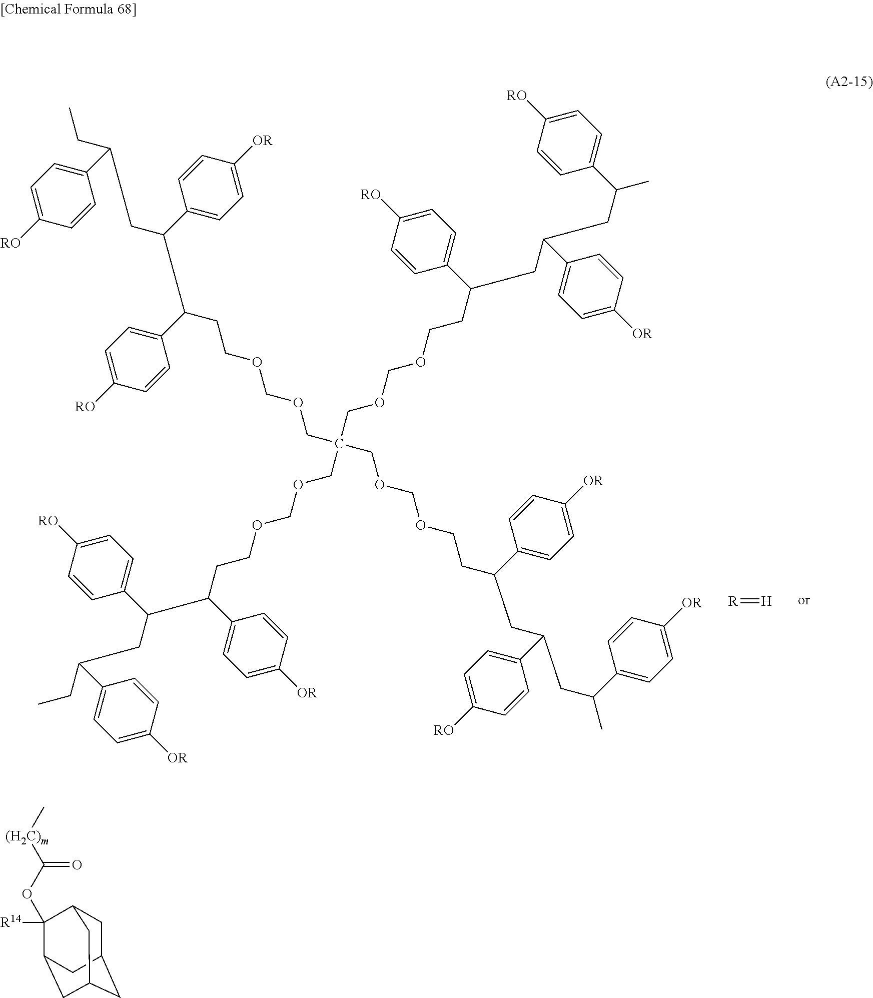

(m is 1 or 2)

### [Component (A3)]

As the component (A3), a low molecular weight compound that has a molecular weight of at least 500 but less than 2,500, contains a hydrophilic group, and also contains an acid dissociable, dissolution inhibiting group such as the groups exemplified above in the description of the component (A1) is preferred. Specific examples include compounds containing a plurality of phenol skeletons in which a part of the hydrogen atoms within hydroxyl groups have been substituted with the aforementioned acid dissociable, dissolution inhibiting groups.

Examples of the component (A3) include low molecular weight phenol compounds in which a portion of the hydroxyl group hydrogen atoms have been substituted with an aforementioned acid dissociable, dissolution inhibiting group. These types of compounds are known, for example, as sensitizers or heat resistance improvers for use in non-chemically amplified g-line or i-line resists, and any of these compounds may be used.

Specific examples of the low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers to hexamers of formalin condensation products of phenols such as phenol, m-cresol, p-cresol and xylenol. Needless to say, the low molecular weight phenol compound is not limited to these examples. Among these, in terms of achieving excellent resolution and LWR, a phenol compound having 2 to 6 triphenylmethane skeletons is particularly desirable.

Also, there are no particular limitations on the acid dissociable, dissolution inhibiting group, and suitable examples include the groups described above.

As the component (A3), one type may be used alone, or two or more types may be used in combination.

In the resist composition of the present invention, as the component (A′), one type may be used alone, or two or more types may be used in combination.

In the resist composition of the present invention, the amount of the component (A′) can be appropriately adjusted depending on the thickness of the resist film to be formed.

### <Optional Component (Component (D))>

The positive resist composition of the present invention may further include a nitrogen-containing organic compound (D) (hereafter, referred to as “component (D)”) as an optional component.

There are no particular limitations on the component (D) as long as it is a nitrogen-containing organic compound to act as an acid diffusion control agent, i.e., a quencher which traps the acid generated from the component (A′) upon exposure. A multitude of these nitrogen-containing organic compounds have already been proposed, and any of these known nitrogen-containing organic compounds may be used, although an aliphatic amine, and particularly a secondary aliphatic amine or tertiary aliphatic amine is preferable. Here, the term “aliphatic amine” refers to an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of no more than 20 carbon atoms (that is, alkylamines or alkyl alcohol amines), and cyclic amines.

Specific examples of alkylamines and alkyl alcohol amines include monoalkylamines such as n-hexylamine, n-heptylamine, n-octylamine, n-nonylamine and n-decylamine, dialkylamines such as diethylamine, di-n-propylamine, di-n-heptylamine, di-n-octylamine and dicyclohexylamine, trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine and tri-n-dodecylamine, and alkyl alcohol amines such as diethanolamine, triethanolamine, diisopropanolamine, triisopropanolamine, di-n-octanolamine, tri-n-octanolamine, stearyldiethanolamine and lauryldiethanolamine. Among these, at least one compound selected from the group consisting of trialkylamines and alkyl alcohol amines is preferred.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of aromatic amines include aniline, pyridine, 4-dimethylaminopyridine, pyrrole, indole, pyrazole, imidazole and derivatives thereof, as well as diphenylamine, triphenylamine and tribenzylamine.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

These compounds can be used either alone, or in combinations of two or more different compounds.

The component (D) is typically used in an amount within a range from 0.01 to 5.0 parts by weight, relative to 100 parts by weight of the component (A′). By ensuring that the amount of the component (D) is within the above-mentioned range, the shape of the resist pattern and the post exposure stability of the latent image formed by the pattern-wise exposure of the resist layer are improved.

### <Optional Component (Component (E))>

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added as an optional component.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid, and among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type of compound may be used alone, or two or more types of compounds may be used in combination.

As the component (E), an organic carboxylic acid is preferable, and salicylic acid is particularly desirable.

The component (E) is typically used in an amount within a range from 0.01 to 5.0 parts by weight, relative to 100 parts by weight of the component (A′).

If desired, miscible additives other than those described above can also be added to the positive resist composition of the present invention. Examples of such miscible additives include additive resins for improving the performance of the resist film, surfactants for improving the applicability, dissolution inhibitors, plasticizers, stabilizers, colorants, halation prevention agents, and dyes.

### <Optional Component (Component (S))>

The positive resist composition of the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone;

ketones such as acetone, methyl ethyl ketone, cyclohexanone, methyl-n-pentyl ketone, methyl isopentyl ketone, and 2-heptanone;

polyhydric alcohols, such as ethylene glycol, diethylene glycol, propylene glycol and dipropylene glycol;

compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable);

cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and

aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents may be used individually, or as a mixed solvent containing two or more different solvents.

Among these, propylene glycol monomethyl ether acetate (PGMEA), propylene glycol monomethyl ether (PGME), ethyl lactate (EL) and cyclohexanone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in a range from 1:9 to 9:1, and more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably from 3:7 to 7:3.

Alternatively, when cyclohexanone is mixed as the polar solvent, the PGMEA:cyclohexanone weight ratio is preferably from 1:9 to 9:1, more preferably from 2:8 to 8:2, and still more preferably 3:7 to 7:3, and the PGMEA:PGME:cyclohexanone weight ratio is preferably from (2 to 9):(0 to 5):(0 to 4.5) and more preferably from (3 to 9):(0 to 4):(0 to 3.5).

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) used is not particularly limited, and is appropriately adjusted to a concentration which enables coating of a coating solution to a substrate, depending on the thickness of the coating film. In general, the component (S) is used in an amount such that the solid content of the resist composition becomes within the range from 1 to 20% by weight, and preferably from 2 to 15% by weight.

By the positive resist composition of the present invention, the shape of the resist pattern to be formed (for example, circularity of the holes of a hole pattern), and various lithography properties are improved.

Although the reasons why the above-mentioned effects can be achieved have not been elucidated yet, in the positive resist composition of the present invention, it is thought that a partial —SO₂— structure of R³ in the structural unit (a0-1) in the base component becomes —SO₂⁻ upon exposure and acts like an acid generator. As a result, it is not necessary to use, separately from the base component, a component having only a function as a conventional acid generator (hereafter, referred to as an acid generator component), and it is presumed that the above-mentioned effects can be achieved because the structural unit (a0-1) is uniformly distributed within the resist film together with the component (A′), and the structural unit (a0-1) exhibits an acid-generating capability in the exposed portions, thereby uniformly dissociating the acid dissociable, dissolution inhibiting groups in the component (A′) within the exposed portions.

Further, in the present invention, it is also assumed that acid diffusion in the exposed portions can be controlled and the above-mentioned effects can be achieved because the structural unit (a1) having an acid dissociable, dissolution inhibiting group and the structural unit (a0-1) are copolymerized. Especially, it is thought that an increase in the resolution can be expected by the shortening of the diffusion length of the acid.

Further, because the positive resist composition of the present invention does not include a conventional acid generator component, the sensitivity can be controlled to an adequate level. For this reason, the positive resist composition of the present invention can be used, not only in lithography processes employing typical exposure light sources such as ArF excimer lasers and KrF excimer lasers, but also in lithography processes employing exposure light sources that require low sensitivity such as low energy EB and EUV, and thus has a wide application range.

Furthermore, in the present invention, by virtue of the structural unit (a0-1) having a cyclic group containing —SO₂— (which is a polar group) on the terminal of a relatively long side chain, the adhesion of the resist composition to substrates is improved, and pattern collapse can also be better suppressed.

### <<Method of Forming a Resist Pattern>>

The method of forming a resist pattern according to the present invention includes: applying a resist composition of the present invention to a substrate to form a resist film on the substrate; conducting exposure of the resist film; and developing the resist film to form a resist pattern.

More specifically, the method of forming a resist pattern according to the present invention can be performed, for example, as follows.

Firstly, the positive resist composition according to the present invention described above is applied onto a substrate using a spinner or the like, and a prebake (post applied bake (PAB)) is conducted under temperature conditions of 80 to 150° C. for 40 to 120 seconds, preferably 60 to 90 seconds, to form a resist film. Then, for example, the resist film is selectively exposed either by exposure through a mask pattern using an exposure apparatus such as an ArF exposure apparatus, an electron beam lithography apparatus or an EUV exposure apparatus, or by patterning via direct irradiation with an electron beam without using a mask pattern, followed by post exposure bake (PEB) under temperature conditions of 80 to 150° C. for 40 to 120 seconds, preferably 60 to 90 seconds. Subsequently, developing is conducted using an alkali developing solution such as a 0.1 to 10% by weight aqueous solution of tetramethylammonium hydroxide (TMAH), preferably followed by rinsing with pure water, and drying. If desired, a bake treatment (post bake) may be conducted following the above developing treatment.

In this manner, a resist pattern that is faithful to the mask pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum, as well as glass substrates. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) can be used.

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective for use with a KrF excimer laser, ArF excimer laser, EB and EUV, and is particularly effective to an ArF excimer laser.

The exposure method used with the resist film may be either a general exposure method (dry exposure) conducted in air or an inert gas such as nitrogen, or an immersion exposure (liquid immersion lithography) method.

In liquid immersion lithography, the region between the resist film and the lens at the lowermost point of the exposure apparatus is pre-filled with a solvent (an immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be subjected to exposure. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point: 102° C.), and an example of a suitable perfluoroalkylamine compound is perfluorotributylamine (boiling point: 174° C.).

As the immersion medium, water is preferable in terms of cost, safety, environmental issues and versatility.

### EXAMPLES

A more detailed description of the present invention is presented below based on a series of examples, although the scope of the present invention is in no way limited by these examples.

In the following examples, a unit represented by a chemical formula (1) is designated as “compound (1)”, and the same labeling system applies for compounds represented by other formulas.

In the NMR analysis, the internal standard for ¹H-NMR and ¹³C-NMR was tetramethylsilane (TMS). The internal standard for ¹⁹F-NMR was hexafluorobenzene (provided that the peak of hexafluorobenzene was regarded as −160 ppm).

### Monomer Synthesis Example 1

### Synthesis of Compound (21)

A compound (21) from which a structural unit (21) described later was derived was synthesized as follows.

50 g of a precursor (1) and 37.18 g of an alcohol (1) were dissolved in 500 ml of tetrahydrofuran (THF) in a three-necked flask in a nitrogen atmosphere. Subsequently, 56.07 g of ethyldiisopropylaminocarbodiimide hydrochloride (EDCI.HCl) was added to the resulting solution, and cooled to 0° C. Then, dimethylaminopyridine (DMAP) was added thereto and reacted for 10 minutes. Thereafter, a reaction was performed at room temperature for 12 hours. After the completion of the reaction, 100 ml of water was added, and the resultant was concentrated under reduced pressure. Then, extraction was conducted with ethyl acetate, and the obtained organic phase was washed with water. Then, extraction was conducted with ethyl acetate, and the obtained organic phase was washed with an aqueous sodium hydrocarbonate solution. This operation was conducted three times in total. Then, extraction was conducted with ethyl acetate, and the obtained organic phase was washed with water. Then, extraction was conducted with ethyl acetate, and the obtained organic phase was washed with aqueous hydrochloric acid solution. This operation was conducted twice. Then, extraction was conducted with ethyl acetate, and the obtained organic phase was washed with water. This operation was conducted three times in total.

Thereafter, extraction was conducted with ethyl acetate, and the obtained organic phase was concentrated under reduced pressure, followed by washing with heptane twice and drying, thereby obtaining 58.10 g of a compound (21) as an objective compound.

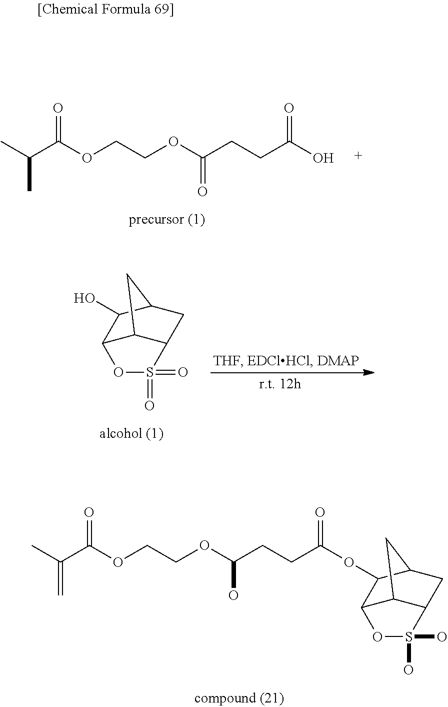

The results of instrumental analysis of the obtained compound (21) were as follows.

¹H-NMR: 6.12 (1H, a, s), 5.60 (1H, b, s), 4.73-4.71 (2H, c, m), 4.34 (4H, d, s), 3.55 (1H, e, m), 3.48 (1H, f, m), 2.68-2.57 (4H, g, m), 2.16-1.76 (5H, h, m), 1.93 (3H, i, s)

From the results above, it was confirmed that the compound (21) had a structure shown below.

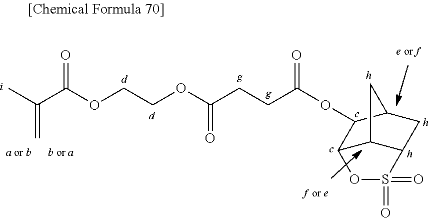

### [Synthesis of Polymeric Compound]

Various polymeric compounds were obtained by a conventional dropwise polymerization method or the like, with reference to Japanese Unexamined Patent Application, First Publication No. 2010-113334, WO2004-059392, or the like.

With respect to each polymeric compound, the weight average molecular weight and the dispersity (Mw/Mn) determined by the polystyrene equivalent value as measured by gel permeation chromatography (GPC) are shown in Tables 1 and 2. The structural units (1) to (21) constituting each polymeric compound are as follows.

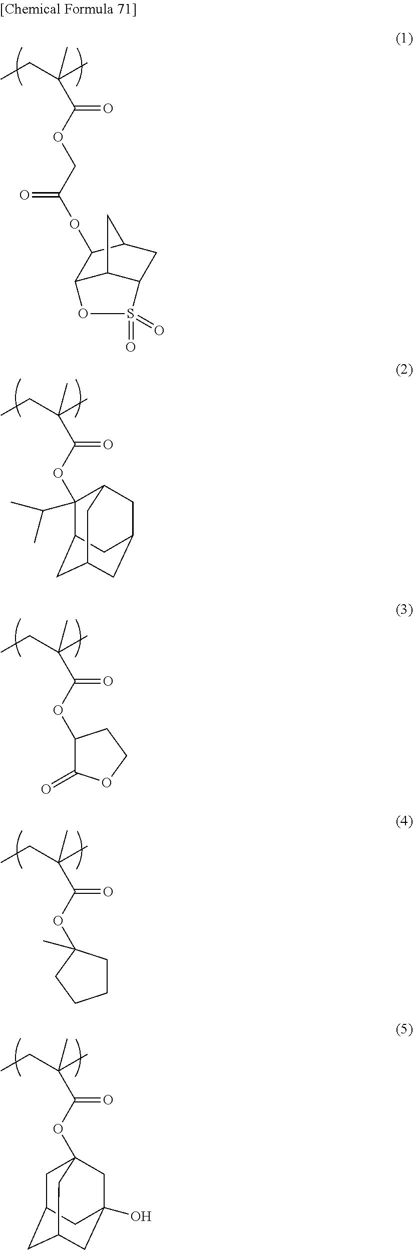

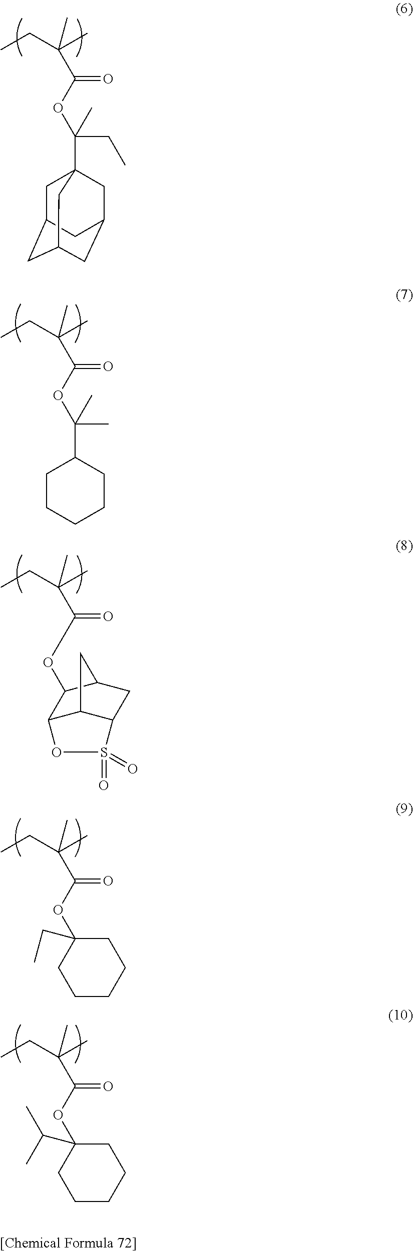

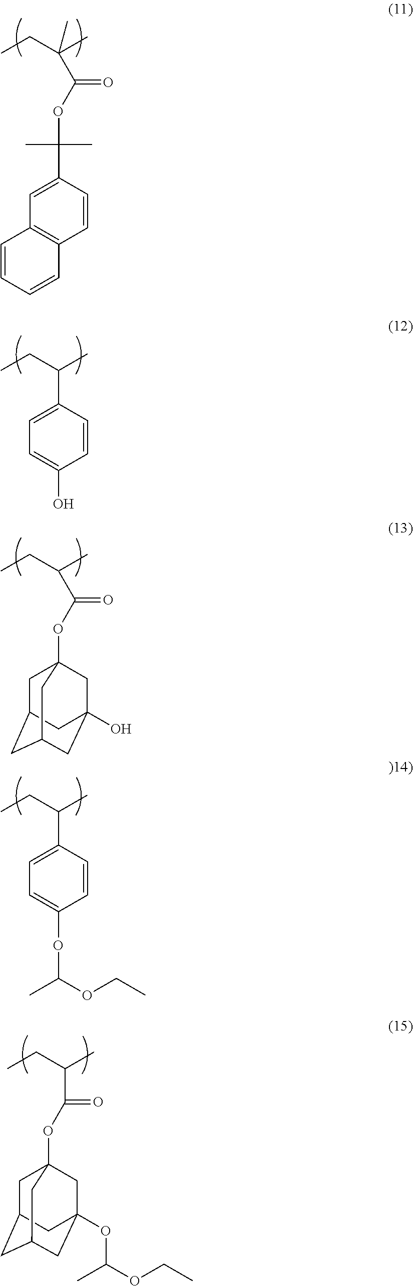

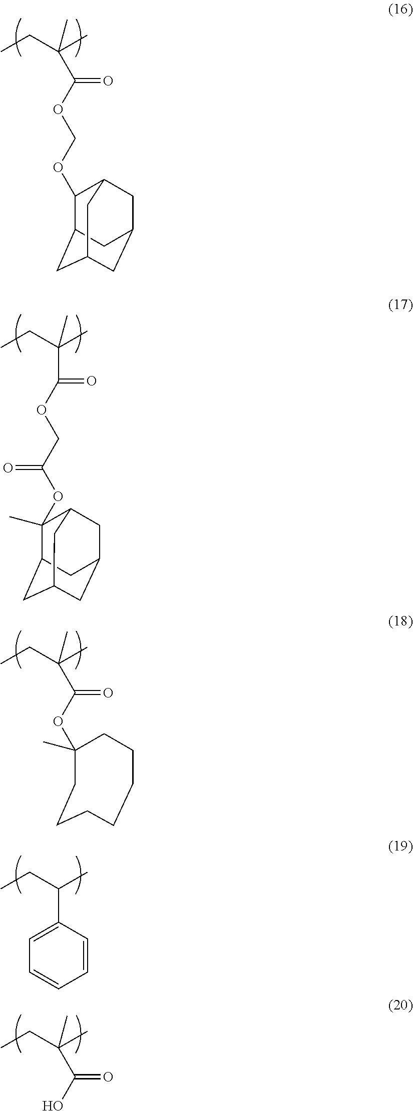

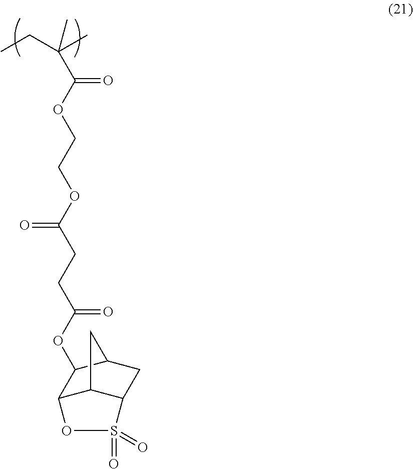

TABLE 1

| | Polymeric compound | | | | | | | | | |
|---|---|---|---|---|---|---|---|---|---|---|
| | 1 | 2 | 3 | 4 | 5 | 6 | 7 | 8 | 9 | 10 |
| (1) | 22 | 50 | 40 | — | — | 50 | 50 | 50 | 70 | — |
| (2) | 18 | 50 | — | 25 | — | — | — | — | — | — |
| (3) | 35 | — | — | 25 | — | — | — | — | — | — |
| (4) | 13 | — | — | 25 | — | — | — | — | — | — |
| (5) | 12 | — | 10 | 25 | — | — | — | — | — | — |
| (6) | — | — | 5 | — | — | — | — | — | — | — |
| (7) | — | — | 45 | — | — | — | — | — | — | — |
| (8) | — | — | — | — | 50 | — | — | — | — | — |
| (9) | — | — | — | — | 50 | 50 | — | — | — | — |
| (10) | — | — | — | — | — | — | 50 | — | 30 | — |
| (11) | — | — | — | — | — | — | — | 50 | — | — |
| (12) | — | — | — | — | — | — | — | — | — | 57 |
| (13) | — | — | — | — | — | — | — | — | — | 16 |
| (14) | — | — | — | — | — | — | — | — | — | 24 |
| (15) | — | — | — | — | — | — | — | — | — | 3 |
| (16) | — | — | — | — | — | — | — | — | — | — |
| (17) | — | — | — | — | — | — | — | — | — | — |
| (18) | — | — | — | — | — | — | — | — | — | — |
| (19) | — | — | — | — | — | — | — | — | — | — |
| (20) | — | — | — | — | — | — | — | — | — | — |
| (21) | — | — | — | — | — | — | — | — | — | — |
| Mw | 7,000 | 7,000 | 7,000 | 7,000 | 7,000 | 7,000 | 7,000 | 7,000 | 7,000 | 8,000 |
| Mw/Mn | 1.6 | 1.6 | 1.6 | 1.6 | 1.6 | 1.6 | 1.6 | 1.6 | 1.6 | 1.7 |

TABLE 2

| | Polymeric compound | | | | | |
|---|---|---|---|---|---|---|
| | 11 | 12 | 13 | 14 | 15 | 16 |
| (1) | — | — | 33 | — | 40 | — |
| (2) | — | — | — | — | — | — |
| (3) | — | — | 33 | — | — | 50 |
| (4) | — | — | — | — | — | — |
| (5) | — | — | 33 | — | 20 | 20 |
| (6) | — | — | — | — | — | — |
| (7) | — | — | — | — | — | — |
| (8) | — | — | — | — | — | — |
| (9) | — | — | — | 50 | 40 | 30 |
| (10) | — | — | — | — | — | — |
| (11) | — | — | — | — | — | — |
| (12) | 60 | 63 | — | — | — | — |
| (13) | — | — | — | — | — | — |
| (14) | — | — | — | — | — | — |
| (15) | — | — | — | — | — | — |
| (16) | 24 | — | — | — | — | — |
| (17) | — | 24 | — | — | — | — |
| (18) | — | 13 | — | — | — | — |
| (19) | 10 | — | — | — | — | — |
| (20) | 6 | — | — | — | — | — |
| (21) | — | — | — | 50 | — | — |
| Mw | 8,000 | 7,000 | 7,000 | 7,000 | 7,000 | 7,000 |
| Mw/Mn | 1.7 | 1.6 | 1.6 | 1.6 | 1.6 | 1.6 |

### Examples 1 to 15

### Comparative Examples 1 to 2

The components shown in Table 3 were mixed together and dissolved to obtain positive resist compositions.

TABLE 3

| | Compo- | | Compo- | PEB | Eop | Resolution | |
|---|---|---|---|---|---|---|---|
| | nent (A′) | | nent (S) | (° C.) | (μC/cm²) | (nm) | Shape |
| Ex. 1 | (A)-1 | | (S)-1 | 100 | >400 | 500 | B |
| | [100] | | [4,900] | | | | |
| Ex. 2 | (A)-2 | | (S)-1 | 100 | 400 | 50 | A |
| | [100] | | [4,900] | | | | |
| Ex. 3 | (A)-2 | | (S)-1 | 120 | 180 | 50 | A |
| | [100] | | [4,900] | | | | |
| Ex. 4 | (A)-3 | | (S)-1 | 100 | 400 | 50 | A |
| | [100] | | [4,900] | | | | |
| Ex. 5 | (A)-3 | | (S)-1 | 120 | 180 | 50 | A |
| | [100] | | [4,900] | | | | |
| Ex. 6 | (A)-2 | (A)-4 | (S)-1 | 100 | >400 | 100 | B |
| | [75] | [25] | [4,900] | | | | |
| Ex. 7 | (A)-2 | (A)-4 | (S)-1 | 100 | >400 | 500 | B |
| | [50] | [50] | [4,900] | | | | |
| Ex. 8 | (A)-5 | | (S)-1 | 100 | >400 | 500 | B |
| | [100] | | [4,900] | | | | |
| Ex. 9 | (A)-6 | | (S)-1 | 100 | 400 | 50 | A |
| | [100] | | [4,900] | | | | |
| Ex. 10 | (A)-7 | | (S)-1 | 100 | 400 | 50 | A |
| | [100] | | [4,900] | | | | |
| Ex. 11 | (A)-8 | | (S)-1 | 100 | >400 | 500 | B |
| | [100] | | [4,900] | | | | |
| Ex. 12 | (A)-9 | (A)-10 | (S)-1 | 100 | 400 | 100 | B |
| | [50] | [50] | [4,900] | | | | |
| Ex. 13 | (A)-9 | (A)-11 | (S)-1 | 100 | 400 | 100 | B |
| | [50] | [50] | [4,900] | | | | |
| Ex. 14 | (A)-9 | (A)-12 | (S)-1 | 100 | 400 | 100 | B |
| | [50] | [50] | [4,900] | | | | |
| Ex. 15 | (A)-9 | (A)-17 | (S)-1 | 100 | 400 | 50 | B |
| | [50] | [50] | [4,900] | | | | |
| Comp. | (A)-13 | | (S)-1 | 100 | — | — | C |
| Ex. 1 | [100] | | [4,900] | | | | |
| Comp. | (A)-4 | | (S)-1 | 100 | — | — | C |
| Ex. 2 | [100] | | [4,900] | | | | |

In Table 3, the values in brackets [ ] indicate the amount (in terms of parts by weight) of the component added. Further, the reference characters in Table 3 indicate the following.
(A)-1: the aforementioned polymeric compound 1
(A)-2: the aforementioned polymeric compound 2
(A)-3: the aforementioned polymeric compound 3
(A)-4: the aforementioned polymeric compound 4
(A)-5: the aforementioned polymeric compound 5
(A)-6: the aforementioned polymeric compound 6
(A)-7: the aforementioned polymeric compound 7
(A)-8: the aforementioned polymeric compound 8
(A)-9: the aforementioned polymeric compound 9
(A)-10: the aforementioned polymeric compound 10
(A)-11: the aforementioned polymeric compound 11
(A)-12: the aforementioned polymeric compound 12
(A)-13: the aforementioned polymeric compound 13
(A)-17: a polymeric compound 17 shown below. It was synthesized in accordance with Examples described in US2010-55606A1.
(S)-1: a mixed solvent of PGMEA/PGME/cyclohexanone=45/30/25 (weight ratio)

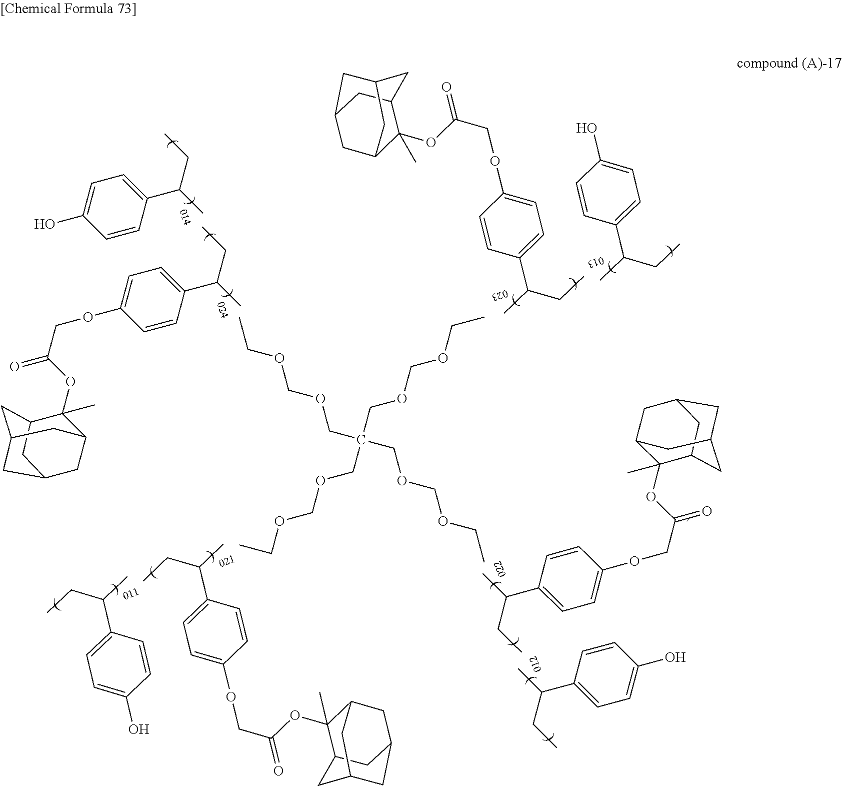

[Average arm length: heptamer; Mw=4,000; Mw/Mn=1.31; (b11+b12+b13+b14)/(b21+b22+b23+b24)=85/15 (molar ratio)]

### <Resist Pattern Formation 1>

### [Optimum Exposure Dose •Resolution]

Using a spinner, each of the above positive resist compositions was applied uniformly onto an 8-inch silicon substrate that had been surface-treated with hexamethyldisilazane (HMDS) for 36 seconds at 90° C., and a prebake treatment (PAB) was then conducted for 60 seconds at 100° C., thereby forming a resist film (film thickness: 50 nm).

This resist film was subjected to exposure with an electron beam lithography apparatus HL-800D (VSB) (manufactured by Hitachi Ltd.) at an accelerating voltage of 70 kV, and was then subjected to a post exposure bake treatment (PEB) for 60 seconds at the temperature shown in Table 3. This resist film was then subjected to development for 30 seconds at 23° C. in a 2.38% by weight aqueous solution of tetramethylammonium hydroxide (TMAH) (product name: NMD-3, manufactured by Tokyo Ohka Kogyo Co., Ltd.), followed by rinsing with pure water for 15 seconds, thereby forming a line and space (L/S) pattern.

At this time, the critical resolution (nm) was evaluated using 1:1 L/S patterns having a line width of 500 nm, 200 nm, 100 nm, and 50 nm as targets. The results are indicated under “resolution (nm)” in Table 3. Further, the optimum exposure dose (Eop; μC/cm²) with which the L/S pattern at the critical resolution for each resist composition was formed is also shown in Table 3.

### [Evaluation of Pattern Shape]

The cross-sectional shape of the 1:1 L/S pattern at the above-mentioned critical resolution for each resist composition was observed using a scanning electron microscope (product name: S-4700; manufactured by Hitachi, Ltd.) and evaluated with the following criteria. The results are shown in Table 3.

A: High rectangularity

B: Low rectangularity with headless shape

C: Tapered shape with no rectangularity

From the above results, it is evident that the resist compositions of Examples 1 to 15 according to the present invention resulted in excellent resolution, as compared to the resist compositions of Comparative Examples 1 and 2. It became apparent that the resist compositions of Examples 2 to 5 and 9 to 10 also yielded a particularly superior resist pattern shape.

### Examples 16 to 20

### Comparative Example 3

The components shown in Table 4 were mixed together and dissolved to obtain positive resist compositions.

TABLE 4

| | Compo- | Compo- | PAB | PEB | Eth | Con- |
|---|---|---|---|---|---|---|
| | nent (A′) | nent (S) | (° C.) | (° C.) | (μC/cm²) | trast |
| Ex. 16 | (A)-15 | (S)-1 | 100 | 120 | 210 | A |
| | [100] | [4,900] | | | | |
| Ex. 17 | (A)-14 | (S)-1 | 100 | 100 | 190 | A |
| | [100] | [4,900] | | | | |
| Ex. 18 | (A)-2 | (S)-1 | 100 | 100 | 190 | A |
| | [100] | [4,900] | | | | |
| Comp. | (A)-16 | (S)-1 | 100 | 120 or | — | B |
| Ex. 3 | [100] | [4,900] | | 100 | | |
| Ex. 19 | (A)-5 | (S)-1 | 100 | 100 | 400 | A |
| | [100] | [4,900] | | | | |
| Ex. 20 | (A)-6 | (S)-1 | 100 | 100 | 400 | A |
| | [100] | [4,900] | | | | |

In Table 4, the values in brackets [ ] indicate the amount (in terms of parts by weight) of the component added. Further, in Table 4, the reference characters (A)-2, (A)-5, (A)-6 and (S)-1 are the same as defined above, and others indicate the following compounds.

(A)-14: the aforementioned polymeric compound 14

(A)-15: the aforementioned polymeric compound 15

(A)-16: the aforementioned polymeric compound 16

### [Evaluation of Contrast-1]

Using a spinner, each of the above positive resist compositions was applied uniformly onto an 8-inch silicon substrate that had been surface-treated with hexamethyldisilazane (HMDS) for 36 seconds at 90° C., and a prebake treatment (PAB) was then conducted for 60 seconds at the temperature shown in Table 4, thereby forming a resist film (film thickness: 60 nm).

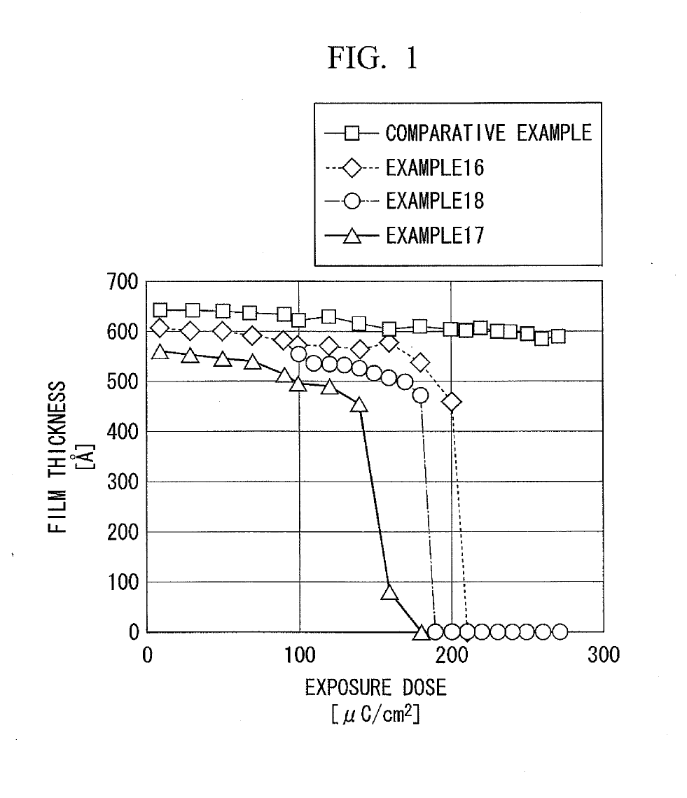

This resist film was subjected to exposure across the entire surface with an electron beam lithography apparatus HL-800D (VSB) (manufactured by Hitachi Ltd.) at an accelerating voltage of 70 kV and an exposure dose of 0 to 270 μC/cm², and was then subjected to a post exposure bake treatment (PEB) for 60 seconds at the temperature shown in Table 4. This resist film was then subjected to development for 60 seconds at 23° C. in a 2.38% by weight aqueous solution of TMAH (product name: NMD-3, manufactured by Tokyo Ohka Kogyo Co., Ltd.), followed by a postbake treatment at 100° C. for 60 seconds. The film thickness of the resist film was then measured using the Nanospec 6100A (manufactured by Nanometrics Inc.). The results for Examples 16 to 18 and Comparative Example 5 are shown in FIG. 1. In FIG. 1, the vertical axis indicates the film thickness (A) following exposure, and the horizontal axis indicates the exposure dose (μC/cm²). In Table 4, those in which the film thickness value reached 0 (at a stage where the exposure dose exceeded a certain level) were evaluated as “with contrast” and indicated as “A”, whereas those in which the film thickness value did not reach 0 were evaluated as “without contrast” and indicated as “B”. For those evaluated as “with contrast”, the Eth value (μC/cm²) (namely, the minimum exposure dose at which the film penetration occurs) is also indicated. It should be noted that in Comparative Example 5, the contrast was not achieved at any PEB temperatures.

From the above results, it is clear that the contrast was achieved in the resist compositions of Examples 16 to 20 according to the present invention, unlike the resist composition of Comparative Example 3. As described above, because the dissolution contrast was achieved even without using a conventional acid generator component separately from the base component, it is thought that the partial —SO₂— structure of R³ in the structural unit (a0-1) is acting like an acid generator component upon exposure. The same applies to the results described in the sections [Evaluation of contrast-2 to 4] below, where the contrast was achieved.

### Examples 21 to 22

### Comparative Example 4

The components shown in Table 5 were mixed together and dissolved to obtain positive resist compositions.

TABLE 5

| | Compo- | Compo- | PAB | PEB | Eth | Con- |
|---|---|---|---|---|---|---|
| | nent (A′) | nent (S) | (° C.) | (° C.) | (mJ/cm²) | trast |
| Ex. 21 | (A)-15 | (S)-1 | 100 | 150 | 3,990 | A |
| | [100] | [4,900] | | | | |
| Ex. 22 | (A)-14 | (S)-1 | 100 | 150 | 2,000 | A |
| | [100] | [4,900] | | | | |
| Comp. | (A)-16 | (S)-1 | 100 | 150 | — | B |
| Ex. 4 | [100] | [4,900] | | | | |

In Table 5, the values in brackets [ ] indicate the amount (in terms of parts by weight) of the component added. Further, in Table 5, the reference characters (A)-14, (A)-15, (A)-16 and (S)-1 are the same as defined above.

### [Evaluation of Contrast-2]

Using a spinner, each of the above positive resist compositions was applied uniformly onto an 8-inch silicon substrate that had been surface-treated with hexamethyldisilazane (HMDS) for 36 seconds at 90° C., and a prebake treatment (PAB) was then conducted for 60 seconds at the temperature shown in Table 5, thereby forming a resist film (film thickness: 60 nm). This formed resist film was subjected to exposure across the entire surface using a KrF exposure apparatus NSR-S203 at an exposure dose of 10 to 4,000 mJ/cm², and was then subjected to a post exposure bake treatment (PEB) for 60 seconds at the temperature shown in Table 5. This resist film was then subjected to development for 60 seconds at 23° C. in a 2.38% by weight aqueous solution of TMAH (product name: NMD-3, manufactured by Tokyo Ohka Kogyo Co., Ltd.), followed by a postbake treatment at 100° C. for 60 seconds. The film thickness of the resist film was then measured in the same manner as described above and the measured results regarding the contrast are indicated in Table 5. For those evaluated as “with contrast”, the Eth value (mJ/cm²) is also indicated.

From the above results, it is clear that the contrast was achieved in the resist compositions of Examples 21 to 22 according to the present invention, unlike the resist composition of Comparative Example 4.

### Examples 23 to 24

### Comparative Example 5

The components shown in Table 6 were mixed together and dissolved to obtain positive resist compositions.

TABLE 6

| | Compo- | Compo- | PAB | PEB 130° C. | | PEB 150° C. | |
|---|---|---|---|---|---|---|---|
| | nent (A′) | nent (S) | (° C.) | Eth (mJ/cm²) | Contrast | Eth (mJ/cm²) | Contrast |
| Ex. 23 | (A)-15 | (S)-1 | 100 | 400 | A | 250 | A |
| | [100] | [4,900] | | | | | |
| Ex. 24 | (A)-14 | (S)-1 | 100 | 250 | A | 200 | A |
| | [100] | [4,900] | | | | | |
| Comp. | (A)-16 | (S)-1 | 100 | — | B | — | B |
| Ex. 5 | [100] | [4,900] | | | | | |

In Table 6, the values in brackets [ ] indicate the amount (in terms of parts by weight) of the component added. Further, in Table 6, the reference characters (A)-14, (A)-15, (A)-16 and (S)-1 are the same as defined above.

### [Evaluation of Contrast-3]

Using a spinner, each of the above positive resist compositions was applied uniformly onto an 8-inch silicon substrate that had been surface-treated with hexamethyldisilazane (HMDS) for 36 seconds at 90° C., and a prebake treatment (PAB) was then conducted for 60 seconds at the temperature shown in Table 6, thereby forming a resist film (film thickness: 60 nm).

This formed resist film was subjected to exposure across the entire surface using an ArF exposure apparatus VUVES-4500 (manufactured by Litho Tech Japan Corporation) at an exposure dose of 10 to 1,000 mJ/cm², and was then subjected to a post exposure bake treatment (PEB) for 60 seconds at the temperature shown in Table 6. This resist film was then subjected to development for 60 seconds at 23° C. in a 2.38% by weight aqueous solution of TMAH (product name: NMD-3, manufactured by Tokyo Ohka Kogyo Co., Ltd.), followed by a postbake treatment at 100° C. for 60 seconds. The film thickness of the resist film was then measured in the same manner as described above and the measured results regarding the contrast are indicated in Table 6. For those evaluated as “with contrast”, the Eth value (mJ/cm²) is also indicated.

From the above results, it is clear that the contrast was achieved in the resist compositions of Examples 23 to 24 according to the present invention, unlike the resist composition of Comparative Example 5.

### Examples 25 to 28

### Comparative Examples 6 to 7

The components shown in Table 7 were mixed together and dissolved to obtain positive resist compositions.

TABLE 7

| | Compo- | | Compo- | Compo- | PAB | PEB | Eth | Con- |
|---|---|---|---|---|---|---|---|---|
| | nent (A′) | | nent (D) | nent (S) | (° C.) | (° C.) | (mJ/cm²) | trast |
| Ex. 25 | (A)-2 | — | — | (S)-1 | 100 | 130 | <100 | A |
| | [100] | | | [4,900] | | | | |
| Ex. 26 | (A)-2 | — | (D)-1 | (S)-1 | 100 | 150 | <32 | A |
| | [100] | | [1.00] | [4,900] | | | | |
| Ex. 27 | (A)-2 | (A)-4 | — | (S)-1 | 100 | 130 | <32 | A |
| | [50] | [50] | | [4,900] | | | | |
| Ex. 28 | (A)-2 | — | — | (S)-1 | 100 | 150 | <10 | A |
| | [100] | | | [4,900] | | | | |
| Comp. | (A)-13 | — | — | (S)-1 | 100 | 130 | Impossible to | |
| Ex. 6 | [100] | | | [4,900] | | | apply | |
| Comp. | (A)-4 | — | — | (S)-1 | 100 | 130 | — | B |
| Ex. 7 | [100] | | | [4,900] | | | | |

In Table 7, the values in brackets [ ] indicate the amount (in terms of parts by weight) of the component added. Further, in Table 7, the reference characters (A)-2, (A)-4, (A)-13 and (S)-1 are the same as defined above, and the reference character (D)-1 indicates the following compound.

(D)-1: tri-n-octylamine

### [Evaluation of Contrast-4]

Using a spinner, each of the above positive resist compositions was applied uniformly onto an 8-inch silicon substrate that had been surface-treated with hexamethyldisilazane (HMDS) for 36 seconds at 90° C., and a prebake treatment (PAB) was then conducted for 60 seconds at the temperature shown in Table 7, thereby forming a resist film (film thickness: 60 nm).

An EUV exposure experiment was conducted using the formed resist film by the Beam Line 3 at the NewSUBARU synchrotron radiation facility. This formed resist film was subjected to exposure across the entire surface at each exposure dose of 100.0, 32.0, 10.0, 3.20 and 0 (mJ/cm²), and was then subjected to a post exposure bake treatment (PEB) for 60 seconds at the temperature shown in Table 7. This resist film was then subjected to development for 60 seconds at 23° C. in a 2.38% by weight aqueous solution of TMAH (product name: NMD-3, manufactured by Tokyo Ohka Kogyo Co., Ltd.), followed by a postbake treatment at 100° C. for 60 seconds. The film thickness of the resist film was then measured in the same manner as described above and the measured results regarding the contrast are indicated in Table 7. For those evaluated as “with contrast”, the Eth value (mJ/cm²) is also indicated. Because application of the resist composition was not possible in Comparative Example 6, no study has been conducted regarding the contrast. However, from the results of the investigations conducted by the inventors of the present invention using other exposure light sources (such as ArF excimer lasers and KrF excimer lasers), it is presumed that the contrast cannot be achieved even if it was possible to apply the resist composition of Comparative Example 6.

From the above results, it is clear that the contrast was achieved in the resist compositions of Examples 25 to 28 according to the present invention, unlike the resist compositions of Comparative Examples 6 and 7.

What is claimed is:

1. A positive resist composition comprising:
a base component (A′) that exhibits increased solubility in an alkali developing solution under action of acid, without including an acid generator component other than the base component (A′),
wherein said base component (A′) includes a resin component (A1) having a structural unit (a0-1) represented by general formula (a0-1) shown below and a structural unit (a1) containing an acid dissociable, dissolution inhibiting group: 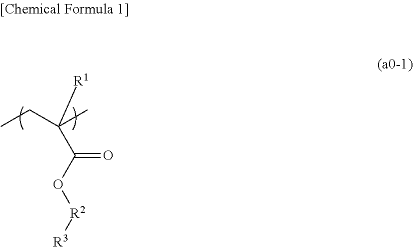
wherein R¹ represents a hydrogen atom, an alkyl group of 1 to 5 carbon atoms or a halogenated alkyl group of 1 to 5 carbon atoms; R² represents a single bond or a divalent linking group; and R³ represents a cyclic group that contains —SO₂— within the ring skeleton thereof.

2. The positive resist composition according to claim 1,
wherein said structural unit (a0-1) is a structural unit represented by general formula (a0-11) or (a0-12) shown below: 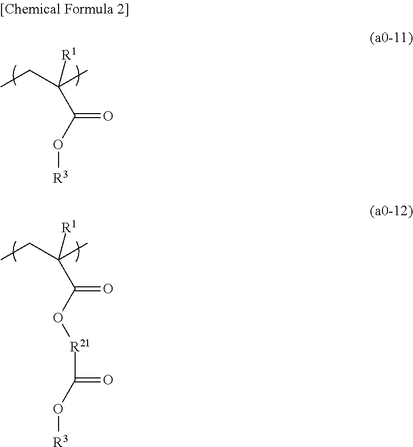
wherein R¹ represents a hydrogen atom, an alkyl group of 1 to 5 carbon atoms or a halogenated alkyl group of 1 to 5 carbon atoms; R²¹ represents a divalent linking group; and R³ represents a cyclic group that contains —SO₂— within the ring skeleton thereof.

3. The positive resist composition according to claim 1, wherein said R³ represents a cyclic group that contains —O—SO₂— within the ring skeleton thereof.

4. The positive resist composition according to claim 3,
wherein said R³ is represented by general formula (3-1) shown below: 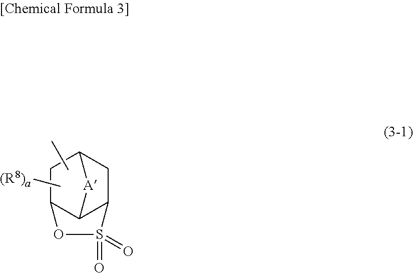
wherein A′ represents an oxygen atom, a sulfur atom, or an alkylene group of 1 to 5 carbon atoms which may contain an oxygen atom or a sulfur atom; a represents an integer of 0 to 2; and R⁸ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

5. A method of forming a resist pattern, comprising:
applying a positive resist composition of any one of claims 1 to 4 to a substrate to form a resist film on the substrate;
conducting exposure of said resist film; and
alkali-developing said resist film to form a resist pattern.
